(19) United States
(12) Patent Application Publication
(10) Pub. No.: US 2023/0114606 A1
(43) Pub. Date: Apr. 13, 2023

(54) WIRELESS COMMUNICATION INFRASTRUCTURE SYSTEM CONFIGURED WITH A SINGLE CRYSTAL PIEZO RESONATOR AND FILTER STRUCTURE USING THIN FILM TRANSFER PROCESS

(71) Applicant: Akoustis, Inc., Huntersville, NC (US)

(72) Inventors: Ramakrishna VETURY, Charlotte, NC (US); Jeffrey B. Shealy, Davidson, NC (US)

(21) Appl. No.: 18/063,003

(22) Filed: Dec. 7, 2022

Related U.S. Application Data
(63) Continuation of application No. 16/818,841, filed on Mar. 13, 2020, now abandoned.
Application No. 16/818,841 is a continuation-in-part of application No. 15/701,307, filed on Sep. 11, 2017, now Pat. No. 10,615,773.
Application No. 16/818,841 is a continuation-in-part of application No. 16/433,849, filed on Jun. 6, 2019, now Pat. No. 11,070,184.
Application No. 16/433,849 is a continuation of application No. 15/784,919, filed on Oct. 16, 2017, now Pat. No. 10,355,659.
Application No. 15/784,919 is a continuation-in-part of application No. 15/068,510, filed on Mar. 11, 2016, now Pat. No. 10,217,930.

(51) Int. Cl. H03H 3/02; H03H 9/02; H03H 9/17; H01L 41/337; H01L 41/317; H01L 41/29; H01L 41/23; H01L 41/18; H01L 41/08; H01L 41/053; H01L 41/047; H03H 9/54; H03H 9/13; H03H 9/10; H03H 9/05

(52) U.S. Cl. CPC H03H 3/02; H01L 41/18; H01L 41/23; H01L 41/29; H01L 41/053; H01L 41/081; H01L 41/317; H01L 41/337; H01L 41/0475; H01L 41/0477; H03H 9/13; H03H 9/105; H03H 9/173; H03H 9/175; H03H 9/177; H03H 9/0523; H03H 9/547; H03H 9/02015; H03H 9/02118; H03H 2003/021; H03H 2003/025; Y10T 29/42

(57) ABSTRACT

A system for a wireless communication infrastructure using single crystal devices. The wireless system can include a controller coupled to a power source, a signal processing module, and a plurality of transceiver modules. Each of the transceiver modules includes a transmit module configured on a transmit path and a receive module configured on a receive path. The transmit modules each include at least a transmit filter having one or more filter devices, while the receive modules each include at least a receive filter. Each of these filter devices includes a single crystal acoustic resonator device formed with a thin film transfer process with at least a first electrode material, a single crystal material, and a second electrode material. Wireless infrastructures using the present single crystal technology perform better in high power density applications, enable higher out of band rejection (OOBR), and achieve higher linearity as well.

### CROSS-REFERENCES TO RELATED APPLICATIONS

The present application claims priority to and is a continuation of U.S. Pat. App. No. 16/818,841 filed Mar. 13, 2020, which is a continuation-in-part of U.S. Pat. App. No. 15/701,307, filed Sep. 11, 2017, now U.S. Pat. No. 10,615,773, issued Apr. 7, 2020, and a continuation-in-part application of U.S. Pat. App. No. 16/433,849, filed Jun. 6, 2019, now U.S. Pat. No. 11,070,184, issued Jul. 20, 2021, which is a continuation of U.S. Pat. App. No. 15/784,919, filed Oct. 16, 2017, now U.S. Pat. No. 10,355,659 issued on Jul. 16, 2019, which is a continuation-in-part application of U.S. Pat. App. No. 15/068,510, filed Mar. 11, 2016, now U.S. Pat.. No. 10,217,930 issued on Feb. 26, 2019. The present application also incorporates by reference, for all purposes, the following patent applications, all commonly owned: U.S. Pat. App. No. 14/298,057, filed Jun. 6, 2014, now U.S. Pat. No. 9,673,384; U.S. Pat. App. No. 14/298,076, filed Jun. 6, 2014, now U.S. Patent No. 9,537,465; U.S. Pat. App. No. 14/298,100, filed Jun. 6, 2014, now U.S. Pat. No. 9,571,061; U.S. Pat. App. No. 14/341,314, filed Jul. 25, 2014, now U.S. Pat. No. 9,805,966; U.S. Pat. App. No. 14/449,001, filed Jul. 31, 2014, now U.S. Pat. No. 9,716,581; U.S. Pat. App. No. 14/469,503, filed Aug. 26, 2014, now U.S. Pat. No. 9,917,568; U.S. Pat. App. No. 15/068,510, filed Mar. 11, 2016, now U.S. Pat. No; U.S. Pat. App. No. 15/221,358, filed Jul. 27, 2016, and U.S. Pat. App. No. 15/341,218, filed Nov. 2, 2016, now U.S. Pat. No. 10,110,190.

### BACKGROUND OF THE INVENTION

According to the present invention, techniques generally related to electronic devices are provided. More particularly, the present invention provides techniques related to methods and devices related to wireless communication systems using single crystal devices, bulk acoustic wave resonator devices, single crystal filter and resonator devices, Power Amplifiers (PA), Low Noise Amplifiers (LNA), switches and the like. Merely by way of example, the invention has been applied to a single crystal resonator device for a communication device, mobile device, computing device, among others.

Mobile telecommunication devices have been successfully deployed world-wide. Over a billion mobile devices, including cell phones and smartphones, were manufactured in a single year and unit volume continues to increase year-over-year. With ramp of 4G/LTE in about 2012, and explosion of mobile data traffic, data rich content is driving the growth of the smartphone segment—which is expected to reach 2B per annum within the next few years. Coexistence of new and legacy standards and thirst for higher data rate requirements is driving wireless communication complexity in smartphones. Unfortunately, limitations exist with conventional wireless technology that is problematic, and may lead to drawbacks in the future.

From the above, it is seen that techniques for improving electronic communication devices are highly desirable.

### BRIEF SUMMARY OF THE INVENTION

According to the present invention, techniques generally related to electronic devices are provided. More particularly, the present invention provides techniques related to methods and devices related to wireless communication systems using single crystal devices, bulk acoustic wave resonator devices, single crystal filter and resonator devices, Power Amplifiers (PA), Low Noise Amplifiers (LNA), switches and the like. Merely by way of example, the invention has been applied to a single crystal resonator device for a communication device, mobile device, computing device, among others.

According to an example, the present invention provides a wireless communication infrastructure using single crystal devices. The wireless system can include a controller coupled to a power source, a signal processing module, and a plurality of transceiver modules. Each of the transceiver modules includes a transmit module configured on a transmit path and a receive module configured on a receive path. The transmit modules each include at least a transmit filter having one or more filter devices, while the receive modules each include at least a receive filter. In a specific example, the power source can include a power supply, a battery-based power supply, or a power supply combined with a battery backup, or the like. The signal processing module can be a baseband signal processing module. Further, the transceiver modules can include RF transmit and receive modules. Those of ordinary skill in the art will recognize other variations, modifications, and alternatives.

Each of these filter devices includes a single crystal acoustic resonator device. As an example, each device can include a substrate, a support layer, a piezoelectric film, a bottom electrode, a top electrode, a top metal, a first contact metal, and a second contact metal. The substrate includes a substrate surface region. The support layer is formed overlying the substrate surface region and has an air cavity formed within. The piezoelectric film is formed overlying the support layer and the substrate, and the piezoelectric film has a contact via formed within. The bottom electrode is formed underlying a portion of the piezoelectric film such that it is configured within the air cavity of the support layer and underlying the contact via of the piezoelectric film. The top electrode formed overlying a portion of the piezoelectric film. The top metal is formed overlying a portion of the piezoelectric film such that it is configured within the contact via of the piezoelectric film. The first contact metal is formed overlying a portion of the piezoelectric film such that it is electrically coupled to the top electrode. The second contact metal is formed overlying a portion of the piezoelectric film such that it is electrically coupled to the top metal and to the bottom electrode through the contact via of the piezoelectric film. As previously discussed, there can be variations, modifications, and alternatives of these devices.

An antenna is coupled to each of the transmit modules and each of the receive modules. An antenna control module is coupled to each of the receive path, the transmit path, and the transceiver modules. This antenna control module is configured to select one of the receive paths or one of the transmit paths in facilitating communication type operations.

In an example, a power amplifier module can be coupled to the controller, the power source, and the transceiver modules. The power amplifier module can be configured on each of the transmit paths and each of the receive paths. This power amplifier module can also include a plurality of communication bands, each of which can have a power amplifier. The filters of the transceiver modules can each be configured to one or more of the communication bands.

One or more benefits are achieved over pre-existing techniques using the present invention. Wireless infrastructures using the present single crystal technology achieves better thermal conductivity, which enables such infrastructures to perform better in high power density applications. The present single crystal infrastructures also provide low loss, thus enabling higher out of band rejection (OOBR). With better thermal properties and resilience over higher power, such single crystal infrastructures achieve higher linearity as well. Depending upon the embodiment, one or more of these benefits may be achieved. Of course, there can be other variations, modifications, and alternatives.

A further understanding of the nature and advantages of the invention may be realized by reference to the latter portions of the specification and attached drawings.

### BRIEF DESCRIPTION OF THE DRAWINGS

In order to more fully understand the present invention, reference is made to the accompanying drawings. Understanding that these drawings are not to be considered limitations in the scope of the invention, the presently described embodiments and the presently understood best mode of the invention are described with additional detail through use of the accompanying drawings in which:

FIG. 1A is a simplified diagram illustrating an acoustic resonator device having topside interconnections according to an example of the present invention.

FIG. 1B is a simplified diagram illustrating an acoustic resonator device having bottom-side interconnections according to an example of the present invention.

FIG. 1C is a simplified diagram illustrating an acoustic resonator device having interposer/cap-free structure interconnections according to an example of the present invention.

FIG. 1D is a simplified diagram illustrating an acoustic resonator device having interposer/cap-free structure interconnections with a shared backside trench according to an example of the present invention.

FIGS. 2 and 3 are simplified diagrams illustrating steps for a method of manufacture for an acoustic resonator device according to an example of the present invention.

FIG. 4A is a simplified diagram illustrating a step for a method creating a topside micro-trench according to an example of the present invention.

FIGS. 4B and 4C are simplified diagrams illustrating alternative methods for conducting the method step of forming a topside micro-trench as described in FIG. 4A.

FIGS. 4D and 4E are simplified diagrams illustrating an alternative method for conducting the method step of forming a topside micro-trench as described in FIG. 4A.

FIGS. 5 to 8 are simplified diagrams illustrating steps for a method of manufacture for an acoustic resonator device according to an example of the present invention.

FIG. 9A is a simplified diagram illustrating a method step for forming backside trenches according to an example of the present invention.

FIGS. 9B and 9C are simplified diagrams illustrating an alternative method for conducting the method step of forming backside trenches, as described in FIG. 9A, and simultaneously singulating a seed substrate according to an embodiment of the present invention.

FIG. 10 is a simplified diagram illustrating a method step forming backside metallization and electrical interconnections between top and bottom sides of a resonator according to an example of the present invention.

FIGS. 11A and 11B are simplified diagrams illustrating alternative steps for a method of manufacture for an acoustic resonator device according to an example of the present invention.

FIGS. 12A to 12E are simplified diagrams illustrating steps for a method of manufacture for an acoustic resonator device using a blind via interposer according to an example of the present invention.

FIG. 13 is a simplified diagram illustrating a step for a method of manufacture for an acoustic resonator device according to an example of the present invention.

FIGS. 14A to 14G are simplified diagrams illustrating method steps for a cap wafer process for an acoustic resonator device according to an example of the present invention.

FIGS. 15A-15E are simplified diagrams illustrating method steps for making an acoustic resonator device with shared backside trench, which can be implemented in both interposer/cap and interposer free versions, according to examples of the present invention.

FIGS. 16A-16C through FIGS. 31A-31C are simplified diagrams illustrating various cross-sectional views of a single crystal acoustic resonator device and of method steps for a transfer process using a sacrificial layer for single crystal acoustic resonator devices according to an example of the present invention.

FIGS. 32A-32C through FIGS. 46A-46C are simplified diagrams illustrating various cross-sectional views of a single crystal acoustic resonator device and of method steps for a cavity bond transfer process for single crystal acoustic resonator devices according to an example of the present invention.

FIGS. 47A-47C though FIGS. 59A-59C are simplified diagrams illustrating various cross-sectional views of a single crystal acoustic resonator device and of method steps for a solidly mounted transfer process for single crystal acoustic resonator devices according to an example of the present invention.

FIGS. 60A through 60E are simplified circuit diagrams illustrating various monolithic single chip single crystal devices according various examples of the present invention.

FIG. 61 is a simplified circuit diagram illustrating a monolithic single chip single crystal device integrated multiple circuit functions according an examples of the present invention.

FIGS. 62A-62E are simplified diagrams illustrating cross-sectional views of monolithic single chip single crystal devices according to various example of the present invention.

FIG. 63 is a simplified flow diagram illustrating a method for manufacturing an acoustic resonator device according to an example of the present invention.

FIG. 64 is a simplified graph illustrating the results of forming a piezoelectric layer for an acoustic resonator device according to an example of the present invention. The graph highlights the ability of to tailor the acoustic properties of the material for a given Aluminum mole fraction. Such flexibility allows for the resulting resonator properties to be tailored to the individual application.

FIG. 65A is a simplified diagram illustrating a method for forming a piezoelectric layer for an acoustic resonator device according to an example of the present invention.

FIG. 65B is a simplified diagram illustrating a method for forming a piezoelectric layer for an acoustic resonator device according to an example of the present invention.

FIG. 65C is a simplified diagram illustrating a method for forming a piezoelectric layer for an acoustic resonator device according to an example of the present invention.

FIG. 66 is a simplified illustrating a smart phone according to an example of the present invention.

FIG. 67 is a simplified system diagram with a smart phone according to an example of the present invention.

FIG. 68 is a simplified diagram of a smart phone system diagram according to an example of the present invention.

FIG. 69 is a simplified diagram of a transmit module and a receive module according to examples of the present invention.

FIG. 70 is an example of filter response in an example of the present invention.

FIG. 71 is a simplified diagram of a smart phone RF power amplifier module according to an example of the present invention.

FIG. 72 is a simplified diagram of a fixed wireless communication infrastructure system according to an example of the present invention.

### DETAILED DESCRIPTION OF THE INVENTION

According to the present invention, techniques generally related to electronic devices are provided. More particularly, the present invention provides techniques related to methods and devices related to wireless communication systems using single crystal devices, bulk acoustic wave resonator devices, single crystal filter and resonator devices, Power Amplifiers (PA), Low Noise Amplifiers (LNA), switches and the like. Merely by way of example, the invention has been applied to a single crystal resonator device for a communication device, mobile device, computing device, among others.

Typically, base stations provide the connections between mobile phones and a wider telephone network for voice and data. These base stations are characterized as macro, micro, nano, pico, or femto depending on the range of wireless coverage. Macro-cells are base stations covering a service provider’s largest coverage areas and are usually situated in rural areas and near highways. Micro-cells are low-power base stations covering areas where a mobile network requires additional coverage to maintain quality of service to subscribers. These micro-cells are usually situated in suburban and urban areas. Pico-cells are smaller base stations providing more localized coverage in areas with many users where network quality is poor. Pico-cells are usually placed inside buildings. Macro base stations may have ranges of up to 35 kilometers (about 22 miles). By comparison, pico-cells may have ranges of 200 meters or less, and femto-cells may have ranges of 10 to 40 meters.

These base stations operate at significantly higher power levels, especially compared to mobile devices. Whereas a mobile phone may typically put out 1 milliWatt (mW) to 1 Watt (W), a base station may put out anywhere from a few Watts to hundreds of Watts. With smaller device sizes being highly desirable in the industry (e.g., smaller than 3×3 sq. mm for wireless infrastructure and smaller than 1.5×1.5 sq. mm for mobile devices), the power density, i.e., RF power per unit area, of wireless infrastructures requirements are much higher than mobile devices as well. Single crystal devices have better thermal conductivity compared to conventional devices, which means wireless infrastructures implementing single crystal devices, e.g., filters, are better suited for high power density operations.

Wireless infrastructures using single crystal devices benefit from higher Out of Band Rejection (OOBR), which is the amount that an undesired signal is attenuated compared to a desired signal. In wireless infrastructure filters, the specification for OOBR can be 10 to 20 dB more stringent than for mobile device filters. Typically, filter designs require a trade-off between insertion loss and OOBR. Thus, improving OOBR without degrading insertion loss requires a lower loss RF filter technology, i.e., single crystal RF filter technology.

The improved thermal conductivity of the single crystal devices also enables present wireless infrastructures to operate with higher linearity. The root causes of non-linearity are changes in the properties of device materials over temperature and power levels. According to examples of the present invention, wireless infrastructures using single crystal device achieve higher linearity due to the improved thermal properties and consistency over higher power levels. The following paragraphs will describe various components of the wireless communication devices and their implementation in a system as a whole.

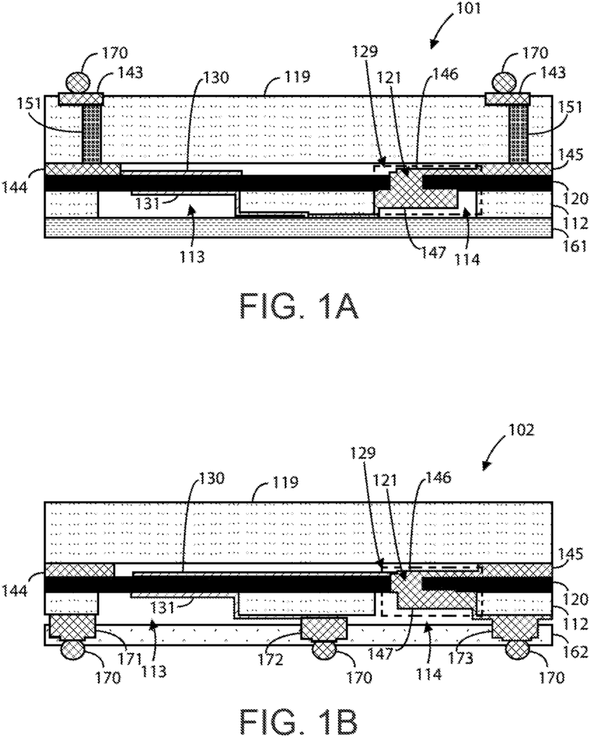

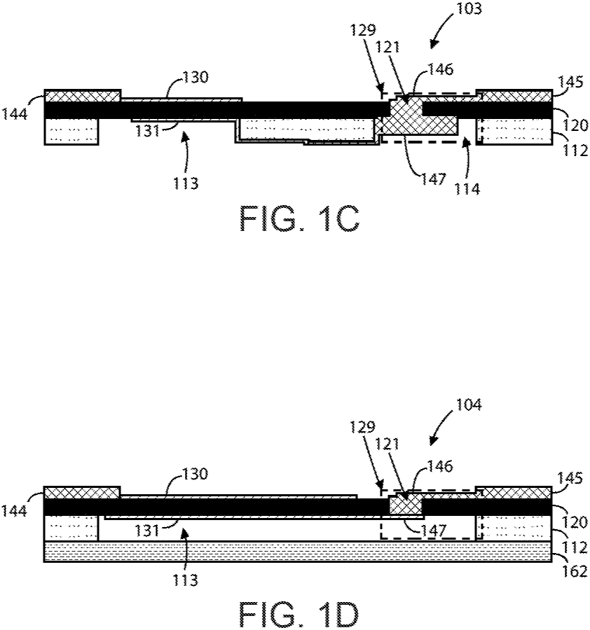

FIG. 1A is a simplified diagram illustrating an acoustic resonator device 101 having topside interconnections according to an example of the present invention. As shown, device 101 includes a thinned seed substrate 112 with an overlying single crystal piezoelectric layer 120, which has a micro-via 129. The micro-via 129 can include a topside micro-trench 121, a topside metal plug 146, a backside trench 114, and a backside metal plug 147. Although device 101 is depicted with a single micro-via 129, device 101 may have multiple micro-vias. A topside metal electrode 130 is formed overlying the piezoelectric layer 120. A top cap structure is bonded to the piezoelectric layer 120. This top cap structure includes an interposer substrate 119 with one or more through-vias 151 that are connected to one or more top bond pads 143, one or more bond pads 144, and topside metal 145 with topside metal plug 146. Solder balls 170 are electrically coupled to the one or more top bond pads 143.

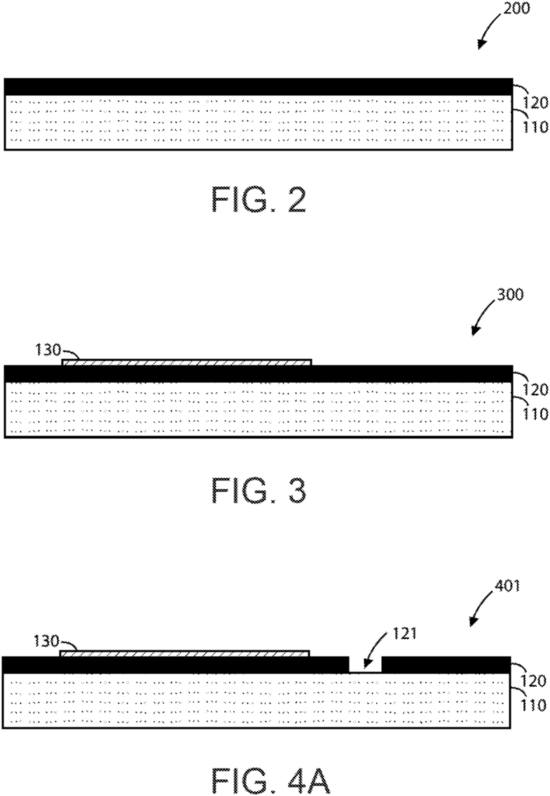

The thinned substrate 112 has the first and second backside trenches 113, 114. A backside metal electrode 131 is formed underlying a portion of the thinned seed substrate 112, the first backside trench 113, and the topside metal electrode 130. The backside metal plug 147 is formed underlying a portion of the thinned seed substrate 112, the second backside trench 114, and the topside metal 145. This backside metal plug 147 is electrically coupled to the topside metal plug 146 and the backside metal electrode 131. A backside cap structure 161 is bonded to the thinned seed substrate 112, underlying the first and second backside trenches 113, 114. Further details relating to the method of manufacture of this device will be discussed starting from FIG. 2.

FIG. 1B is a simplified diagram illustrating an acoustic resonator device 102 having backside interconnections according to an example of the present invention. As shown, device 102 includes a thinned seed substrate 112 with an overlying piezoelectric layer 120, which has a micro-via 129. The micro-via 129 can include a topside micro-trench 121, a topside metal plug 146, a backside trench 114, and a backside metal plug 147. Although device 102 is depicted with a single micro-via 129, device 102 may have multiple micro-vias. A topside metal electrode 130 is formed overlying the piezoelectric layer 120. A top cap structure is bonded to the piezoelectric layer 120. This top cap structure 119 includes bond pads which are connected to one or more bond pads 144 and topside metal 145 on piezoelectric layer 120. The topside metal 145 includes a topside metal plug 146.

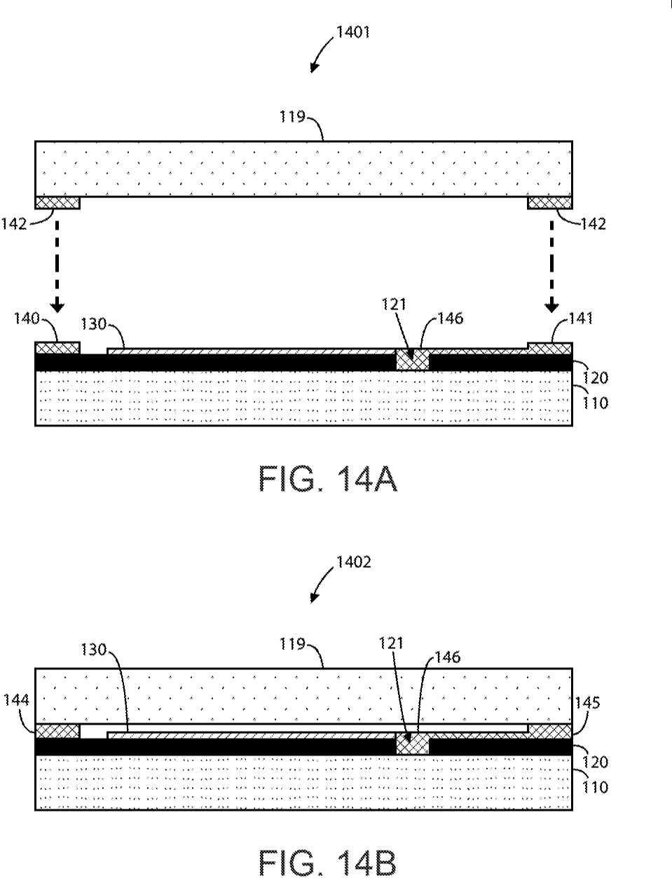

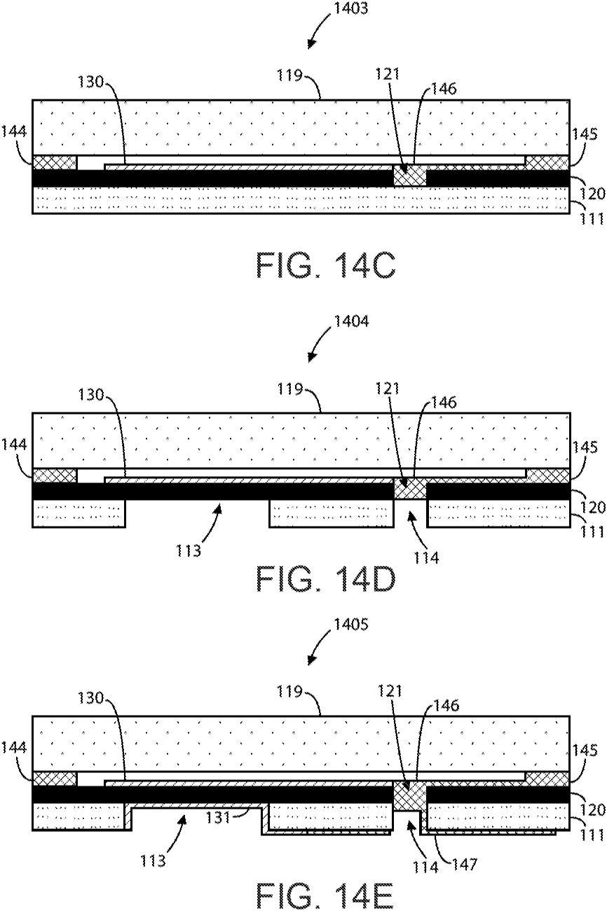

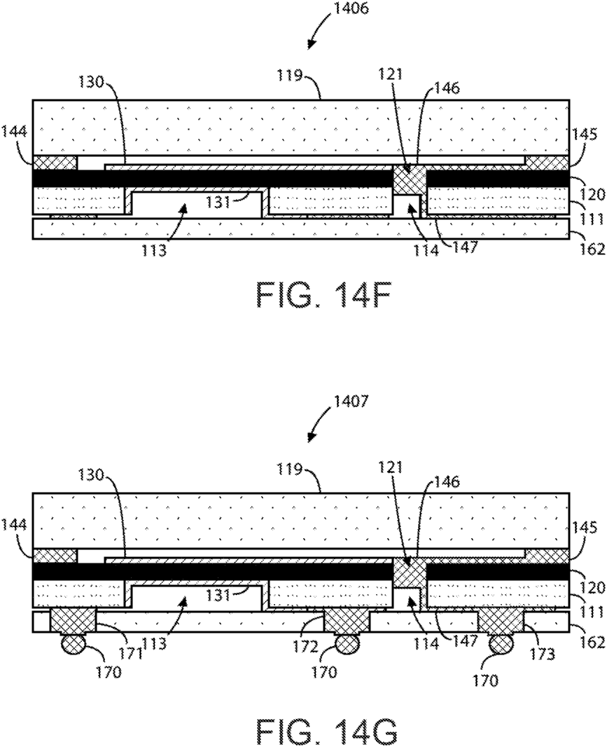

The thinned substrate 112 has the first and second backside trenches 113, 114. A backside metal electrode 131 is formed underlying a portion of the thinned seed substrate 112, the first backside trench 113, and the topside metal electrode 130. A backside metal plug 147 is formed underlying a portion of the thinned seed substrate 112, the second backside trench 114, and the topside metal plug 146. This backside metal plug 147 is electrically coupled to the topside metal plug 146. A backside cap structure 162 is bonded to the thinned seed substrate 112, underlying the first and second backside trenches. One or more backside bond pads (171, 172, 173) are formed within one or more portions of the backside cap structure 162. Solder balls 170 are electrically coupled to the one or more backside bond pads 171-173. Further details relating to the method of manufacture of this device will be discussed starting from FIG. 14A.

FIG. 1C is a simplified diagram illustrating an acoustic resonator device having interposer/cap-free structure interconnections according to an example of the present invention. As shown, device 103 includes a thinned seed substrate 112 with an overlying single crystal piezoelectric layer 120, which has a micro-via 129. The micro-via 129 can include a topside micro-trench 121, a topside metal plug 146, a backside trench 114, and a backside metal plug 147. Although device 103 is depicted with a single micro-via 129, device 103 may have multiple micro-vias. A topside metal electrode 130 is formed overlying the piezoelectric layer 120. The thinned substrate 112 has the first and second backside trenches 113, 114. A backside metal electrode 131 is formed underlying a portion of the thinned seed substrate 112, the first backside trench 113, and the topside metal electrode 130. A backside metal plug 147 is formed underlying a portion of the thinned seed substrate 112, the second backside trench 114, and the topside metal 145. This backside metal plug 147 is electrically coupled to the topside metal plug 146 and the backside metal electrode 131. Further details relating to the method of manufacture of this device will be discussed starting from FIG. 2.

FIG. 1D is a simplified diagram illustrating an acoustic resonator device having interposer/cap-free structure interconnections with a shared backside trench according to an example of the present invention. As shown, device 104 includes a thinned seed substrate 112 with an overlying single crystal piezoelectric layer 120, which has a micro-via 129. The micro-via 129 can include a topside micro-trench 121, a topside metal plug 146, and a backside metal 147. Although device 104 is depicted with a single micro-via 129, device 104 may have multiple micro-vias. A topside metal electrode 130 is formed overlying the piezoelectric layer 120. The thinned substrate 112 has a first backside trench 113. A backside metal electrode 131 is formed underlying a portion of the thinned seed substrate 112, the first backside trench 113, and the topside metal electrode 130. A backside metal 147 is formed underlying a portion of the thinned seed substrate 112, the second backside trench 114, and the topside metal 145. This backside metal 147 is electrically coupled to the topside metal plug 146 and the backside metal electrode 131. Further details relating to the method of manufacture of this device will be discussed starting from FIG. 2.

FIGS. 2 and 3 are simplified diagrams illustrating steps for a method of manufacture for an acoustic resonator device according to an example of the present invention. This method illustrates the process for fabricating an acoustic resonator device similar to that shown in FIG. 1A. FIG. 2 can represent a method step of providing a partially processed piezoelectric substrate. As shown, device 200 includes a seed substrate 110 with a piezoelectric layer 120 formed overlying. In a specific example, the seed substrate can include silicon (Si), silicon carbide (SiC), aluminum oxide (A1O), or single crystal aluminum gallium nitride (GaN) materials, or the like. In a specific example, an SiC substrate can provide better thermal conductivity, which can be desirable depending on the application. The piezoelectric layer 120 can include a piezoelectric single crystal layer or a thin film piezoelectric single crystal layer.

As shown in device 300, FIG. 3 can represent a method step of forming a top side metallization or top resonator metal electrode 130. In a specific example, the topside metal electrode 130 can include a molybdenum, aluminum, ruthenium, or titanium material, or the like and combinations thereof. This layer can be deposited and patterned on top of the piezoelectric layer by a lift-off process, a wet etching process, a dry etching process, a metal printing process, a metal laminating process, or the like. The lift-off process can include a sequential process of lithographic patterning, metal deposition, and lift-off steps to produce the topside metal layer. The wet/dry etching processes can includes sequential processes of metal deposition, lithographic patterning, metal deposition, and metal etching steps to produce the topside metal layer. Those of ordinary skill in the art will recognize other variations, modifications, and alternatives.

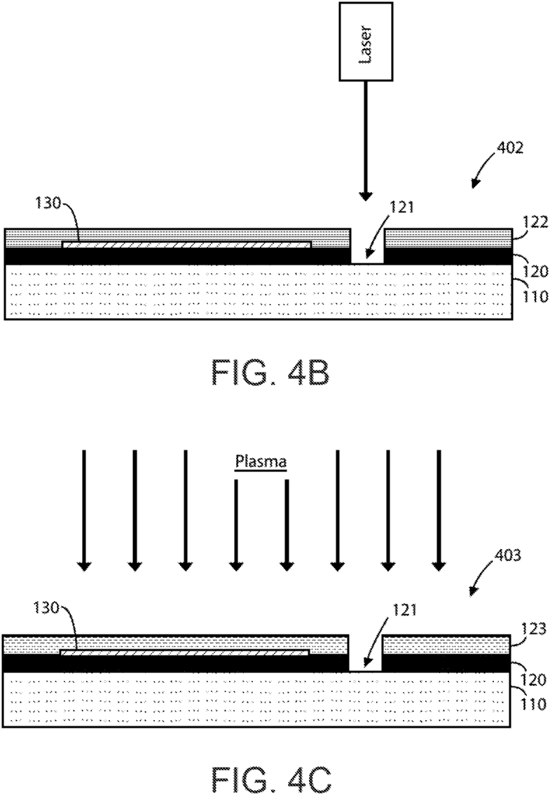

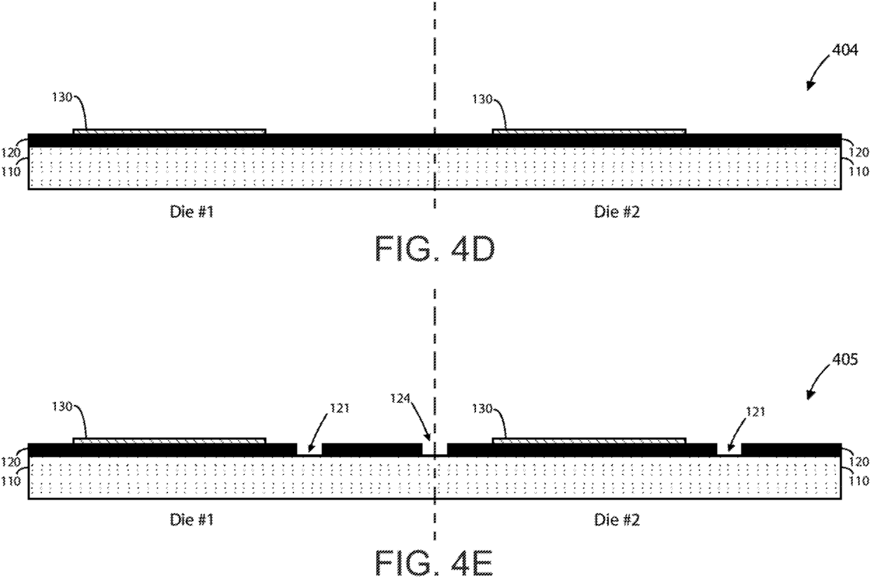

FIG. 4A is a simplified diagram illustrating a step for a method of manufacture for an acoustic resonator device 401 according to an example of the present invention. This figure can represent a method step of forming one or more topside micro-trenches 121 within a portion of the piezoelectric layer 120. This topside micro-trench 121 can serve as the main interconnect junction between the top and bottom sides of the acoustic membrane, which will be developed in later method steps. In an example, the topside micro-trench 121 is extends all the way through the piezoelectric layer 120 and stops in the seed substrate 110. This topside micro-trench 121 can be formed through a dry etching process, a laser drilling process, or the like. FIGS. 4B and 4C describe these options in more detail.

FIGS. 4B and 4C are simplified diagrams illustrating alternative methods for conducting the method step as described in FIG. 4A. As shown with device 402, FIG. 4B represents a method step of using a laser drill, which can quickly and accurately form the topside micro-trench 121 in the piezoelectric layer 120. In an example, the laser drill can be used to form nominal 50 um holes, or holes between 10 um and 500 um in diameter, through the piezoelectric layer 120 and stop in the seed substrate 110 below the interface between layers 120 and 110. A protective layer 122 can be formed overlying the piezoelectric layer 120 and the topside metal electrode 130. This protective layer 122 can serve to protect the device from laser debris and to provide a mask for the etching of the topside micro-via 121. In a specific example, the laser drill can be an 11 W high power diode-pumped UV laser, or the like. This mask 122 can be subsequently removed before proceeding to other steps. The mask may also be omitted from the laser drilling process, and air flow can be used to remove laser debris.

FIG. 4C can represent a method step of using a dry etching process to form the topside micro-trench 121 in the piezoelectric layer 120. As shown with device 403, a lithographic masking layer 123 can be forming overlying the piezoelectric layer 120 and the topside metal electrode 130. The topside micro-trench 121 can be formed by exposure to plasma, or the like.

FIGS. 4D and 4E are simplified diagrams illustrating an alternative method for conducting the method step as described in FIG. 4A. These figures can represent the method step of manufacturing multiple acoustic resonator devices simultaneously. In FIG. 4D, two devices are shown on Die #1 and Die #2 of wafer 404, respectively. FIG. 4E shows the process of forming a micro-via 121 on each of these dies of wafer 405 while also etching a scribe line 124 or dicing line. In an example, the etching of the scribe line 124 singulates and relieves stress in the piezoelectric single crystal layer 120.

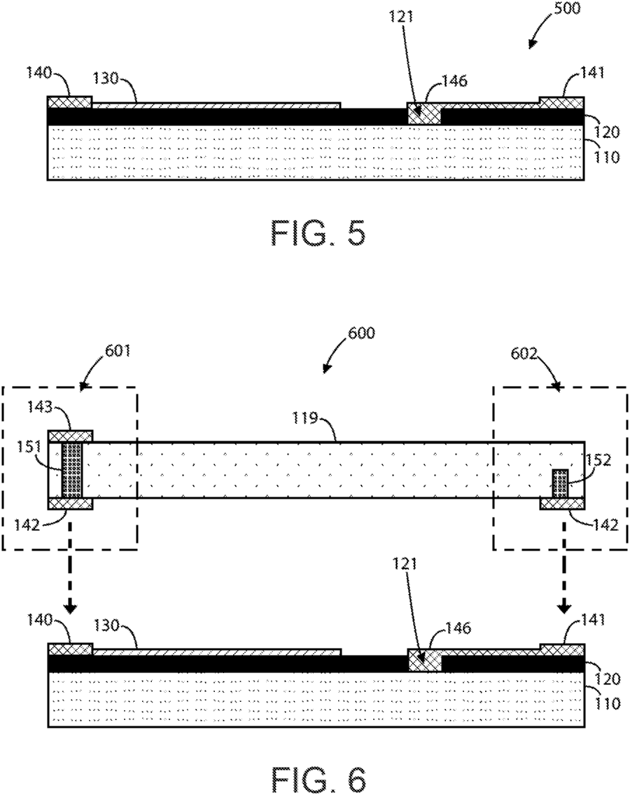

FIGS. 5 to 8 are simplified diagrams illustrating steps for a method of manufacture for an acoustic resonator device according to an example of the present invention. As shown with device 500, FIG. 5 can represent the method step of forming one or more bond pads 140 and forming a topside metal 141 electrically coupled to at least one of the bond pads 140. The topside metal 141 can include a topside metal plug 146 formed within the topside micro-trench 121. In a specific example, the topside metal plug 146 fills the topside micro-trench 121 to form a topside portion of a micro-via.

In an example, the bond pads 140 and the topside metal 141 can include a gold material or other interconnect metal material depending upon the application of the device. These metal materials can be formed by a lift-off process, a wet etching process, a dry etching process, a screen-printing process, an electroplating process, a metal printing process, or the like. In a specific example, the deposited metal materials can also serve as bond pads for a cap structure, which will be described below.

FIG. 6 can represent a method step for preparing the acoustic resonator device for bonding, which can be a hermetic bonding. As shown with device 600, a top cap structure is positioned above the partially processed acoustic resonator device as described in the previous figures. The top cap structure can be formed using an interposer substrate 119 in two configurations: fully processed interposer version 601 (through glass via) and partially processed interposer version 602 (blind via version). In the 601 version, the interposer substrate 119 includes through-via structures 151 that extend through the interposer substrate 119 and are electrically coupled to bottom bond pads 142 and top bond pads 143. In the 602 version, the interposer substrate 119 includes blind via structures 152 that only extend through a portion of the interposer substrate 119 from the bottom side. These blind via structures 152 are also electrically coupled to bottom bond pads 142. In a specific example, the interposer substrate can include a silicon, glass, smart-glass, or other like material.

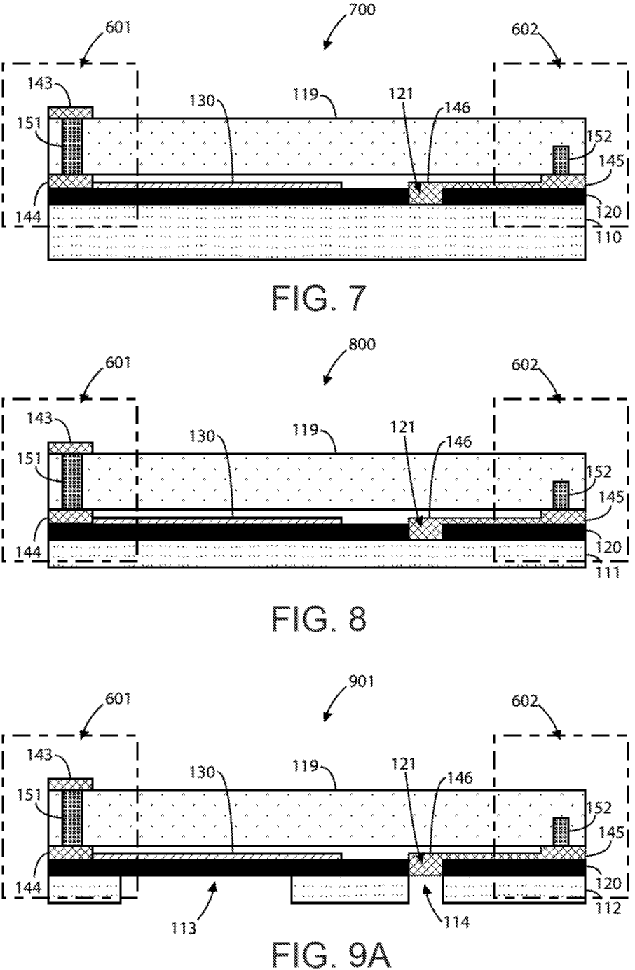

FIG. 7 can represent a method step of bonding the top cap structure to the partially processed acoustic resonator device. As shown with device 700, the interposer substrate 119 is bonded to the piezoelectric layer by the bond pads (140, 142) and the topside metal 141, which are now denoted as bond pad 144 and topside metal 145. This bonding process can be done using a compression bond method or the like. As shown with device 800, FIG. 8 can represent a method step of thinning the seed substrate 110, which is now denoted as thinned seed substrate 111. This substrate thinning process can include grinding and etching processes or the like. In a specific example, this process can include a wafer backgrinding process followed by stress removal, which can involve dry etching, CMP polishing, or annealing processes.

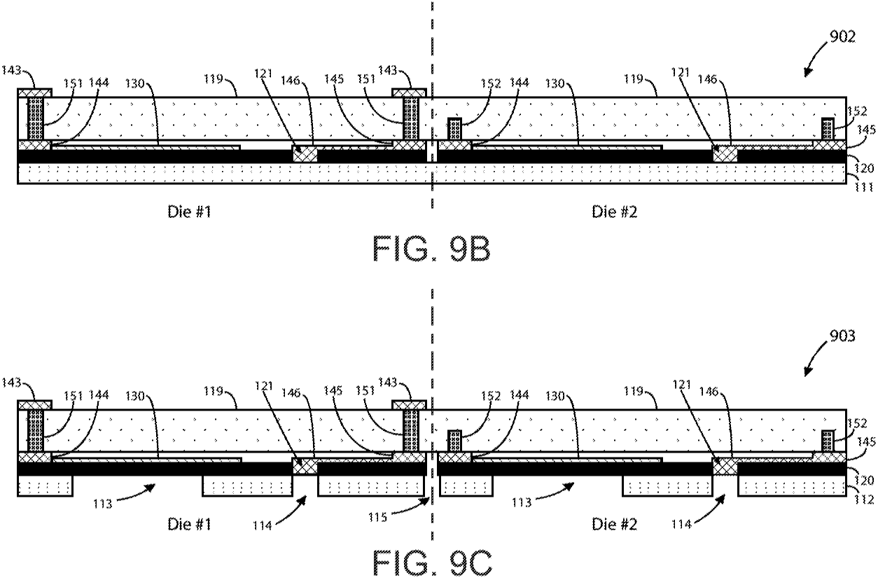

FIG. 9A is a simplified diagram illustrating a step for a method of manufacture for an acoustic resonator device 901 according to an example of the present invention. FIG. 9A can represent a method step for forming backside trenches 113 and 114 to allow access to the piezoelectric layer from the backside of the thinned seed substrate 111. In an example, the first backside trench 113 can be formed within the thinned seed substrate 111 and underlying the topside metal electrode 130. The second backside trench 114 can be formed within the thinned seed substrate 111 and underlying the topside micro-trench 121 and topside metal plug 146. This substrate is now denoted thinned substrate 112. In a specific example, these trenches 113 and 114 can be formed using deep reactive ion etching (DRIE) processes, Bosch processes, or the like. The size, shape, and number of the trenches may vary with the design of the acoustic resonator device. In various examples, the first backside trench may be formed with a trench shape similar to a shape of the topside metal electrode or a shape of the backside metal electrode. The first backside trench may also be formed with a trench shape that is different from both a shape of the topside metal electrode and the backside metal electrode.

FIGS. 9B and 9C are simplified diagrams illustrating an alternative method for conducting the method step as described in FIG. 9A. Like FIGS. 4D and 4E, these figures can represent the method step of manufacturing multiple acoustic resonator devices simultaneously. In FIG. 9B, two devices with cap structures are shown on Die #1 and Die #2 of wafer 902, respectively. FIG. 9C shows the process of forming backside trenches (113, 114) on each of these dies of wafer 903 while also etching a scribe line 115 or dicing line. In an example, the etching of the scribe line 115 provides an optional way to singulate the backside wafer 112.

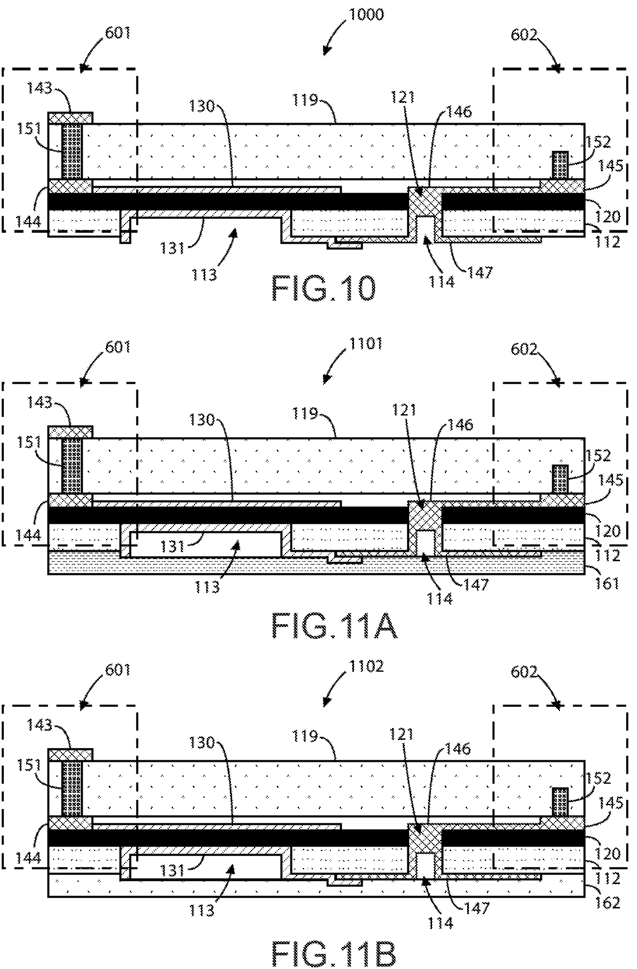

FIG. 10 is a simplified diagram illustrating a step for a method of manufacture for an acoustic resonator device 1000 according to an example of the present invention. This figure can represent a method step of forming a backside metal electrode 131 and a backside metal plug 147 within the backside trenches of the thinned seed substrate 112. In an example, the backside metal electrode 131 can be formed underlying one or more portions of the thinned substrate 112, within the first backside trench 113, and underlying the topside metal electrode 130. This process completes the resonator structure within the acoustic resonator device. The backside metal plug 147 can be formed underlying one or more portions of the thinned substrate 112, within the second backside trench 114, and underlying the topside micro-trench 121. The backside metal plug 147 can be electrically coupled to the topside metal plug 146 and the backside metal electrode 131. In a specific example, the backside metal electrode 130 can include a molybdenum, aluminum, ruthenium, or titanium material, or the like and combinations thereof. The backside metal plug can include a gold material, low resistivity interconnect metals, electrode metals, or the like. These layers can be deposited using the deposition methods described previously.

FIGS. 11A and 11B are simplified diagrams illustrating alternative steps for a method of manufacture for an acoustic resonator device according to an example of the present invention. These figures show methods of bonding a backside cap structure underlying the thinned seed substrate 112. In device 1101 of FIG. 11A, the backside cap structure is a dry film cap 161, which can include a permanent photo-imageable dry film such as a solder mask, polyimide, or the like. Bonding this cap structure can be cost-effective and reliable, but may not produce a hermetic seal. In device 1102 of FIG. 11B, the backside cap structure is a substrate 162, which can include a silicon, glass, or other like material. Bonding this substrate can provide a hermetic seal, but may cost more and require additional processes. Depending upon application, either of these backside cap structures can be bonded underlying the first and second backside vias.

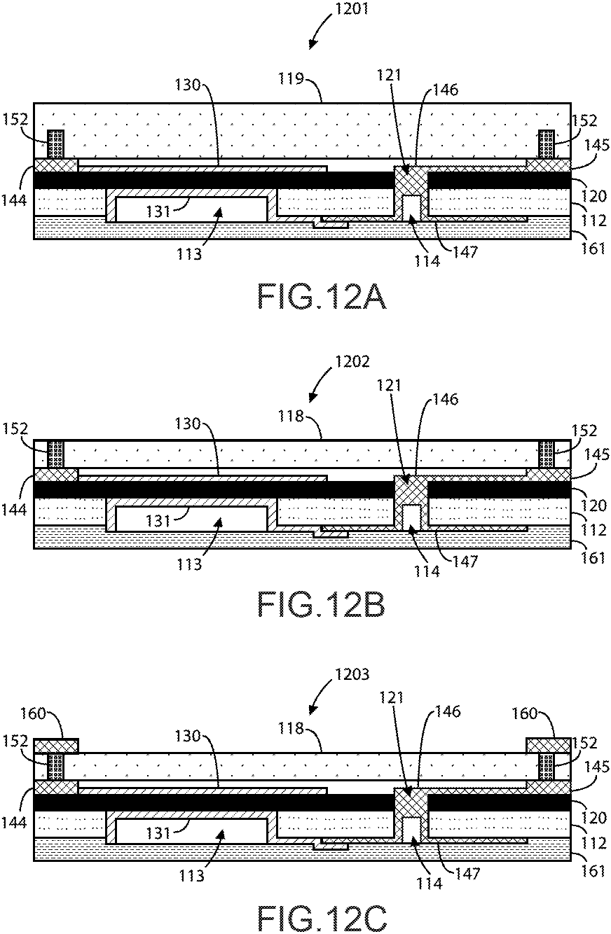

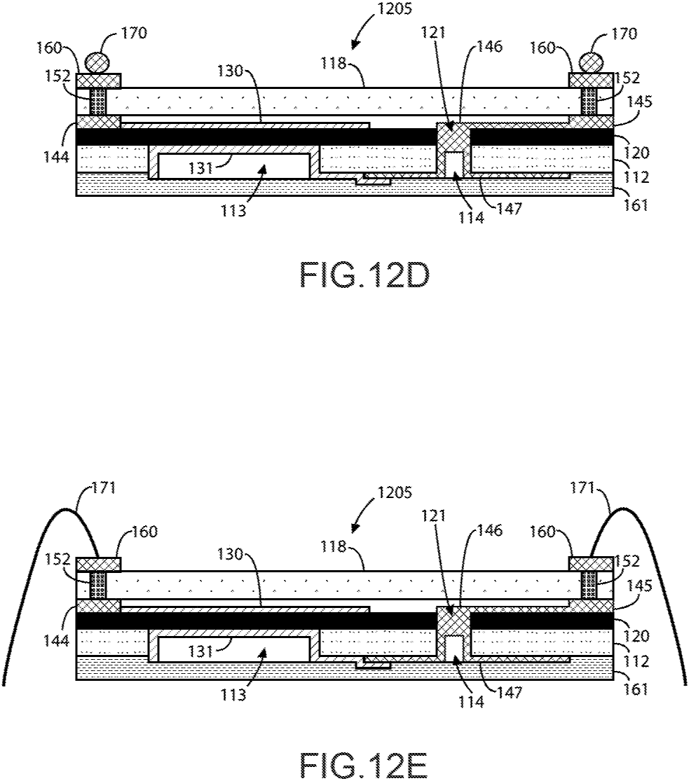

FIGS. 12A to 12E are simplified diagrams illustrating steps for a method of manufacture for an acoustic resonator device according to an example of the present invention. More specifically, these figures describe additional steps for processing the blind via interposer “602” version of the top cap structure. FIG. 12A shows an acoustic resonator device 1201 with blind vias 152 in the top cap structure. In device 1202 of FIG. 12B, the interposer substrate 119 is thinned, which forms a thinned interposer substrate 118, to expose the blind vias 152. This thinning process can be a combination of a grinding process and etching process as described for the thinning of the seed substrate. In device 1203 of FIG. 12C, a redistribution layer (RDL) process and metallization process can be applied to create top cap bond pads 160 that are formed overlying the blind vias 152 and are electrically coupled to the blind vias 152. As shown in device 1204 of FIG. 12D, a ball grid array (BGA) process can be applied to form solder balls 170 overlying and electrically coupled to the top cap bond pads 160. This process leaves the acoustic resonator device ready for wire bonding 171, as shown in device 1205 of FIG. 12E.

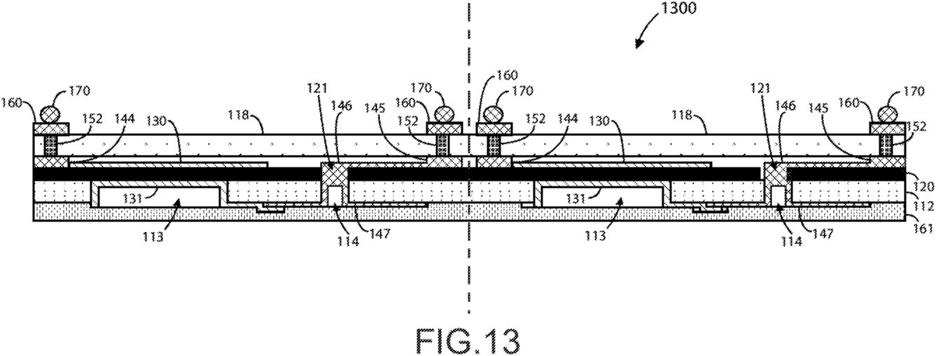

FIG. 13 is a simplified diagram illustrating a step for a method of manufacture for an acoustic resonator device according to an example of the present invention. As shown, device 1300 includes two fully processed acoustic resonator devices that are ready to singulation to create separate devices. In an example, the die singulation process can be done using a wafer dicing saw process, a laser cut singulation process, or other processes and combinations thereof.

FIGS. 14A to 14G are simplified diagrams illustrating steps for a method of manufacture for an acoustic resonator device according to an example of the present invention. This method illustrates the process for fabricating an acoustic resonator device similar to that shown in FIG. 1B. The method for this example of an acoustic resonator can go through similar steps as described in FIGS. 1-5. FIG. 14A (device 1401) shows where this method differs from that described previously. Here, the top cap structure substrate 119 and only includes one layer of metallization with one or more bottom bond pads 142. Compared to FIG. 6, there are no via structures in the top cap structure because the interconnections will be formed on the bottom side of the acoustic resonator device.

FIGS. 14B to 14F depict method steps similar to those described in the first process flow. FIG. 14B (device 1402) can represent a method step of bonding the top cap structure to the piezoelectric layer 120 through the bond pads (140, 142) and the topside metal 141, now denoted as bond pads 144 and topside metal 145 with topside metal plug 146. FIG. 14C (device 1403) can represent a method step of thinning the seed substrate 110, which forms a thinned seed substrate 111, similar to that described in FIG. 8. FIG. 14D (device 1404) can represent a method step of forming first and second backside trenches, similar to that described in FIG. 9A. FIG. 14E (device 1405) can represent a method step of forming a backside metal electrode 131 and a backside metal plug 147, similar to that described in FIG. 10. FIG. 14F (device 1406) can represent a method step of bonding a backside cap structure 162, similar to that described in FIGS. 11A and 11B.

FIG. 14G(device 1407) shows another step that differs from the previously described process flow. Here, the backside bond pads 171, 172, and 173 are formed within the backside cap structure 162. In an example, these backside bond pads 171-173 can be formed through a masking, etching, and metal deposition processes similar to those used to form the other metal materials. A BGA process can be applied to form solder balls 170 in contact with these backside bond pads 171-173, which prepares the acoustic resonator device 1407 for wire bonding.

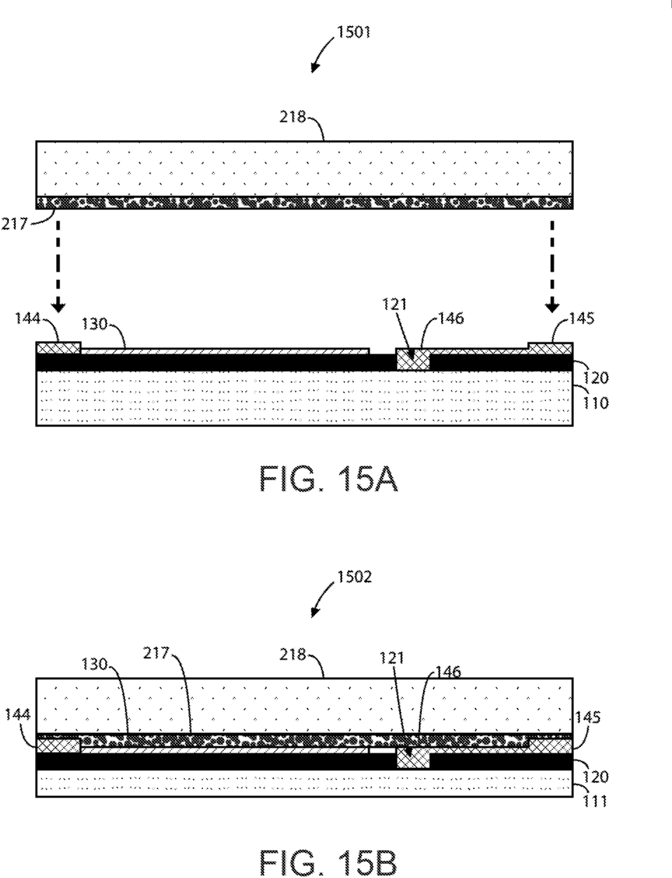

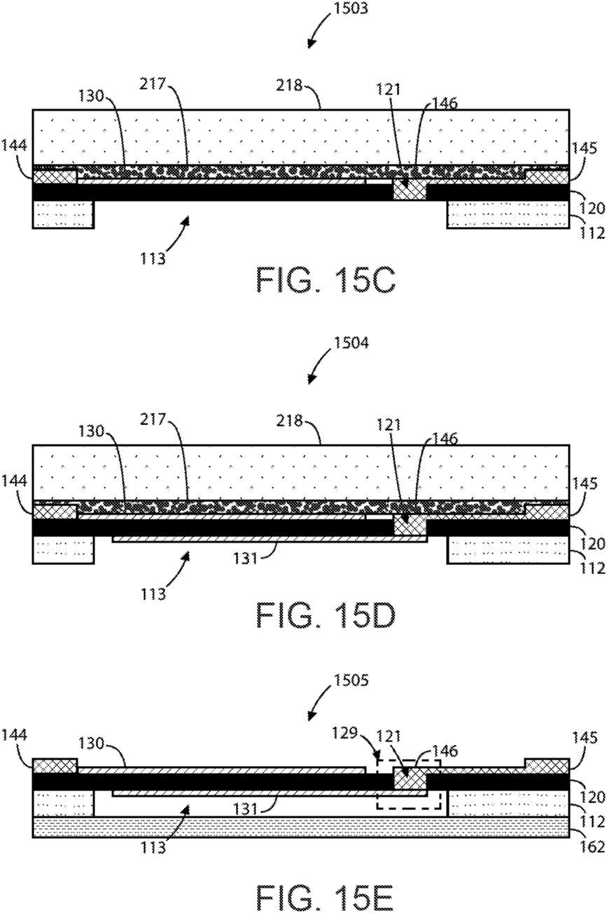

FIGS. 15A to 15E are simplified diagrams illustrating steps for a method of manufacture for an acoustic resonator device according to an example of the present invention. This method illustrates the process for fabricating an acoustic resonator device similar to that shown in FIG. 1B. The method for this example can go through similar steps as described in FIGS. 1-5. FIG. 15A (device 1501) shows where this method differs from that described previously. A temporary carrier 218 with a layer of temporary adhesive 217 is attached to the substrate. In a specific example, the temporary carrier 218 can include a glass wafer, a silicon wafer, or other wafer and the like.

FIGS. 15B to 15F depict method steps similar to those described in the first process flow. FIG. 15B (device 1502) can represent a method step of thinning the seed substrate 110, which forms a thinned substrate 111, similar to that described in FIG. 8. In a specific example, the thinning of the seed substrate 110 can include a back side grinding process followed by a stress removal process. The stress removal process can include a dry etch, a Chemical Mechanical Planarization (CMP), and annealing processes.

FIG. 15C (device 1503) can represent a method step of forming a shared backside trench 113, similar to the techniques described in FIG. 9A. The main difference is that the shared backside trench is configured underlying both topside metal electrode 130, topside micro-trench 121, and topside metal plug 146. In an example, the shared backside trench 113 is a backside resonator cavity that can vary in size, shape (all possible geometric shapes), and side wall profile (tapered convex, tapered concave, or right angle). In a specific example, the forming of the shared backside trench 113 can include a litho-etch process, which can include a back-to-front alignment and dry etch of the backside substrate 111. The piezoelectric layer 120 can serve as an etch stop layer for the forming of the shared backside trench 113.

FIG. 15D (device 1504) can represent a method step of forming a backside metal electrode 131 and a backside metal 147, similar to that described in FIG. 10. In an example, the forming of the backside metal electrode 131 can include a deposition and patterning of metal materials within the shared backside trench 113. Here, the backside metal 131 serves as an electrode and the backside plug/connect metal 147 within the micro-via 121. The thickness, shape, and type of metal can vary as a function of the resonator/filter design. As an example, the backside electrode 131 and via plug metal 147 can be different metals. In a specific example, these backside metals 131, 147 can either be deposited and patterned on the surface of the piezoelectric layer 120 or rerouted to the backside of the substrate 112. In an example, the backside metal electrode may be patterned such that it is configured within the boundaries of the shared backside trench such that the backside metal electrode does not come in contact with one or more side-walls of the seed substrate created during the forming of the shared backside trench.

FIG. 15E (device 1505) can represent a method step of bonding a backside cap structure 162, similar to that described in FIGS. 11A and 11B, following a de-bonding of the temporary carrier 218 and cleaning of the topside of the device to remove the temporary adhesive 217. Those of ordinary skill in the art will recognize other variations, modifications, and alternatives of the methods steps described previously.

As used herein, the term “substrate” can mean the bulk substrate or can include overlying growth structures such as an aluminum, gallium, or ternary compound of aluminum and gallium and nitrogen containing epitaxial region, or functional regions, combinations, and the like.

One or more benefits are achieved over pre-existing techniques using the invention. In particular, the present device can be manufactured in a relatively simple and cost effective manner while using conventional materials and/or methods according to one of ordinary skill in the art. Using the present method, one can create a reliable single crystal based acoustic resonator using multiple ways of three-dimensional stacking through a wafer level process. Such filters or resonators can be implemented in an RF filter device, an RF filter system, or the like. Depending upon the embodiment, one or more of these benefits may be achieved. Of course, there can be other variations, modifications, and alternatives.

With 4G LTE and 5G growing more popular by the day, wireless data communication demands high performance RF filters with frequencies around 5 GHz and higher. Bulk acoustic wave resonators (BAWR), widely used in such filters operating at frequencies around 3 GHz and lower, are leading candidates for meeting such demands. Current bulk acoustic wave resonators use polycrystalline piezoelectric A1N thin films where each grain’s c-axis is aligned perpendicular to the film’s surface to allow high piezoelectric performance whereas the grains' a- or b-axis are randomly distributed. This peculiar grain distribution works well when the piezoelectric film’s thickness is around 1 um and above, which is the perfect thickness for bulk acoustic wave (BAW) filters operating at frequencies ranging from 1 to 3 GHz. However, the quality of the polycrystalline piezoelectric films degrades quickly as the thicknesses decrease below around 0.5 um, which is required for resonators and filters operating at frequencies around 5 GHz and above.

Single crystalline or epitaxial piezoelectric thin films grown on compatible crystalline substrates exhibit good crystalline quality and high piezoelectric performance even down to very thin thicknesses, e.g., 0.4 um. The present invention provides manufacturing processes and structures for high quality bulk acoustic wave resonators with single crystalline or epitaxial piezoelectric thn films for high frequency BAW filter applications.

BAWRs require a piezoelectric material, e.g., A1N, in crystalline form, i.e., polycrystalline or single crystalline. The quality of the film heavy depends on the chemical, crystalline, or topographical quality of the layer on which the film is grown. In conventional BAWR processes (including film bulk acoustic resonator (FBAR) or solidly mounted resonator (SMR) geometry), the piezoelectric film is grown on a patterned bottom electrode, which is usually made of molybdenum (Mo), tungsten (W), or ruthenium (Ru). The surface geometry of the patterned bottom electrode significantly influences the crystalline orientation and crystalline quality of the piezoelectric film, requiring complicated modification of the structure.

Thus, the present invention uses single crystalline piezoelectric films and thin film transfer processes to produce a BAWR with enhanced ultimate quality factor and electromechanical coupling for RF filters. Such methods and structures facilitate methods of manufacturing and structures for RF filters using single crystalline or epitaxial piezoelectric films to meet the growing demands of contemporary data communication.

In an example, the present invention provides transfer structures and processes for acoustic resonator devices, which provides a flat, high-quality, single-crystal piezoelectric film for superior acoustic wave control and high Q in high frequency. As described above, polycrystalline piezoelectric layers limit Q in high frequency. Also, growing epitaxial piezoelectric layers on patterned electrodes affects the crystalline orientation of the piezoelectric layer, which limits the ability to have tight boundary control of the resulting resonators. Embodiments of the present invention, as further described below, can overcome these limitations and exhibit improved performance and cost-efficiency.

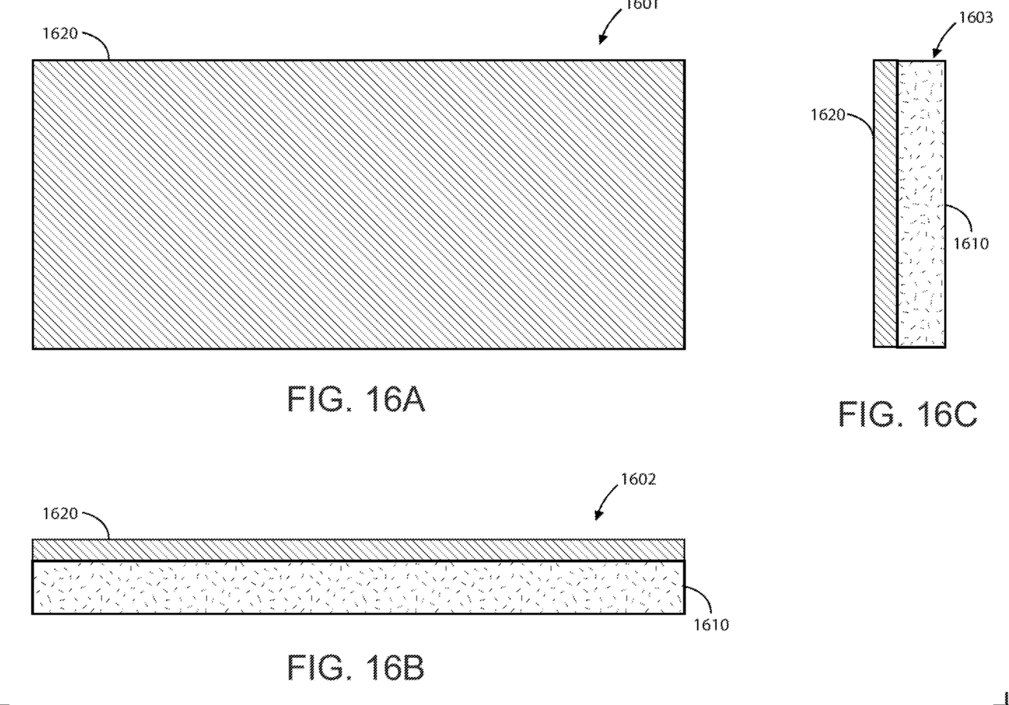

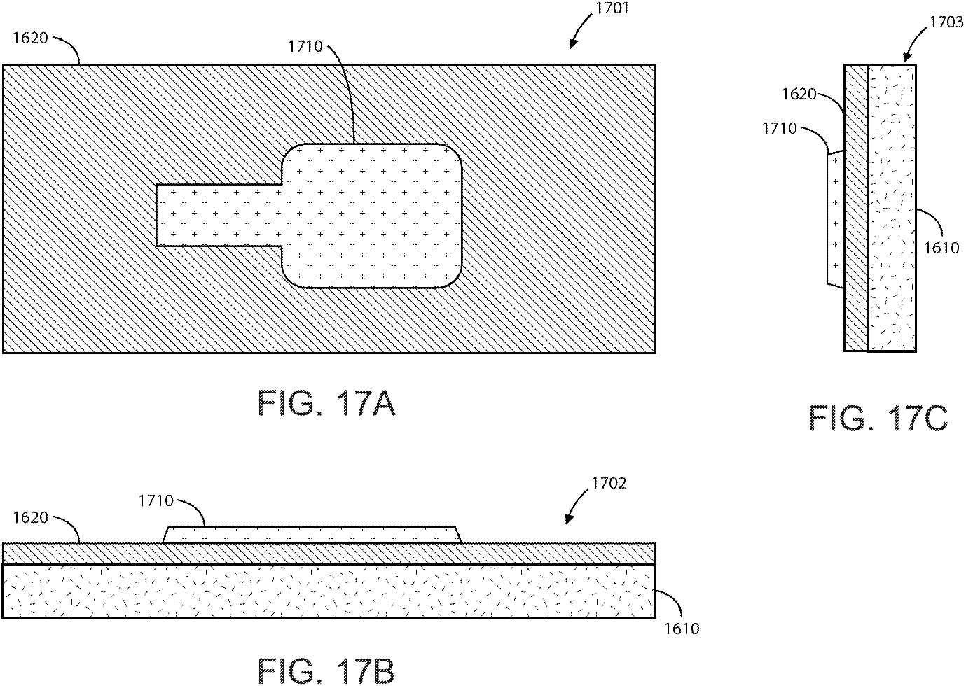

FIGS. 16A-16C through FIGS. 31A-31C illustrate a method of fabrication for an acoustic resonator device using a transfer structure with a sacrificial layer. In these figure series described below, the “A” figures show simplified diagrams illustrating top cross-sectional views of single crystal resonator devices according to various embodiments of the present invention. The “B” figures show simplified diagrams illustrating lengthwise cross-sectional views of the same devices in the “A” figures. Similarly, the “C” figures show simplified diagrams illustrating widthwise cross-sectional views of the same devices in the “A” figures. In some cases, certain features are omitted to highlight other features and the relationships between such features. Those of ordinary skill in the art will recognize variations, modifications, and alternatives to the examples shown in these figure series.

FIGS. 16A-16C (devices 1601 to 1603, respectively) are simplified diagrams illustrating various cross-sectional views of a single crystal acoustic resonator device and of method steps for a transfer process using a sacrificial layer for single crystal acoustic resonator devices according to an example of the present invention. As shown, these figures illustrate the method step of forming a piezoelectric film 1620 overlying a growth substrate 1610. In an example, the growth substrate 1610 can include silicon (S), silicon carbide (SiC), or other like materials. The piezoelectric film 1620 can be an epitaxial film including aluminum nitride (A1N), gallium nitride (GaN), or other like materials. Additionally, this piezoelectric substrate can be subjected to a thickness trim.

FIGS. 17A-17C (devices 1701 to 1703, respectively) are simplified diagrams illustrating various cross-sectional views of a single crystal acoustic resonator device and of method steps for a transfer process using a sacrificial layer for single crystal acoustic resonator devices according to an example of the present invention. As shown, these figures illustrate the method step of forming a first electrode 1710 overlying the surface region of the piezoelectric film 1620. In an example, the first electrode 1710 can include molybdenum (Mo), ruthenium (Ru), tungsten (W), or other like materials. In a specific example, the first electrode 1710 can be subjected to a dry etch with a slope. As an example, the slope can be about 60 degrees.

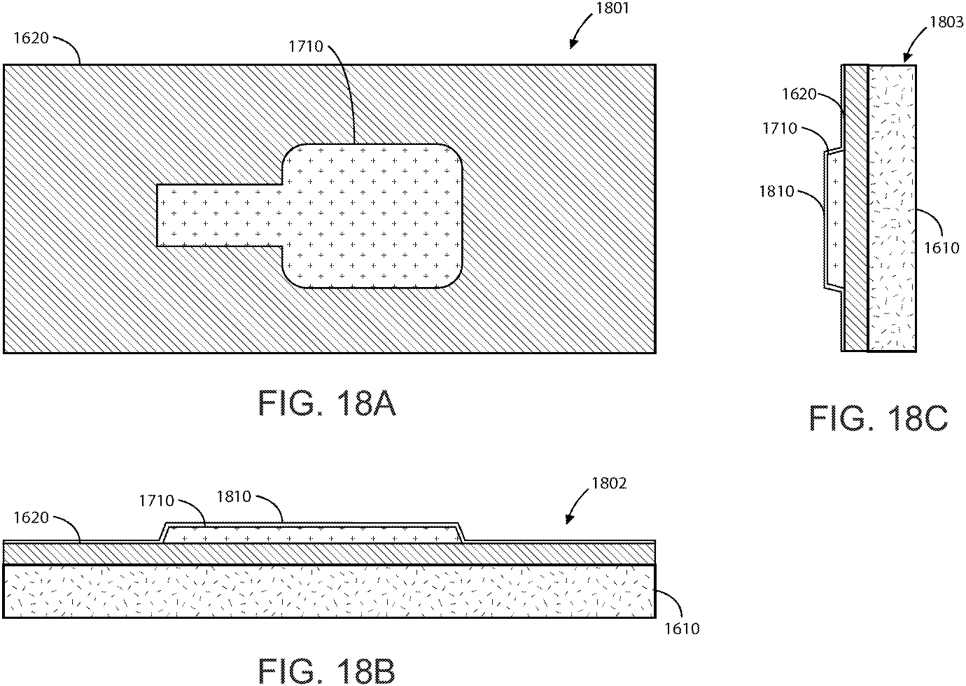

FIGS. 18A-18C (devices 1801 to 1803, respectively) are simplified diagrams illustrating various cross-sectional views of a single crystal acoustic resonator device and of method steps for a transfer process using a sacrificial layer for single crystal acoustic resonator devices according to an example of the present invention. As shown, these figures illustrate the method step of forming a first passivation layer 1810 overlying the first electrode 1710 and the piezoelectric film 1620. In an example, the first passivation layer 1810 can include silicon nitride (SiN), silicon oxide (SiO), or other like materials. In a specific example, the first passivation layer 1810 can have a thickness ranging from about 50 nm to about 100 nm.

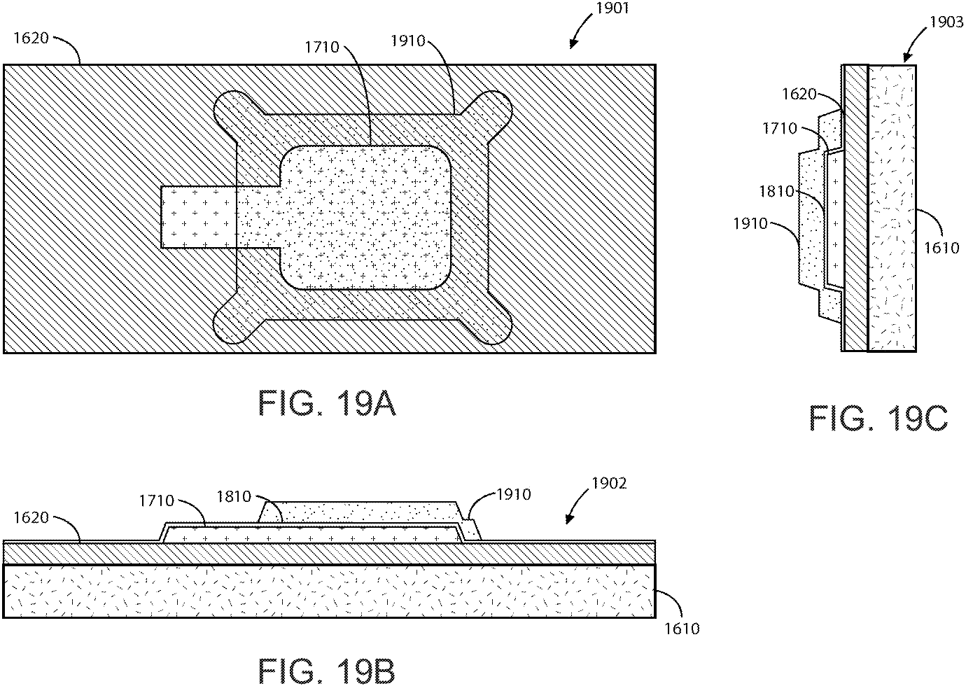

FIGS. 19A-19C (devices 1901 to 1903, respectively) are simplified diagrams illustrating various cross-sectional views of a single crystal acoustic resonator device and of method steps for a transfer process using a sacrificial layer for single crystal acoustic resonator devices according to an example of the present invention. As shown, these figures illustrate the method step of forming a sacrificial layer 1910 overlying a portion of the first electrode 1810 and a portion of the piezoelectric film 1620. In an example, the sacrificial layer 1910 can include polycrystalline silicon (poly-Si), amorphous silicon (a-Si), or other like materials. In a specific example, this sacrificial layer 1910 can be subjected to a dry etch with a slope and be deposited with a thickness of about 1 um. Further, phosphorous doped SiO₂ (PSG) can be used as the sacrificial layer with different combinations of support layer (e.g., SiNx).

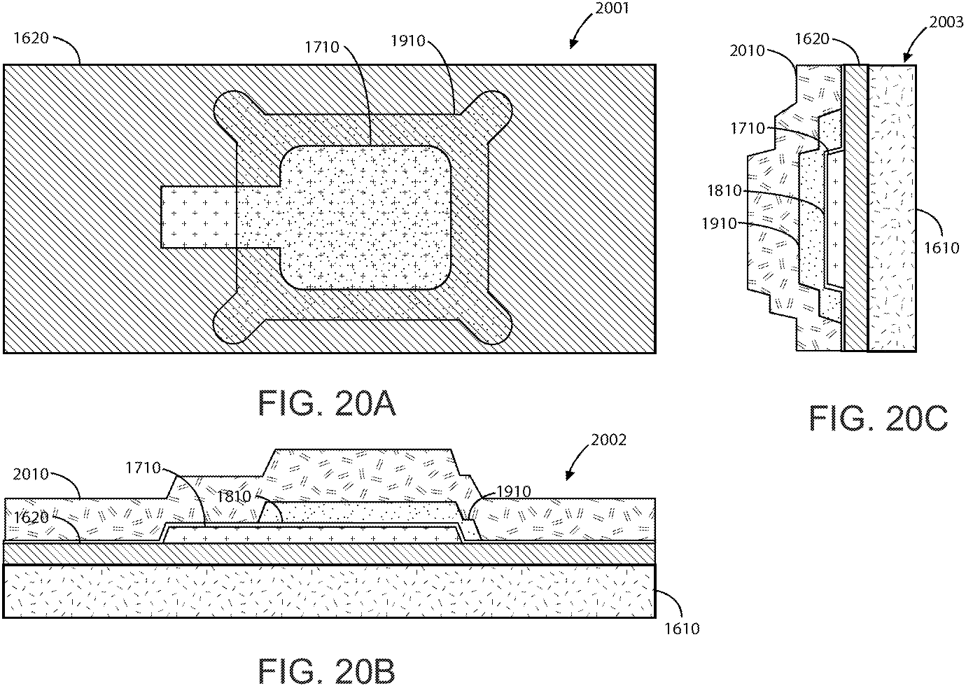

FIGS. 20A-20C (devices 2001 to 2003, respectively) are simplified diagrams illustrating various cross-sectional views of a single crystal acoustic resonator device and of method steps for a transfer process using a sacrificial layer for single crystal acoustic resonator devices according to an example of the present invention. As shown, these figures illustrate the method step of forming a support layer 2010 overlying the sacrificial layer 1910, the first electrode 1710, and the piezoelectric film 1620. In an example, the support layer 2010 can include silicon dioxide (SiO₂), silicon nitride (SiN), or other like materials. In a specific example, this support layer 2010 can be deposited with a thickness of about 2-3 um. As described above, other support layers (e.g., SiNx) can be used in the case of a PSG sacrificial layer.

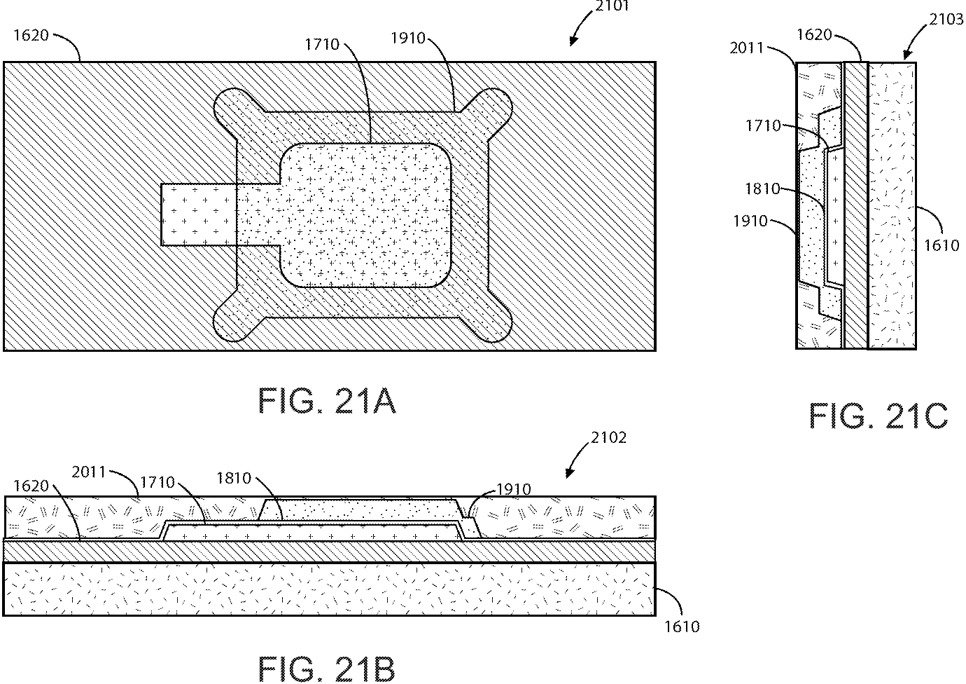

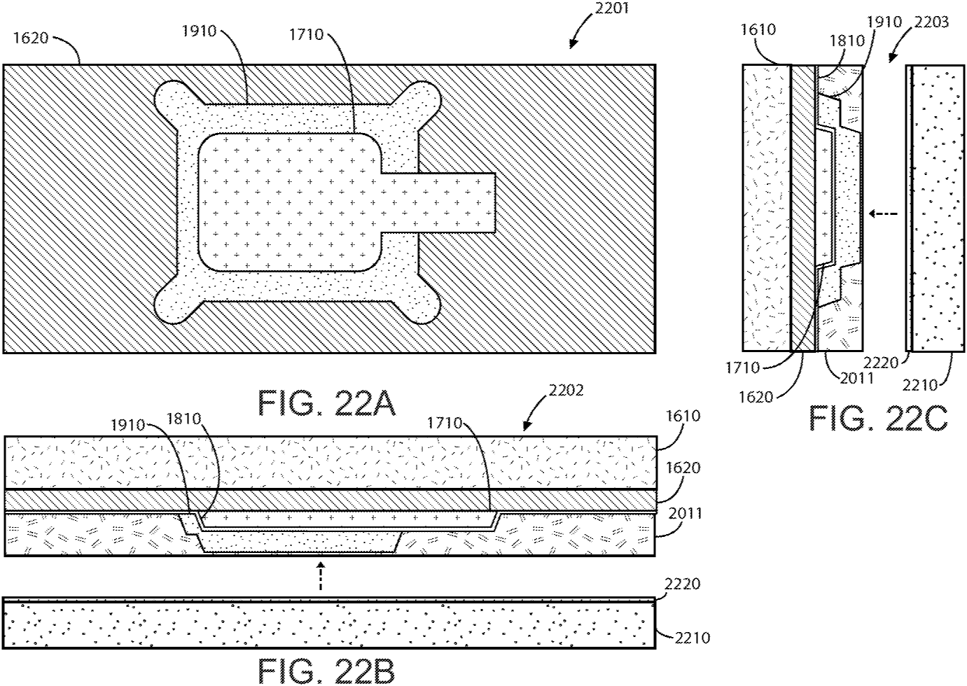

FIGS. 21A-21C (devices 2101 to 2103, respectively) are simplified diagrams illustrating various cross-sectional views of a single crystal acoustic resonator device and of method steps for a transfer process using a sacrificial layer for single crystal acoustic resonator devices according to an example of the present invention. As shown, these figures illustrate the method step of polishing the support layer 2010 to form a polished support layer 2011. In an example, the polishing process can include a chemical-mechanical planarization process or the like.

FIGS. 22A-22C (devices 2201 to 2203, respectively) are simplified diagrams illustrating various cross-sectional views of a single crystal acoustic resonator device and of method steps for a transfer process using a sacrificial layer for single crystal acoustic resonator devices according to an example of the present invention. As shown, these figures illustrate flipping the device and physically coupling overlying the support layer 2011 overlying a bond substrate 2210. In an example, the bond substrate 2210 can include a bonding support layer 2220 (SiO₂ or like material) overlying a substrate having silicon (Si), sapphire (A1₂O₃), silicon dioxide (SiO₂), silicon carbide (SiC), or other like materials. In a specific embodiment, the bonding support layer 2220 of the bond substrate 2210 is physically coupled to the polished support layer 2011. Further, the physical coupling process can include a room temperature bonding process following by a 300 degree Celsius annealing process.

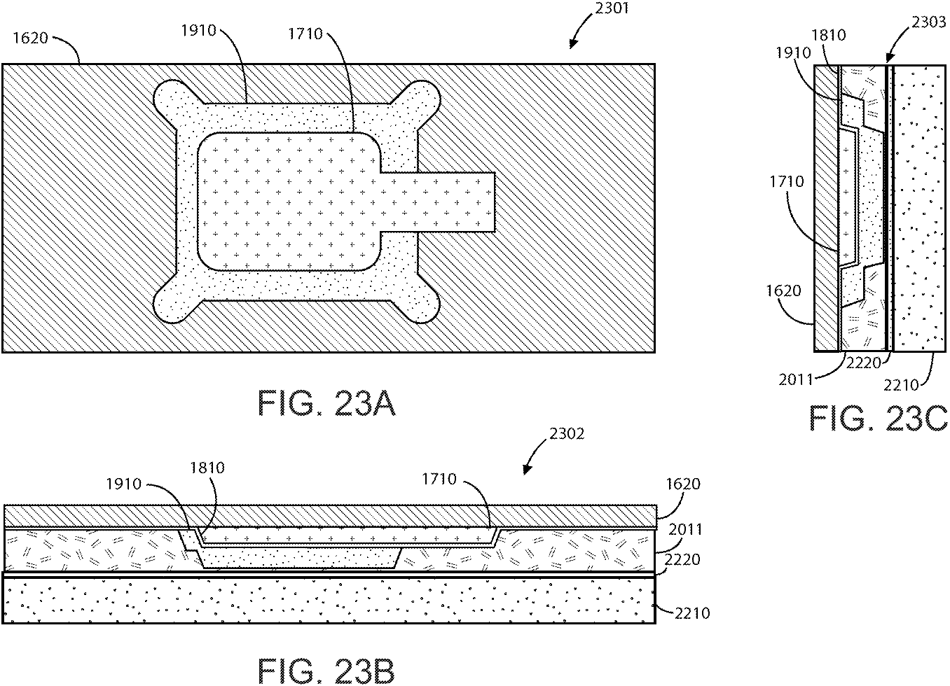

FIGS. 23A-23C (devices 2301 to 2303, respectively) are simplified diagrams illustrating various cross-sectional views of a single crystal acoustic resonator device and of method steps for a transfer process using a sacrificial layer for single crystal acoustic resonator devices according to an example of the present invention. As shown, these figures illustrate the method step of removing the growth substrate 1610 or otherwise the transfer of the piezoelectric film 1620. In an example, the removal process can include a grinding process, a blanket etching process, a film transfer process, an ion implantation transfer process, a laser crack transfer process, or the like and combinations thereof.

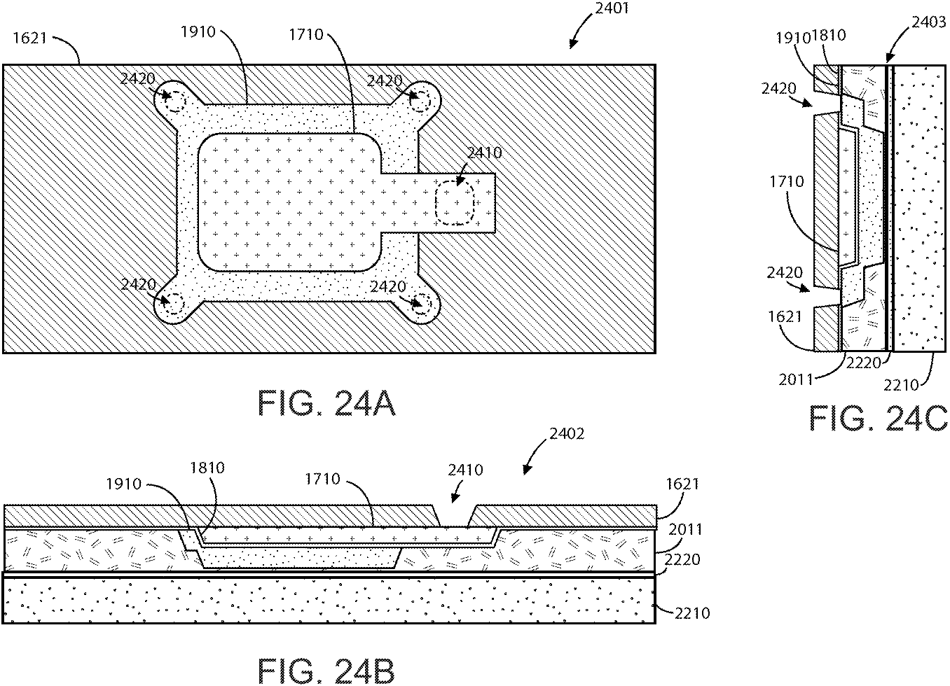

FIGS. 24A-24C (devices 2401 to 2403, respectively) are simplified diagrams illustrating various cross-sectional views of a single crystal acoustic resonator device and of method steps for a transfer process using a sacrificial layer for single crystal acoustic resonator devices according to an example of the present invention. As shown, these figures illustrate the method step of forming an electrode contact via 2410 within the piezoelectric film 1620 (becoming piezoelectric film 1621) overlying the first electrode 1710 and forming one or more release holes 2420 within the piezoelectric film 1620 and the first passivation layer 1810 overlying the sacrificial layer 1910. The via forming processes can include various types of etching processes.

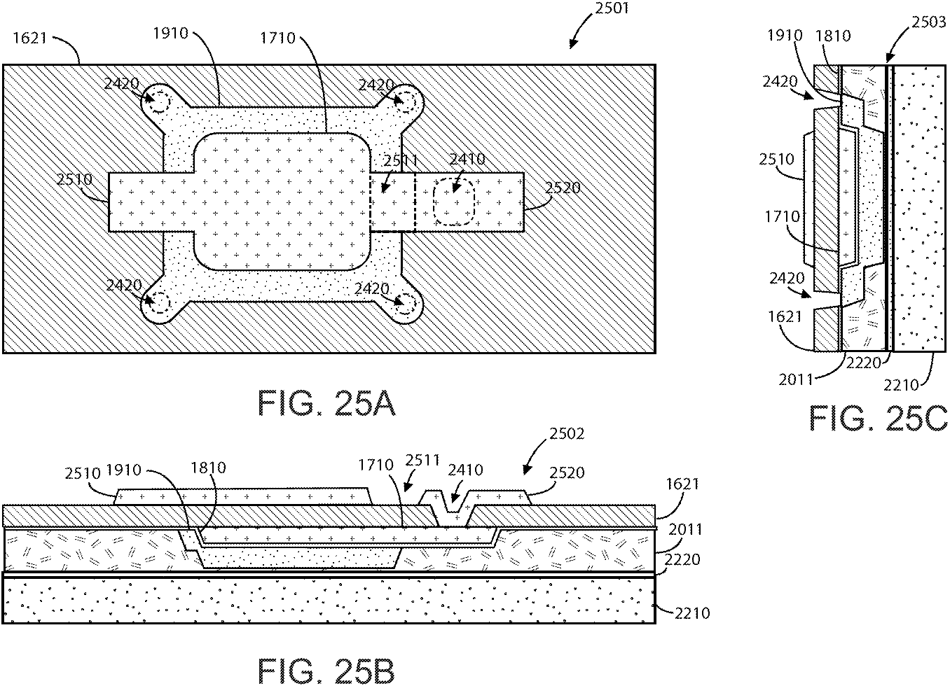

FIGS. 25A-25C (devices 2501 to 2503, respectively) are simplified diagrams illustrating various cross-sectional views of a single crystal acoustic resonator device and of method steps for a transfer process using a sacrificial layer for single crystal acoustic resonator devices according to an example of the present invention. As shown, these figures illustrate the method step of forming a second electrode 2510 overlying the piezoelectric film 1621. In an example, the formation of the second electrode 2510 includes depositing molybdenum (Mo), ruthenium (Ru), tungsten (W), or other like materials; and then etching the second electrode 2510 to form an electrode cavity 2511 and to remove portion 2511 from the second electrode to form a top metal 2520. Further, the top metal 2520 is physically coupled to the first electrode 1720 through electrode contact via 2410.

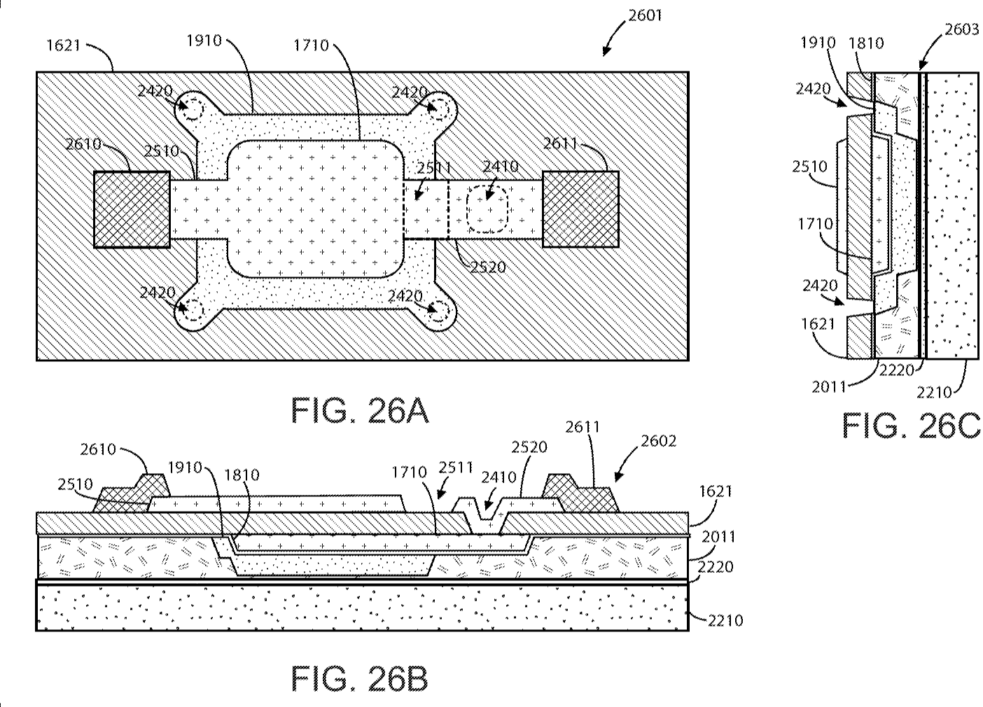

FIGS. 26A-26C (devices 2601 to 2603, respectively) are simplified diagrams illustrating various cross-sectional views of a single crystal acoustic resonator device and of method steps for a transfer process using a sacrificial layer for single crystal acoustic resonator devices according to an example of the present invention. As shown, these figures illustrate the method step of forming a first contact metal 2610 overlying a portion of the second electrode 2510 and a portion of the piezoelectric film 1621, and forming a second contact metal 2611 overlying a portion of the top metal 2520 and a portion of the piezoelectric film 1621. In an example, the first and second contact metals can include gold (Au), aluminum (Al), copper (Cu), nickel (Ni), aluminum bronze (A1Cu), or related alloys of these materials or other like materials.

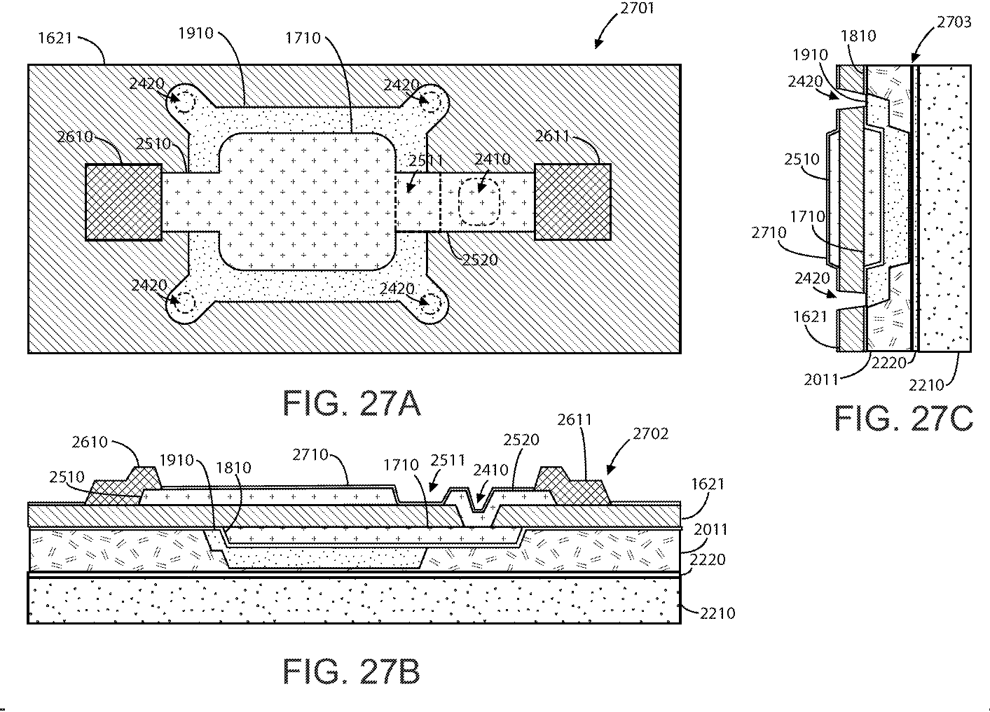

FIGS. 27A-27C (devices 2701 to 2703, respectively) are simplified diagrams illustrating various cross-sectional views of a single crystal acoustic resonator device and of method steps for a transfer process using a sacrificial layer for single crystal acoustic resonator devices according to an example of the present invention. As shown, these figures illustrate the method step of forming a second passivation layer 2710 overlying the second electrode 2510, the top metal 2520, and the piezoelectric film 1621. In an example, the second passivation layer 2710 can include silicon nitride (SiN), silicon oxide (SiO), or other like materials. In a specific example, the second passivation layer 2710 can have a thickness ranging from about 50 nm to about 100 nm.

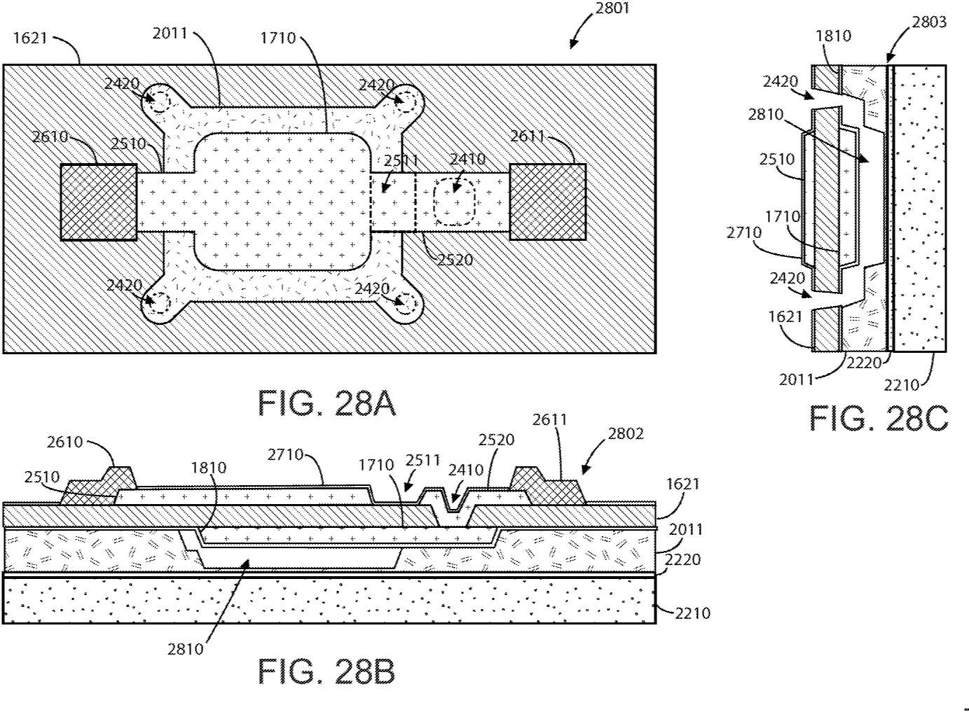

FIGS. 28A-28C (devices 2801 to 2803, respectively) are simplified diagrams illustrating various cross-sectional views of a single crystal acoustic resonator device and of method steps for a transfer process using a sacrificial layer for single crystal acoustic resonator devices according to an example of the present invention. As shown, these figures illustrate the method step of removing the sacrificial layer 1910 to form an air cavity 2810. In an example, the removal process can include a poly-Si etch or an a-Si etch, or the like.

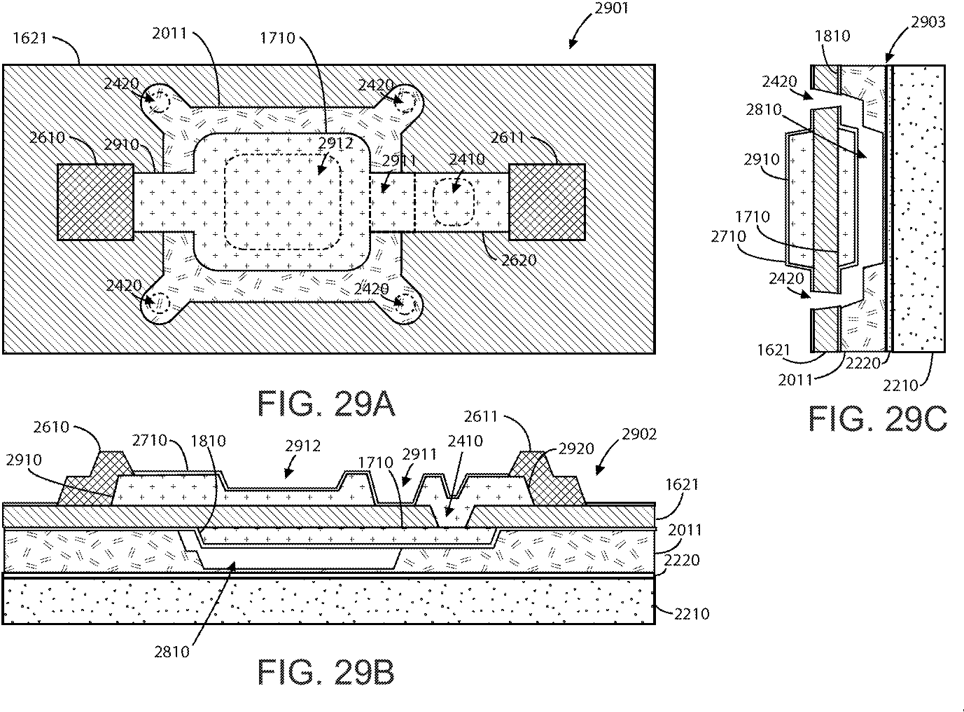

FIGS. 29A-29C (devices 2901 to 2903, respectively) are simplified diagrams illustrating various cross-sectional views of a single crystal acoustic resonator device and of method steps for a transfer process using a sacrificial layer for single crystal acoustic resonator devices according to another example of the present invention. As shown, these figures illustrate the method step of processing the second electrode 2510 and the top metal 2520 to form a processed second electrode 2910 and a processed top metal 2920. This step can follow the formation of second electrode 2510 and top metal 2520. In an example, the processing of these two components includes depositing molybdenum (Mo), ruthenium (Ru), tungsten (W), or other like materials; and then etching (e.g., dry etch or the like) this material to form the processed second electrode 2910 with an electrode cavity 2912 and the processed top metal 2920. The processed top metal 2920 remains separated from the processed second electrode 2910 by the removal of portion 2911. In a specific example, the processed second electrode 2910 is characterized by the addition of an energy confinement structure configured on the processed second electrode 2910 to increase Q.

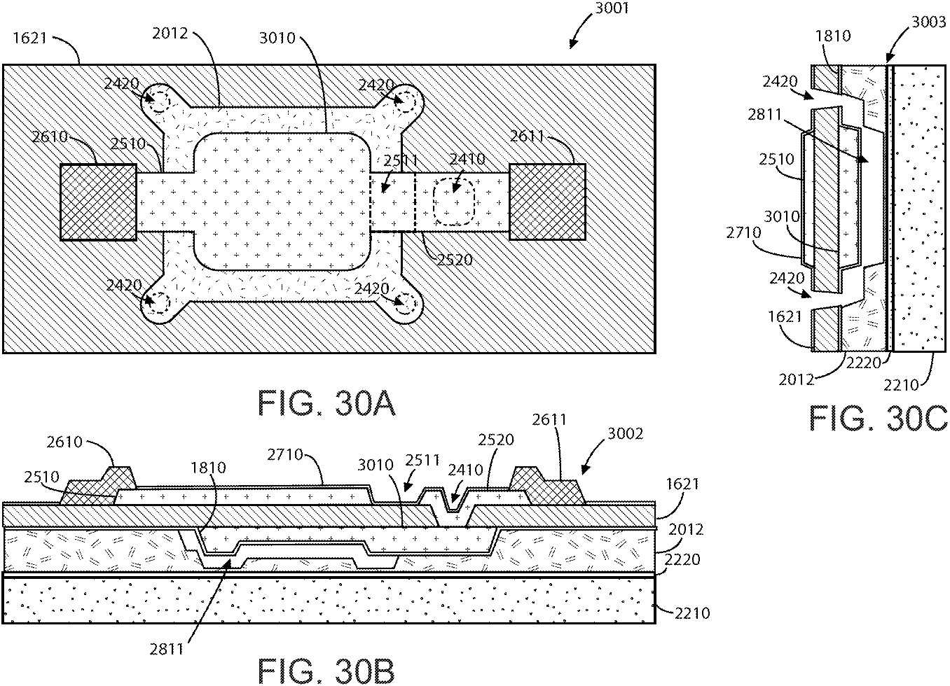

FIGS. 30A-30C (devices 3001 to 3003, respectively) are simplified diagrams illustrating various cross-sectional views of a single crystal acoustic resonator device and of method steps for a transfer process using a sacrificial layer for single crystal acoustic resonator devices according to another example of the present invention. As shown, these figures illustrate the method step of processing the first electrode 1710 to form a processed first electrode 2310. This step can follow the formation of first electrode 1710. In an example, the processing of these two components includes depositing molybdenum (Mo), ruthenium (Ru), tungsten (W), or other like materials; and then etching (e.g., dry etch or the like) this material to form the processed first electrode 3010 with an electrode cavity, similar to the processed second electrode 2910. Air cavity 2811 shows the change in cavity shape due to the processed first electrode 3010. In a specific example, the processed first electrode 3010 is characterized by the addition of an energy confinement structure configured on the processed second electrode 3010 to increase Q.

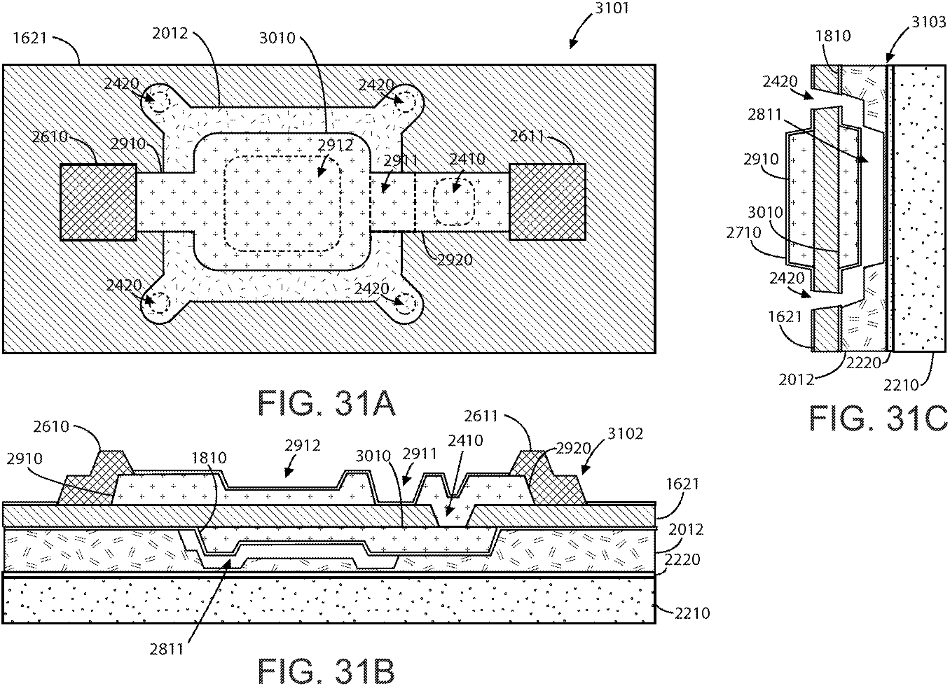

FIGS. 31A-31C (devices 3101 to 3103, respectively) are simplified diagrams illustrating various cross-sectional views of a single crystal acoustic resonator device and of method steps for a transfer process using a sacrificial layer for single crystal acoustic resonator devices according to another example of the present invention. As shown, these figures illustrate the method step of processing the first electrode 1710, to form a processed first electrode 2310, and the second electrode 2510/top metal 2520 to form a processed second electrode 2910/processed top metal 2920. These steps can follow the formation of each respective electrode, as described for FIGS. 29A-29C and 30A-30C. Those of ordinary skill in the art will recognize other variations, modifications, and alternatives.

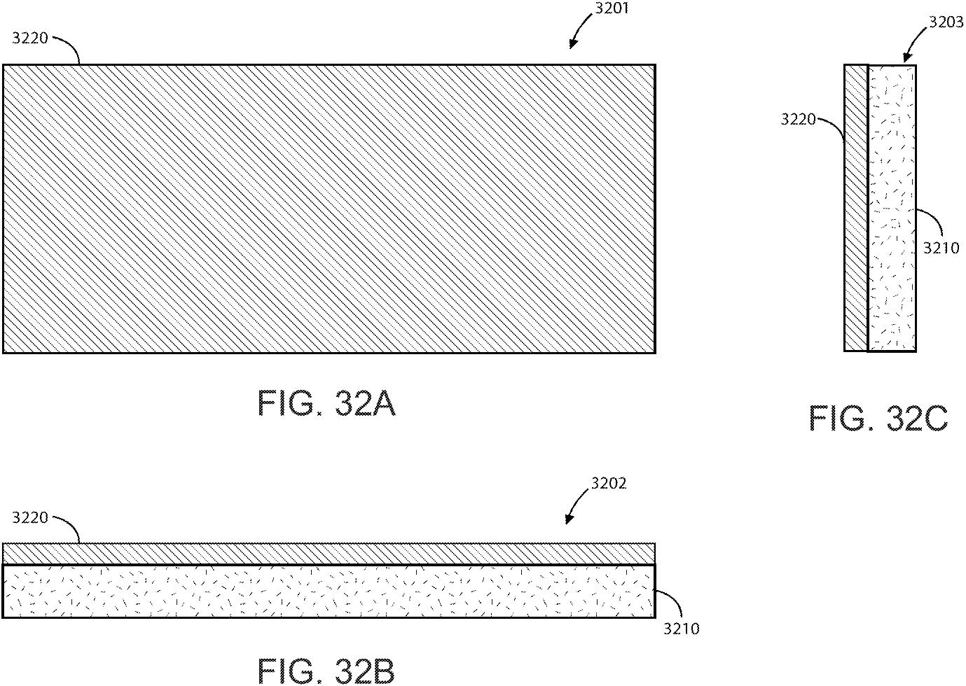

FIGS. 32A-32C through FIGS. 46A-46C illustrate a method of fabrication for an acoustic resonator device using a transfer structure without sacrificial layer. In these figure series described below, the “A” figures show simplified diagrams illustrating top cross-sectional views of single crystal resonator devices according to various embodiments of the present invention. The “B” figures show simplified diagrams illustrating lengthwise cross-sectional views of the same devices in the “A” figures. Similarly, the “C” figures show simplified diagrams illustrating widthwise cross-sectional views of the same devices in the “A” figures. In some cases, certain features are omitted to highlight other features and the relationships between such features. Those of ordinary skill in the art will recognize variations, modifications, and alternatives to the examples shown in these figure series.

FIGS. 32A-32C (devices 3201 to 3203, respectively) are simplified diagrams illustrating various cross-sectional views of a single crystal acoustic resonator device and of method steps for a transfer process for single crystal acoustic resonator devices according to an example of the present invention. As shown, these figures illustrate the method step of forming a piezoelectric film 3220 overlying a growth substrate 3210. In an example, the growth substrate 3210 can include silicon (S), silicon carbide (SiC), or other like materials. The piezoelectric film 3220 can be an epitaxial film including aluminum nitride (A1N), gallium nitride (GaN), or other like materials. Additionally, this piezoelectric substrate can be subjected to a thickness trim.

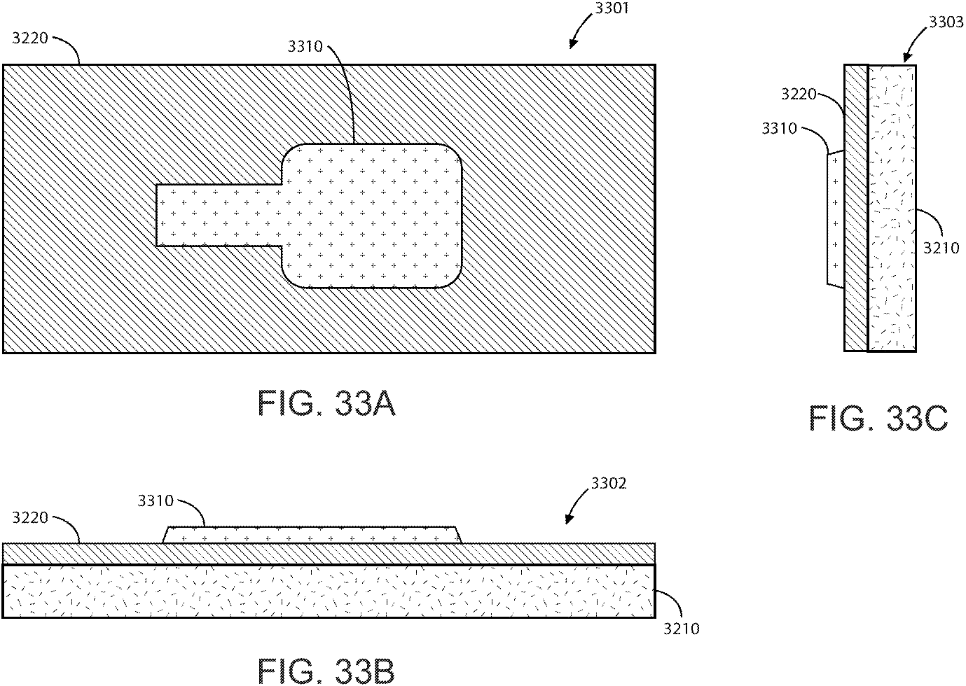

FIGS. 33A-33C (devices 3301 to 3303, respectively) are simplified diagrams illustrating various cross-sectional views of a single crystal acoustic resonator device and of method steps for a transfer process for single crystal acoustic resonator devices according to an example of the present invention. As shown, these figures illustrate the method step of forming a first electrode 3310 overlying the surface region of the piezoelectric film 3220. In an example, the first electrode 3310 can include molybdenum (Mo), ruthenium (Ru), tungsten (W), or other like materials. In a specific example, the first electrode 3310 can be subjected to a dry etch with a slope. As an example, the slope can be about 60 degrees.

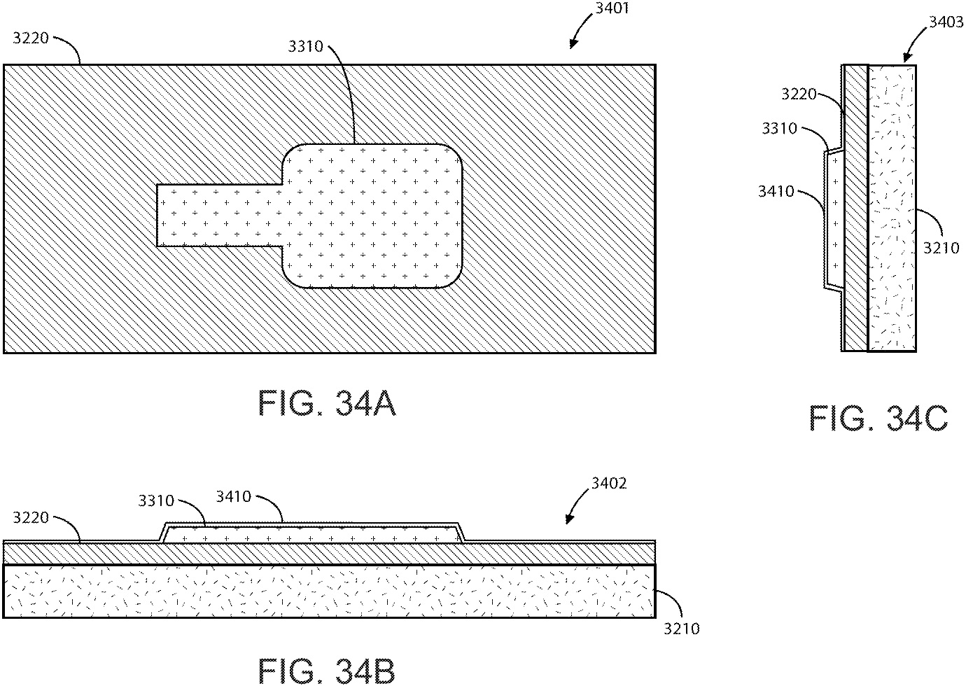

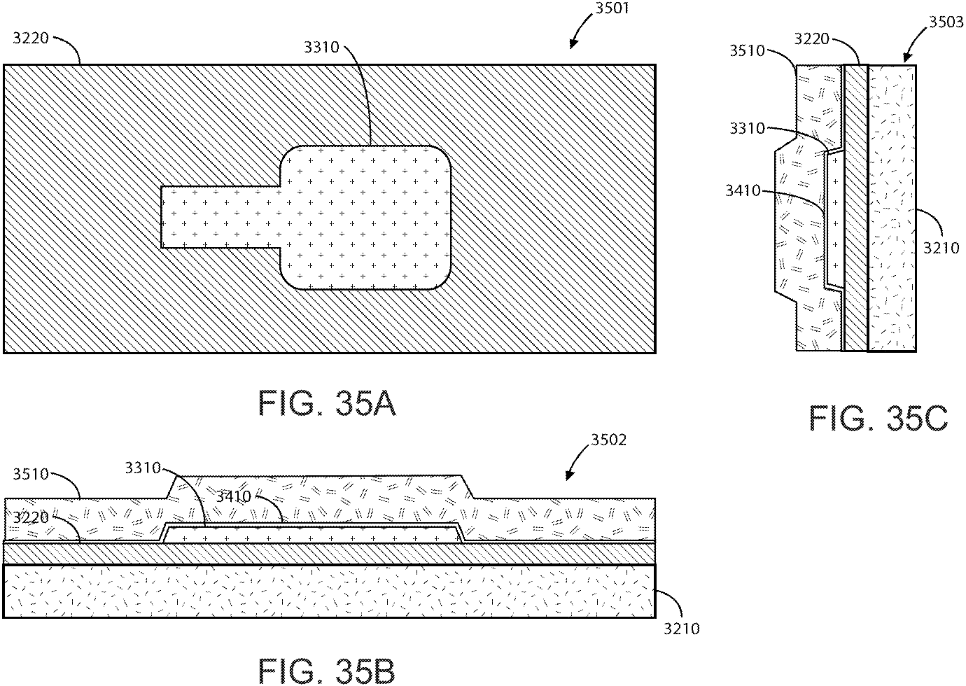

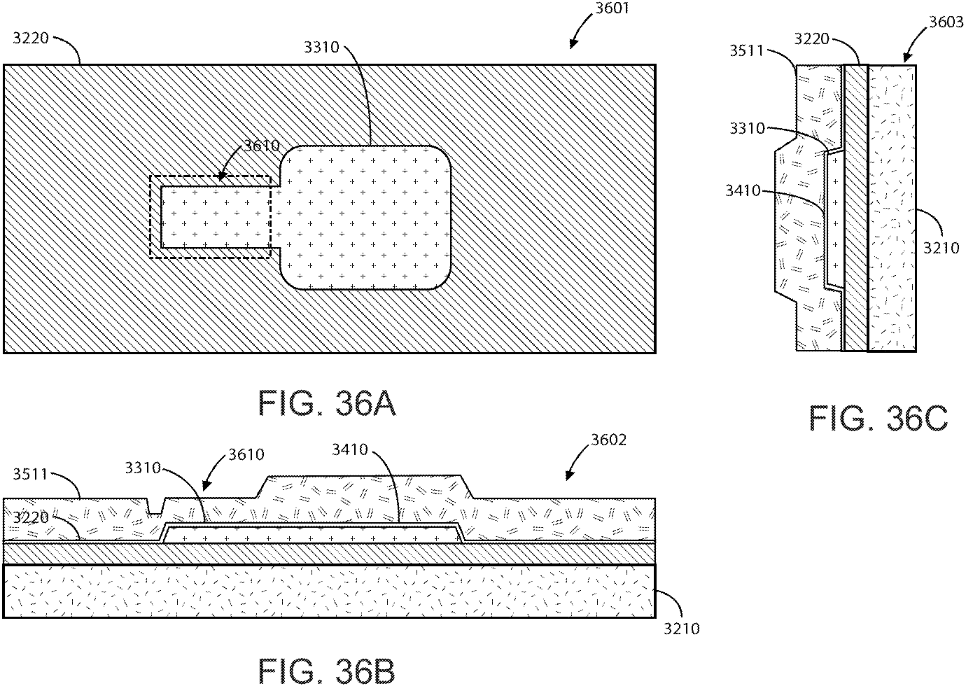

FIGS. 34A-34C (devices 3401 to 3403, respectively) are simplified diagrams illustrating various cross-sectional views of a single crystal acoustic resonator device and of method steps for a transfer process for single crystal acoustic resonator devices according to an example of the present invention. As shown, these figures illustrate the method step of forming a first passivation layer 3410 overlying the first electrode 3310 and the piezoelectric film 3220. In an example, the first passivation layer 3410 can include silicon nitride (SiN), silicon oxide (SiO), or other like materials. In a specific example, the first passivation layer 3410 can have a thickness ranging from about 50 nm to about 100 nm.

FIGS. 35A-35C (devices 3501 to 3503, respectively) are simplified diagrams illustrating various cross-sectional views of a single crystal acoustic resonator device and of method steps for a transfer process for single crystal acoustic resonator devices according to an example of the present invention. As shown, these figures illustrate the method step of forming a support layer 3510 overlying the first electrode 3310, and the piezoelectric film 3220. In an example, the support layer 3510 can include silicon dioxide (SiO₂), silicon nitride (SiN), or other like materials. In a specific example, this support layer 3510 can be deposited with a thickness of about 2-3 um. As described above, other support layers (e.g., SiNx) can be used in the case of a PSG sacrificial layer.

FIGS. 36A-36C (devices 3601 to 3603, respectively) are simplified diagrams illustrating various cross-sectional views of a single crystal acoustic resonator device and of method steps for a transfer process for single crystal acoustic resonator devices according to an example of the present invention. As shown, these figures illustrate the optional method step of processing the support layer 3510 (to form support layer 3511) in region 3610. In an example, the processing can include a partial etch of the support layer 3510 to create a flat bond surface. In a specific example, the processing can include a cavity region. In other examples, this step can be replaced with a polishing process such as a chemical-mechanical planarization process or the like.

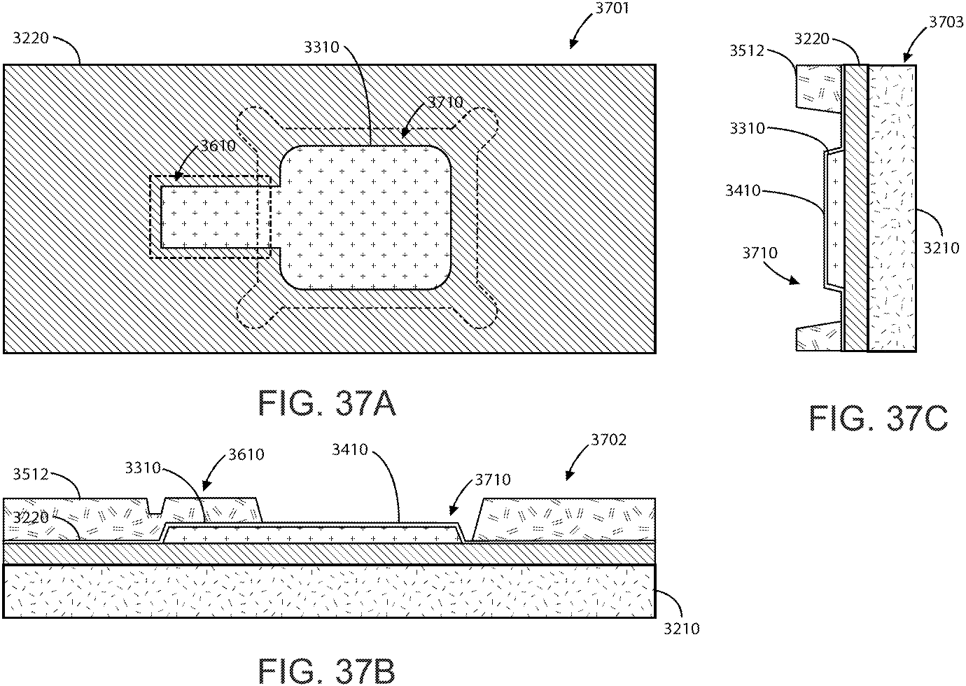

FIGS. 37A-37C (devices 3701 to 3703, respectively) are simplified diagrams illustrating various cross-sectional views of a single crystal acoustic resonator device and of method steps for a transfer process for single crystal acoustic resonator devices according to an example of the present invention. As shown, these figures illustrate the method step of forming an air cavity 3710 within a portion of the support layer 3511 (to form support layer 3512). In an example, the cavity formation can include an etching process that stops at the first passivation layer 3410.

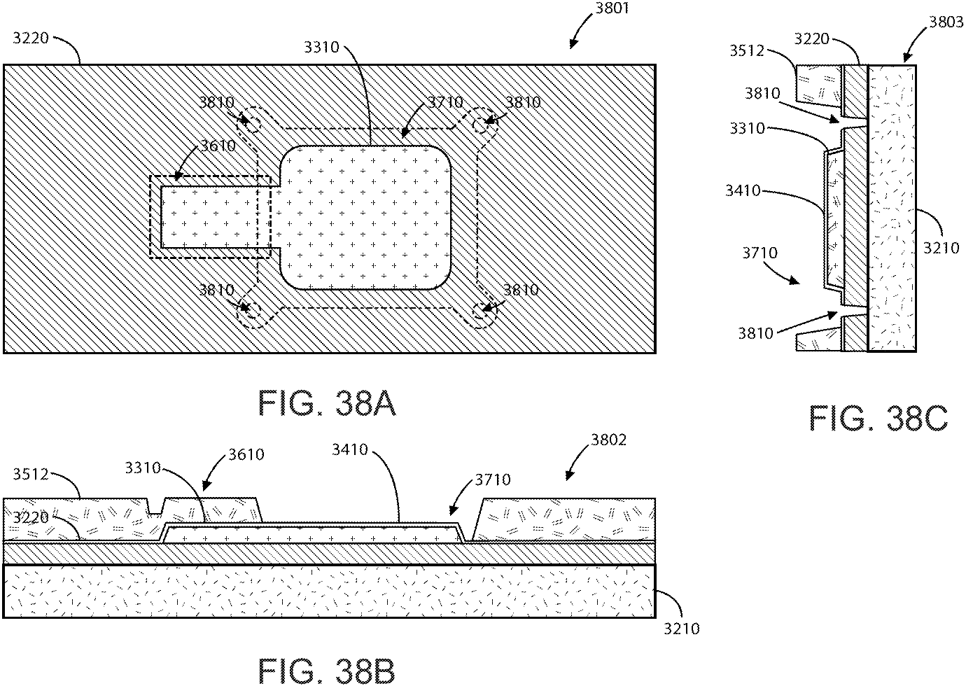

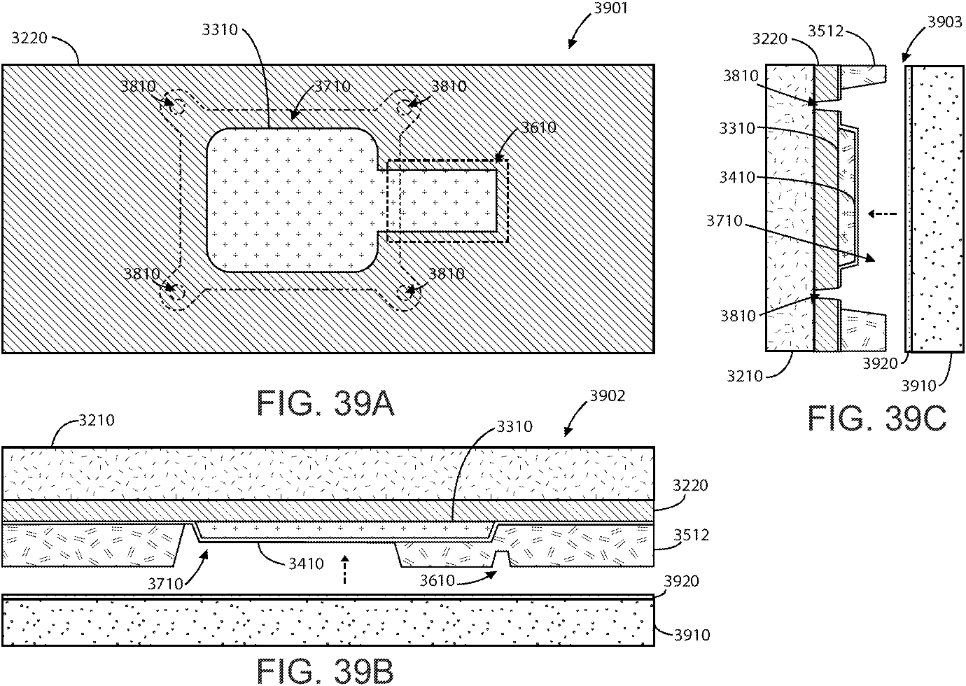

FIGS. 38A-38C (devices 3901 to 3903, respectively) are simplified diagrams illustrating various cross-sectional views of a single crystal acoustic resonator device and of method steps for a transfer process for single crystal acoustic resonator devices according to an example of the present invention. As shown, these figures illustrate the method step of forming one or more cavity vent holes 3810 within a portion of the piezoelectric film 3220 through the first passivation layer 3410. In an example, the cavity vent holes 3810 connect to the air cavity 3710.

FIGS. 39A-39C (devices 3901 to 3903, respectively) are simplified diagrams illustrating various cross-sectional views of a single crystal acoustic resonator device and of method steps for a transfer process for single crystal acoustic resonator devices according to an example of the present invention. As shown, these figures illustrate flipping the device and physically coupling overlying the support layer 3512 overlying a bond substrate 3910. In an example, the bond substrate 3910 can include a bonding support layer 3920 (SiO₂ or like material) overlying a substrate having silicon (Si), sapphire (A1₂O₃), silicon dioxide (SiO₂), silicon carbide (SiC), or other like materials. In a specific embodiment, the bonding support layer 3920 of the bond substrate 3910 is physically coupled to the polished support layer 3512. Further, the physical coupling process can include a room temperature bonding process following by a 300 degree Celsius annealing process.

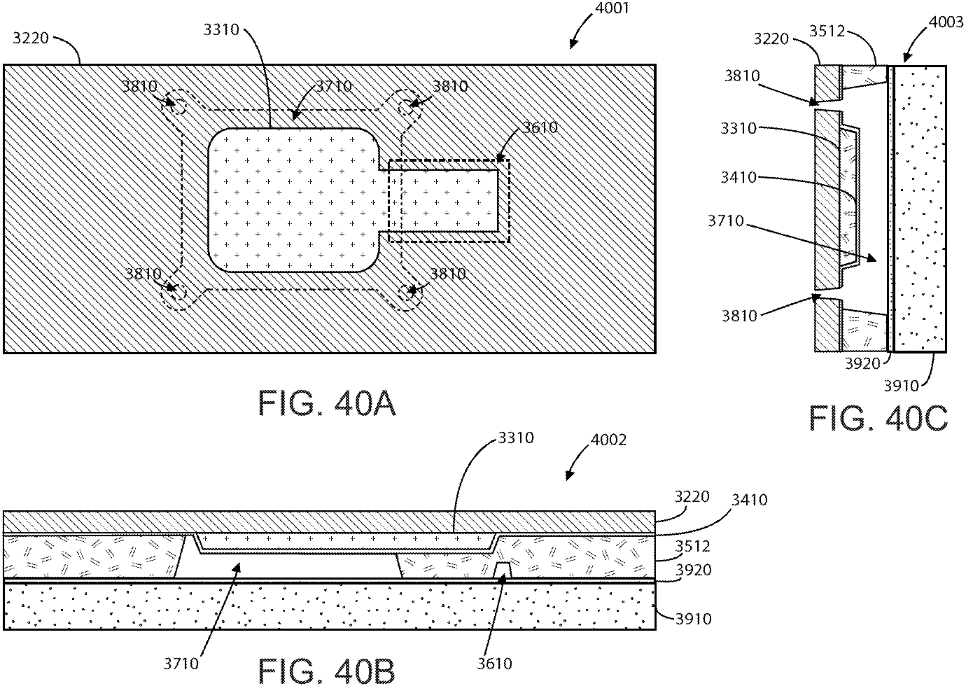

FIGS. 40A-40C (devices 4001 to 4003, respectively) are simplified diagrams illustrating various cross-sectional views of a single crystal acoustic resonator device and of method steps for a transfer process for single crystal acoustic resonator devices according to an example of the present invention. As shown, these figures illustrate the method step of removing the growth substrate 3210 or otherwise the transfer of the piezoelectric film 3220. In an example, the removal process can include a grinding process, a blanket etching process, a film transfer process, an ion implantation transfer process, a laser crack transfer process, or the like and combinations thereof.

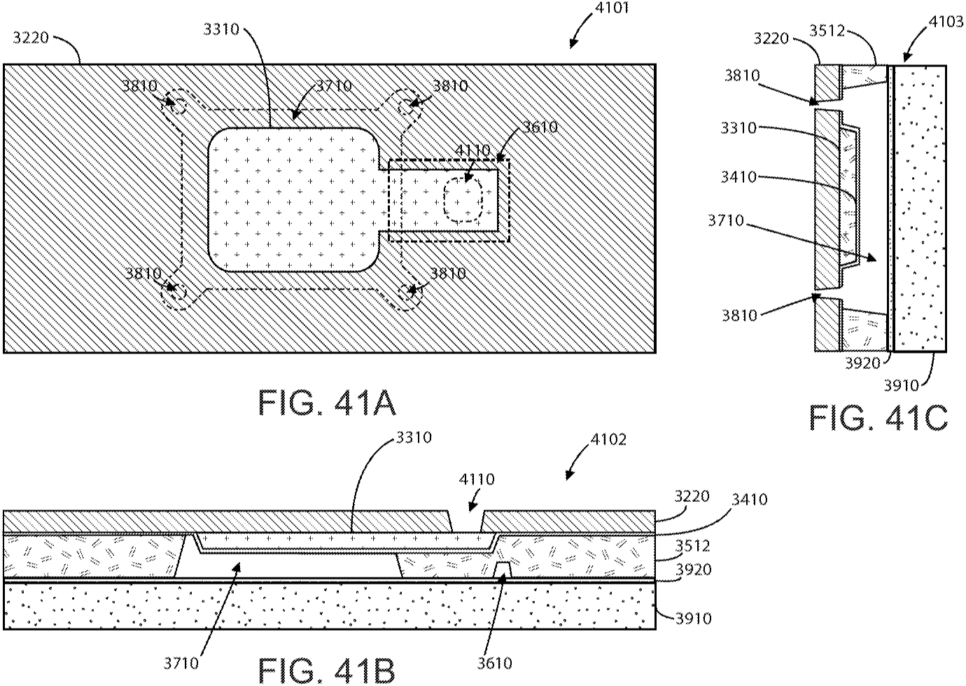

FIGS. 41A-41C (devices 4101 to 4103, respectively) are simplified diagrams illustrating various cross-sectional views of a single crystal acoustic resonator device and of method steps for a transfer process for single crystal acoustic resonator devices according to an example of the present invention. As shown, these figures illustrate the method step of forming an electrode contact via 4110 within the piezoelectric film 3220 overlying the first electrode 3310. The via forming processes can include various types of etching processes.

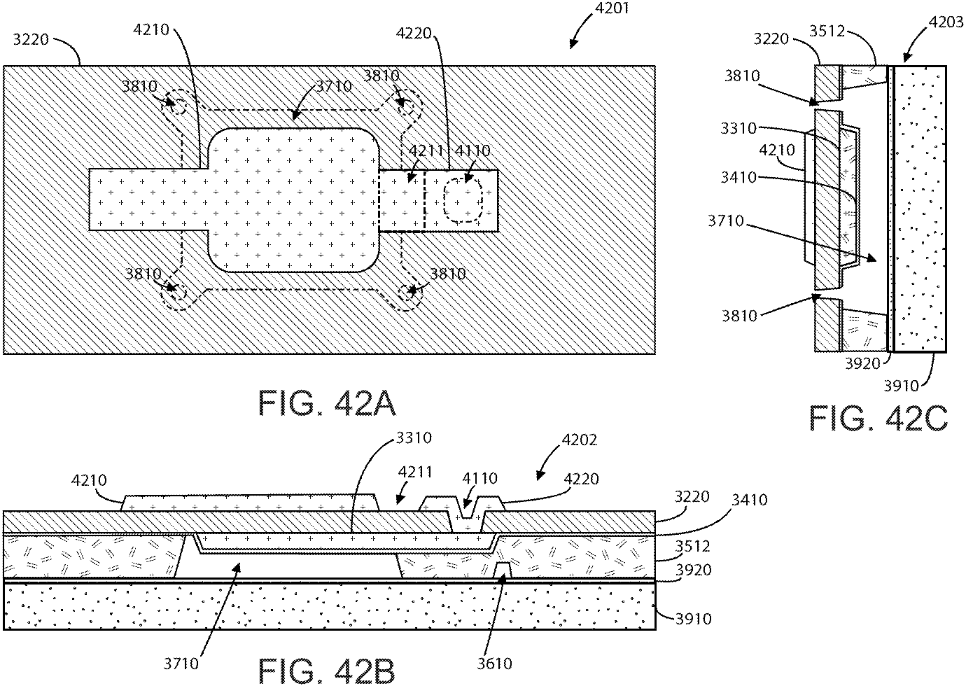

FIGS. 42A-42C (devices 4201 to 4203, respectively) are simplified diagrams illustrating various cross-sectional views of a single crystal acoustic resonator device and of method steps for a transfer process for single crystal acoustic resonator devices according to an example of the present invention. As shown, these figures illustrate the method step of forming a second electrode 4210 overlying the piezoelectric film 3220. In an example, the formation of the second electrode 4210 includes depositing molybdenum (Mo), ruthenium (Ru), tungsten (W), or other like materials; and then etching the second electrode 4210 to form an electrode cavity 4211 and to remove portion 4211 from the second electrode to form a top metal 4220. Further, the top metal 4220 is physically coupled to the first electrode 3310 through electrode contact via 4110.

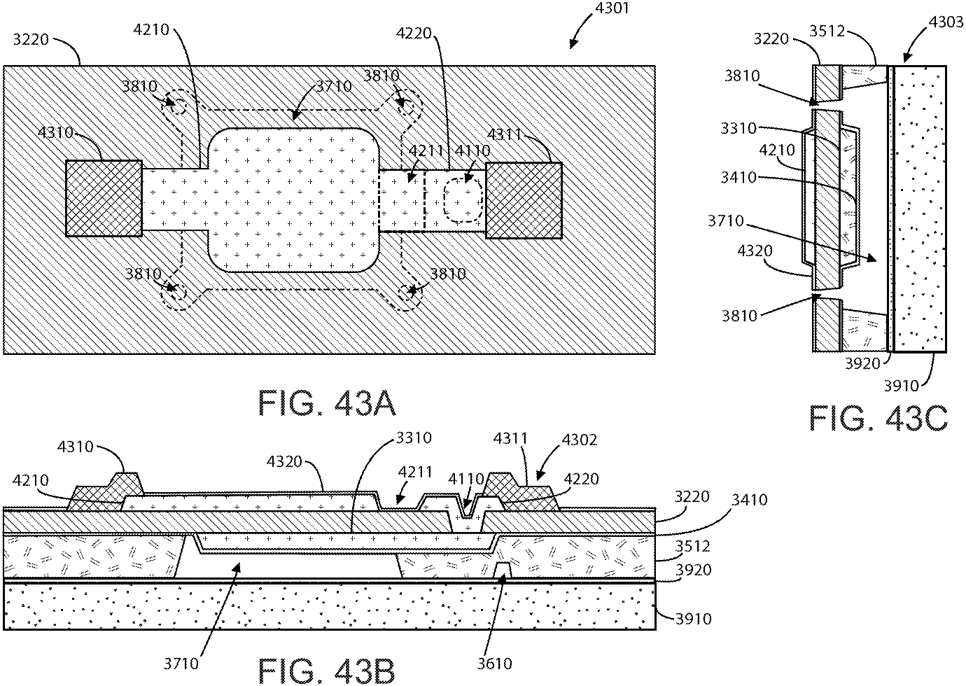

FIGS. 43A-43C (devices 4301 to 4303, respectively) are simplified diagrams illustrating various cross-sectional views of a single crystal acoustic resonator device and of method steps for a transfer process for single crystal acoustic resonator devices according to an example of the present invention. As shown, these figures illustrate the method step of forming a first contact metal 4310 overlying a portion of the second electrode 4210 and a portion of the piezoelectric film 3220, and forming a second contact metal 4311 overlying a portion of the top metal 4220 and a portion of the piezoelectric film 3220. In an example, the first and second contact metals can include gold (Au), aluminum (Al), copper (Cu), nickel (Ni), aluminum bronze (AlCu), or other like materials. This figure also shows the method step of forming a second passivation layer 4320 overlying the second electrode 4210, the top metal 4220, and the piezoelectric film 3220. In an example, the second passivation layer 4320 can include silicon nitride (SiN), silicon oxide (SiO), or other like materials. In a specific example, the second passivation layer 4320 can have a thickness ranging from about 50 nm to about 100 nm.

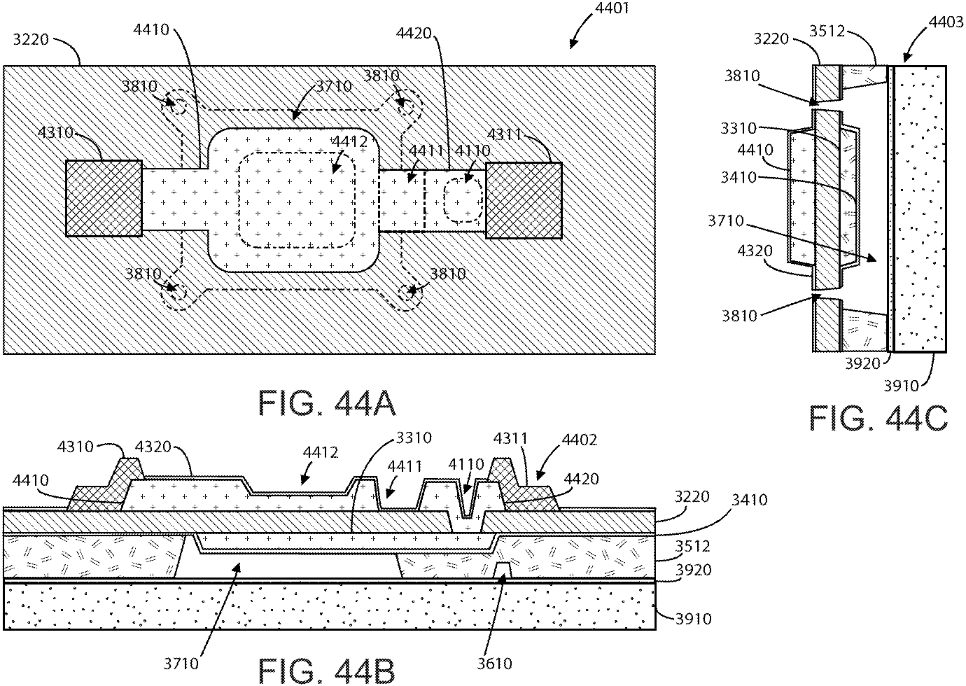

FIGS. 44A-44C (devices 4401 to 4403, respectively) are simplified diagrams illustrating various cross-sectional views of a single crystal acoustic resonator device and of method steps for a transfer process for single crystal acoustic resonator devices according to another example of the present invention. As shown, these figures illustrate the method step of processing the second electrode 4210 and the top metal 4220 to form a processed second electrode 4410 and a processed top metal 4420. This step can follow the formation of second electrode 4210 and top metal 4220. In an example, the processing of these two components includes depositing molybdenum (Mo), ruthenium (Ru), tungsten (W), or other like materials; and then etching (e.g., dry etch or the like) this material to form the processed second electrode 4410 with an electrode cavity 4412 and the processed top metal 4420. The processed top metal 4420 remains separated from the processed second electrode 4410 by the removal of portion 4411. In a specific example, the processed second electrode 4410 is characterized by the addition of an energy confinement structure configured on the processed second electrode 4410 to increase Q.

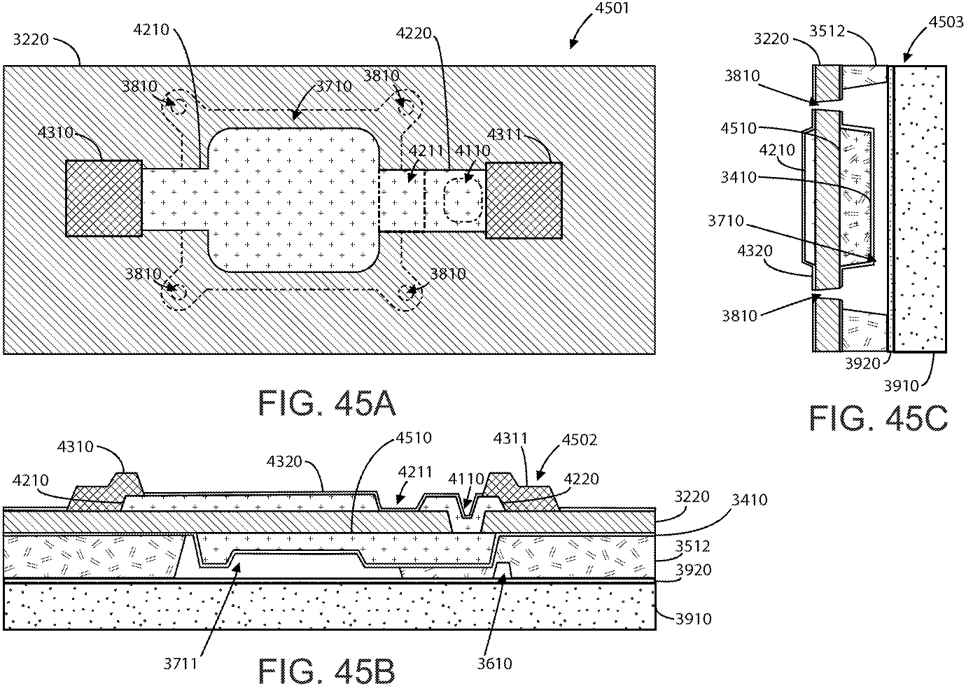

FIGS. 45A-45C (devices 4501 to 4503, respectively) are simplified diagrams illustrating various cross-sectional views of a single crystal acoustic resonator device and of method steps for a transfer process using a sacrificial layer for single crystal acoustic resonator devices according to another example of the present invention. As shown, these figures illustrate the method step of processing the first electrode 3310 to form a processed first electrode 4510. This step can follow the formation of first electrode 3310. In an example, the processing of these two components includes depositing molybdenum (Mo), ruthenium (Ru), tungsten (W), or other like materials; and then etching (e.g., dry etch or the like) this material to form the processed first electrode 4510 with an electrode cavity, similar to the processed second electrode 4410. Air cavity 3711 shows the change in cavity shape due to the processed first electrode 4510. In a specific example, the processed first electrode 4510 is characterized by the addition of an energy confinement structure configured on the processed second electrode 4510 to increase Q.

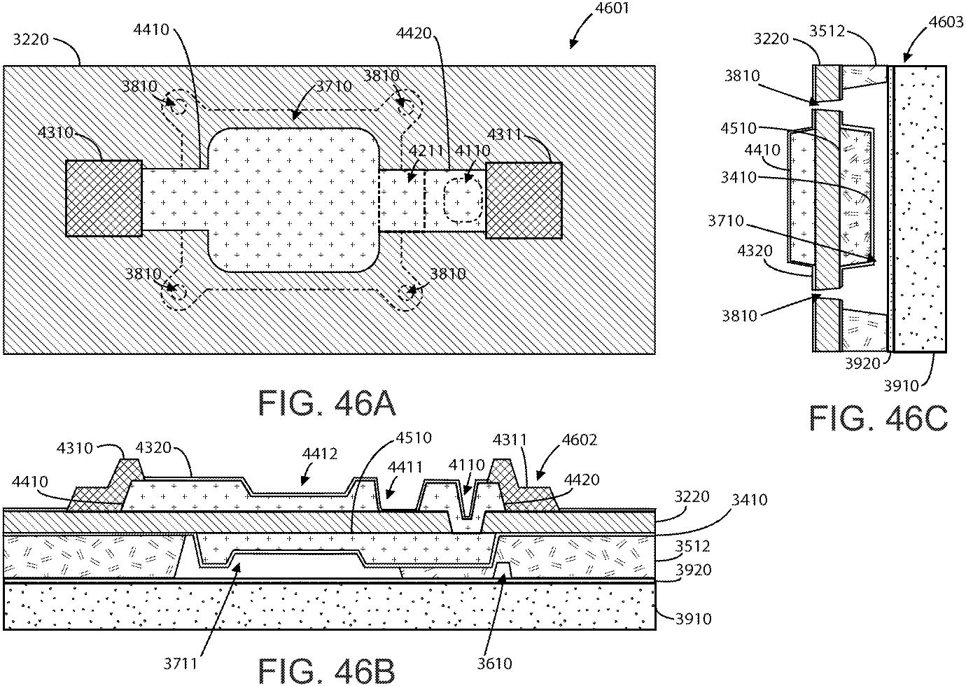

FIGS. 46A-46C (devices 4601 to 4603, respectively) are simplified diagrams illustrating various cross-sectional views of a single crystal acoustic resonator device and of method steps for a transfer process using a sacrificial layer for single crystal acoustic resonator devices according to another example of the present invention. As shown, these figures illustrate the method step of processing the first electrode 3310, to form a processed first electrode 4510, and the second electrode 4210/top metal 4220 to form a processed second electrode 4410/processed top metal 4420. These steps can follow the formation of each respective electrode, as described for FIGS. 44A-44C and 45A-45C. Those of ordinary skill in the art will recognize other variations, modifications, and alternatives.

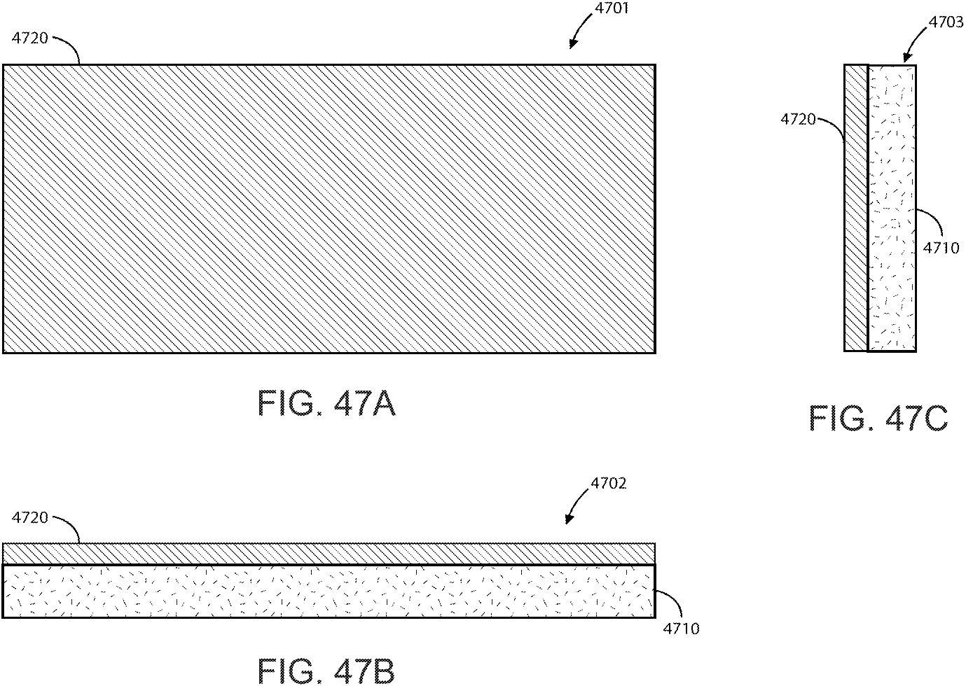

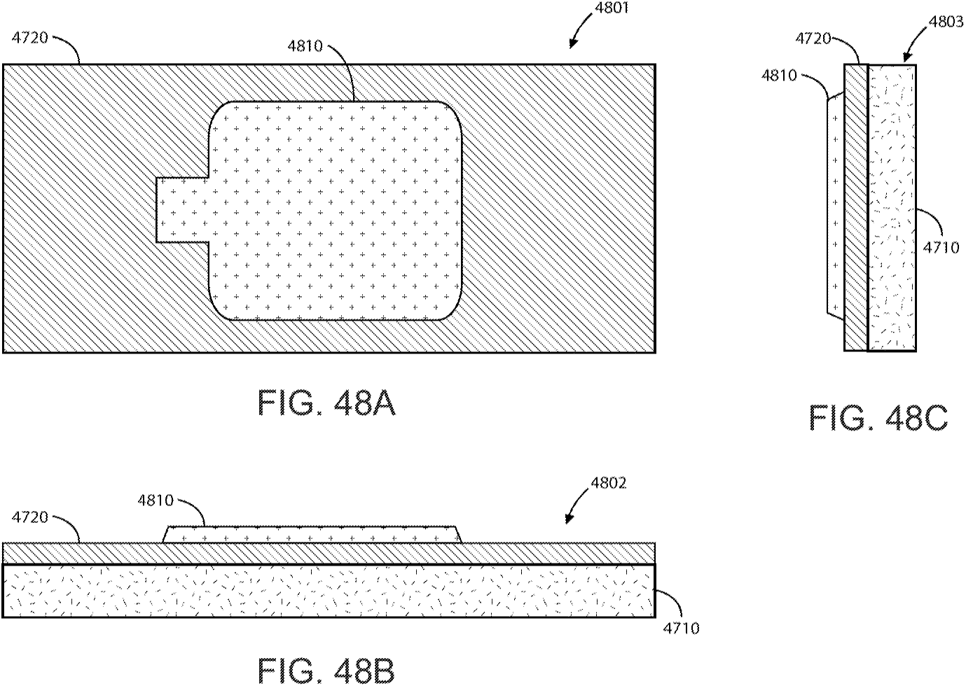

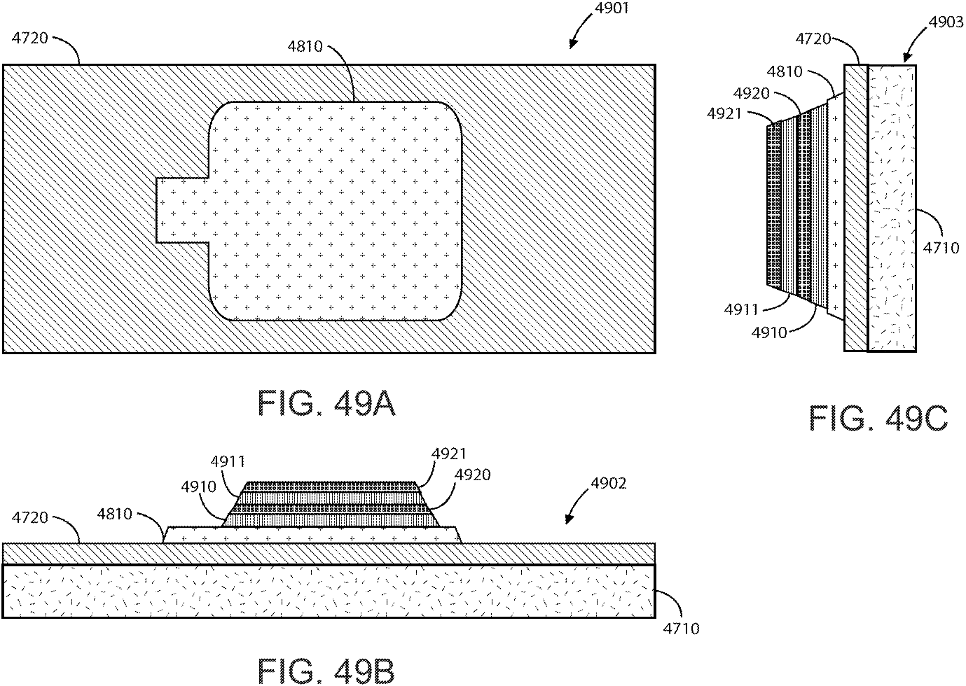

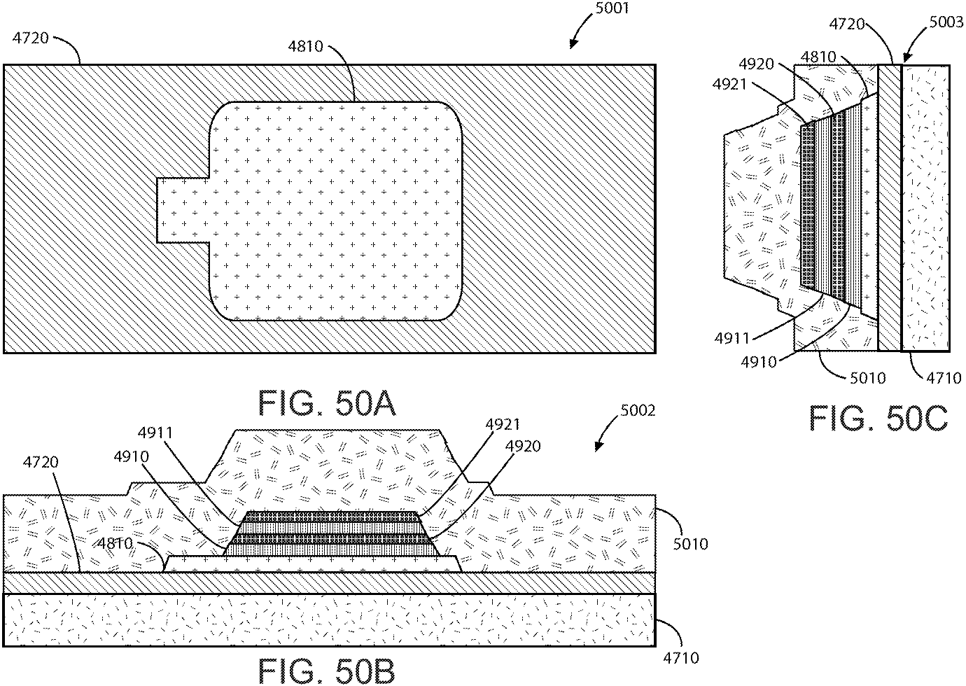

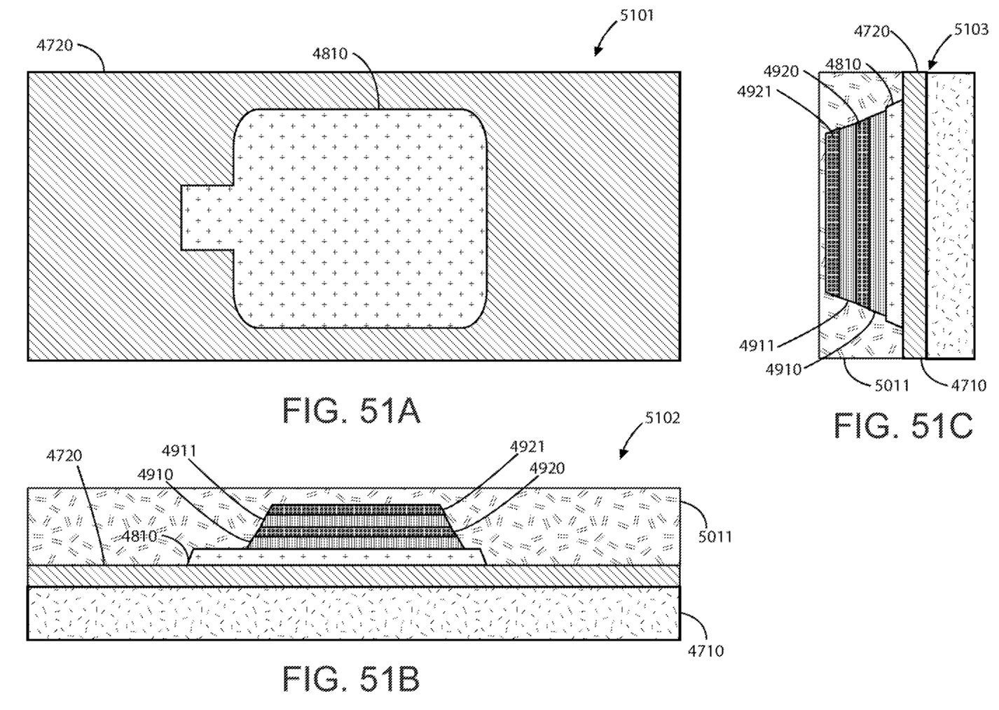

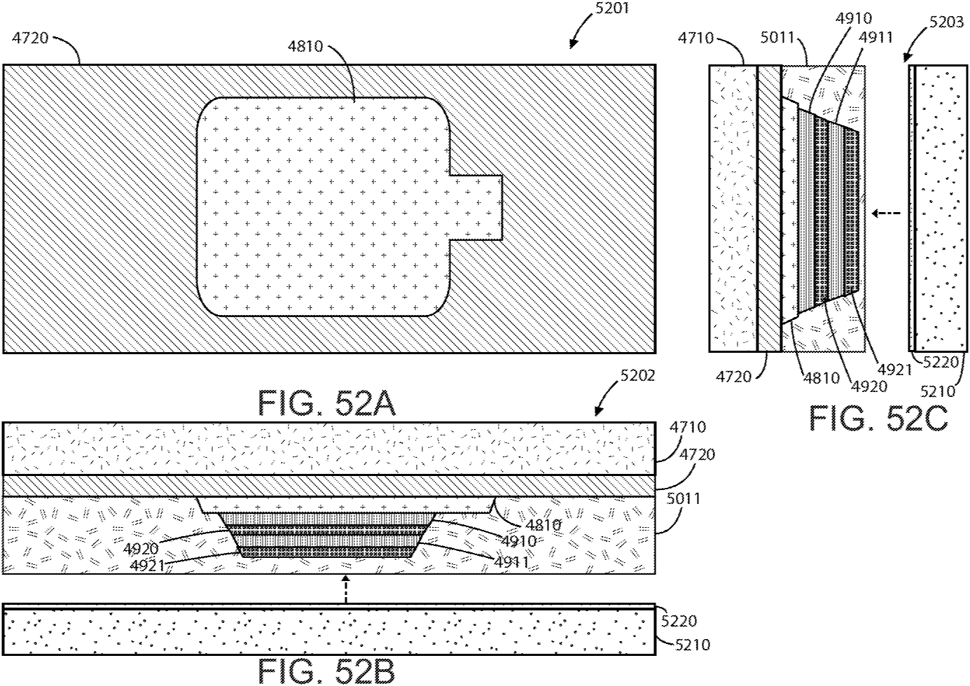

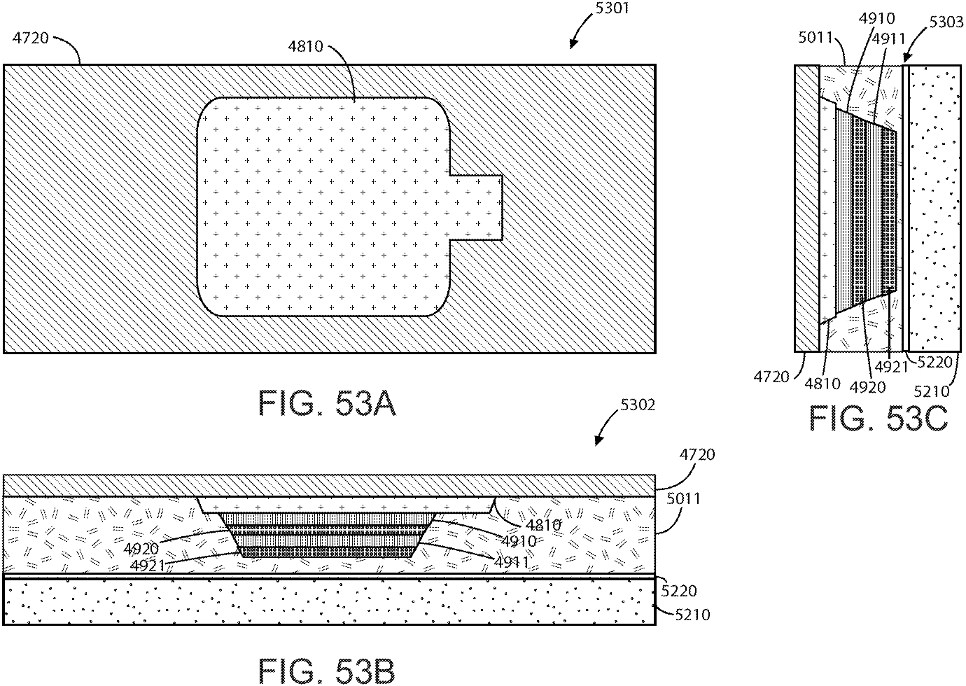

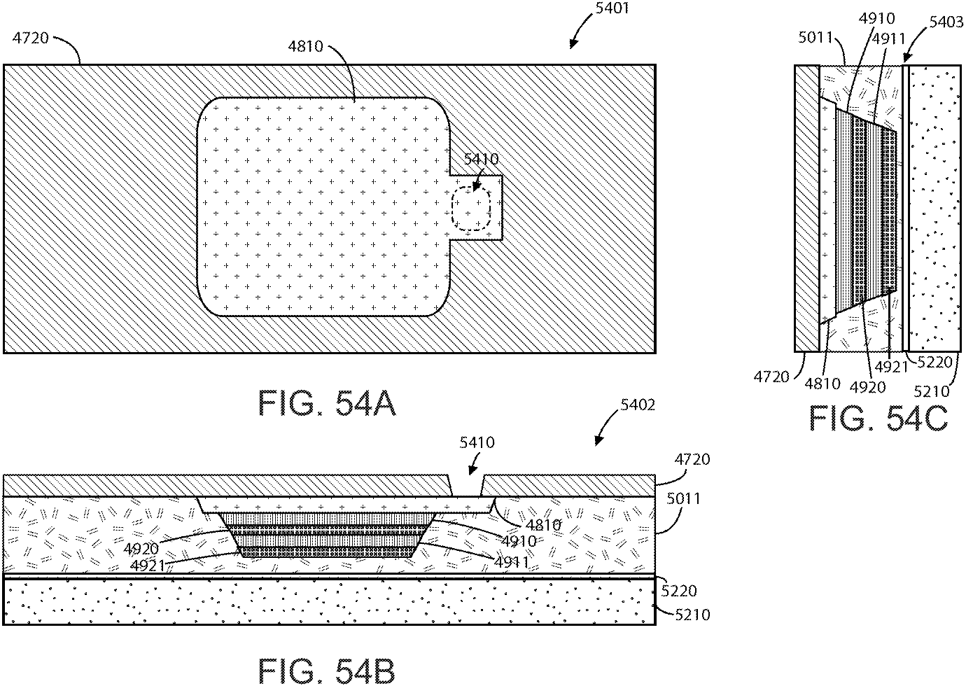

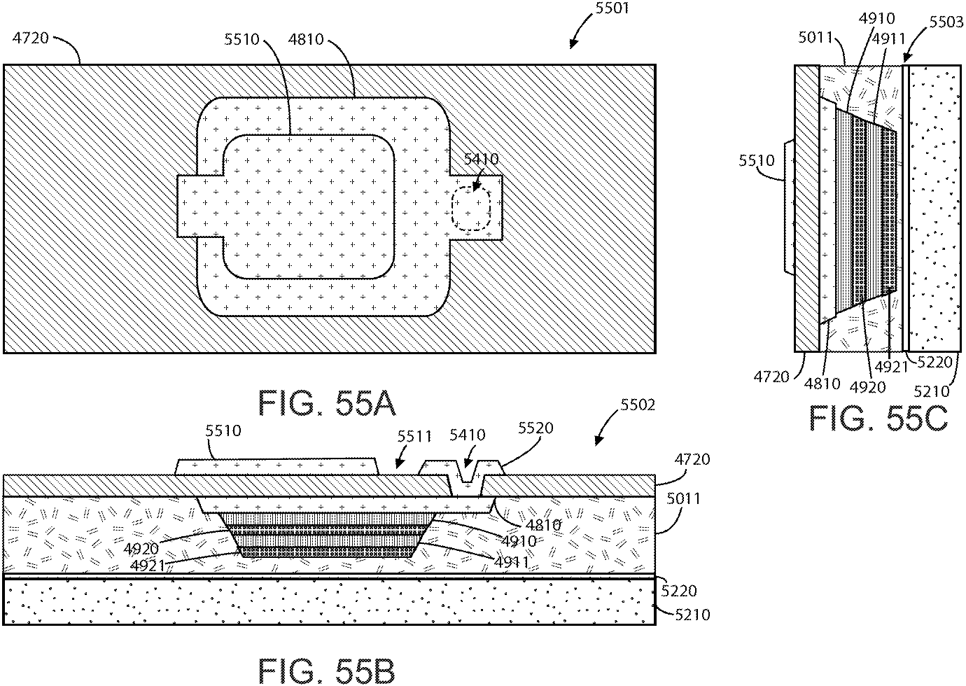

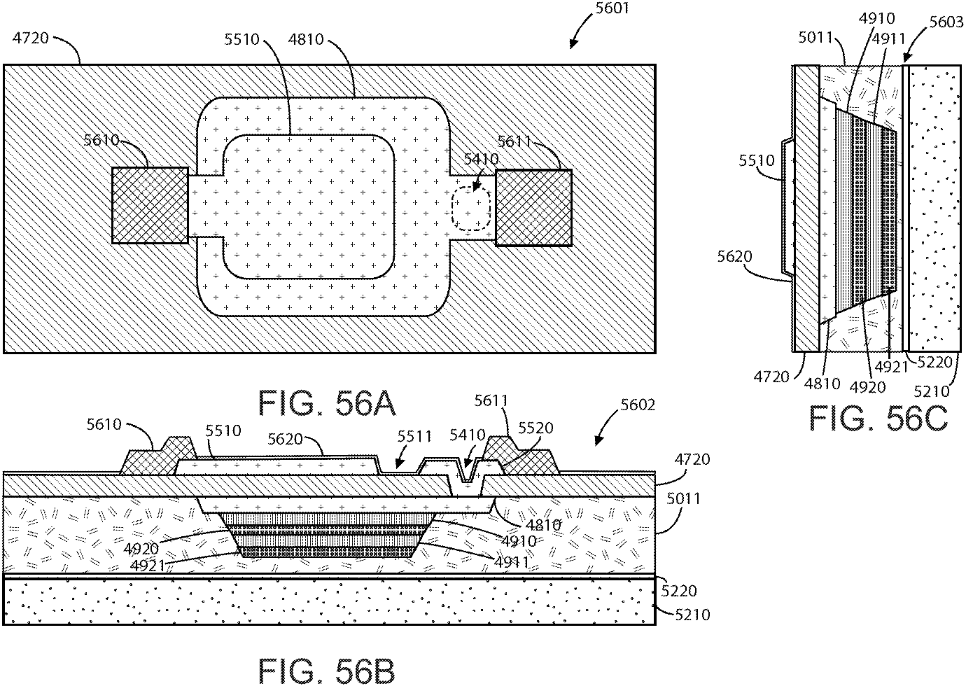

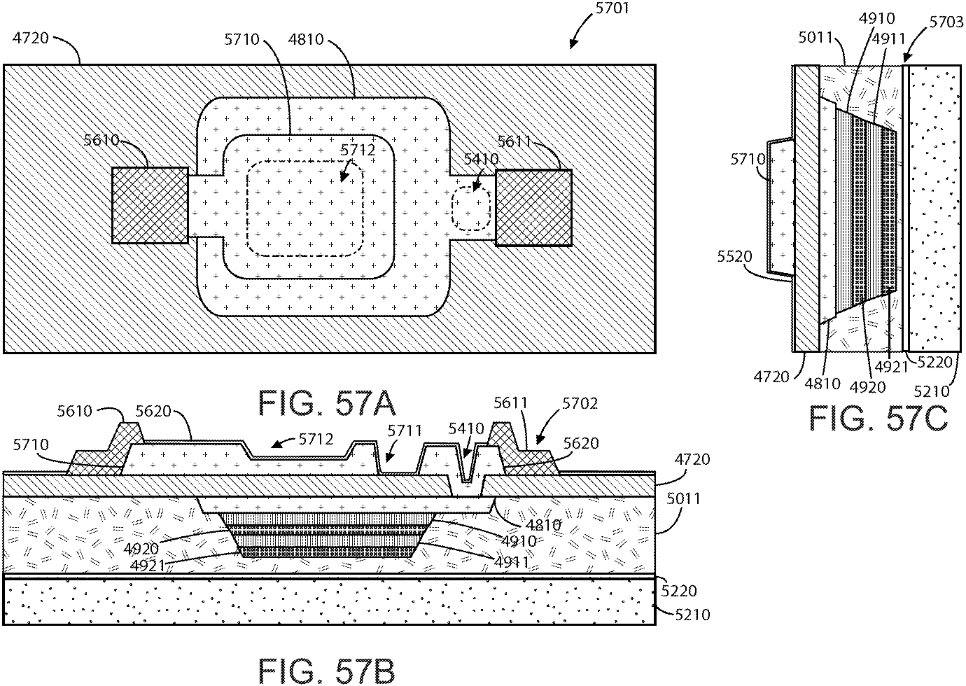

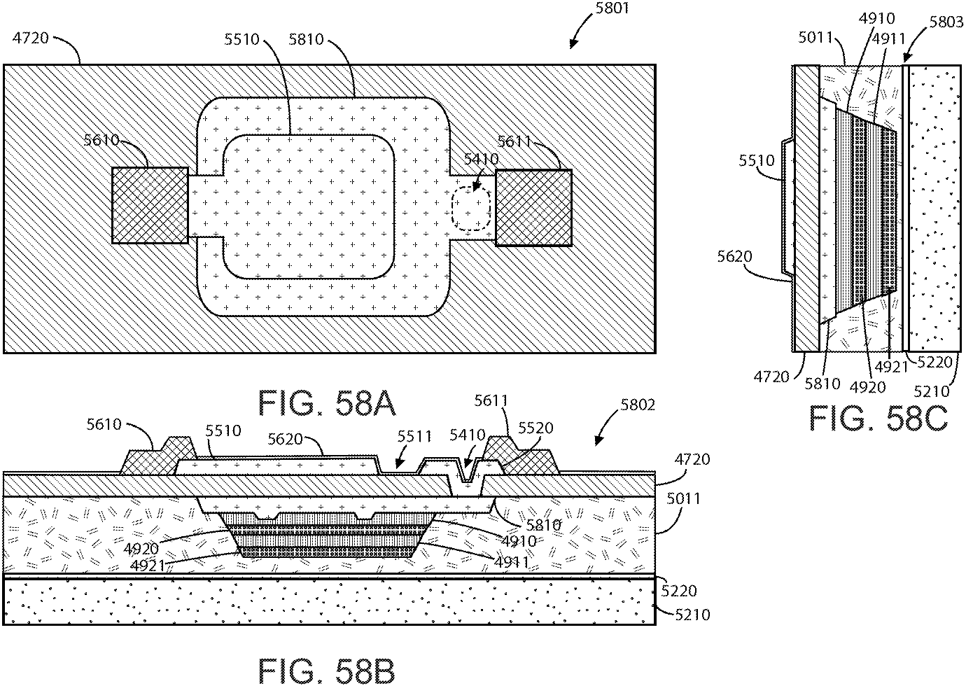

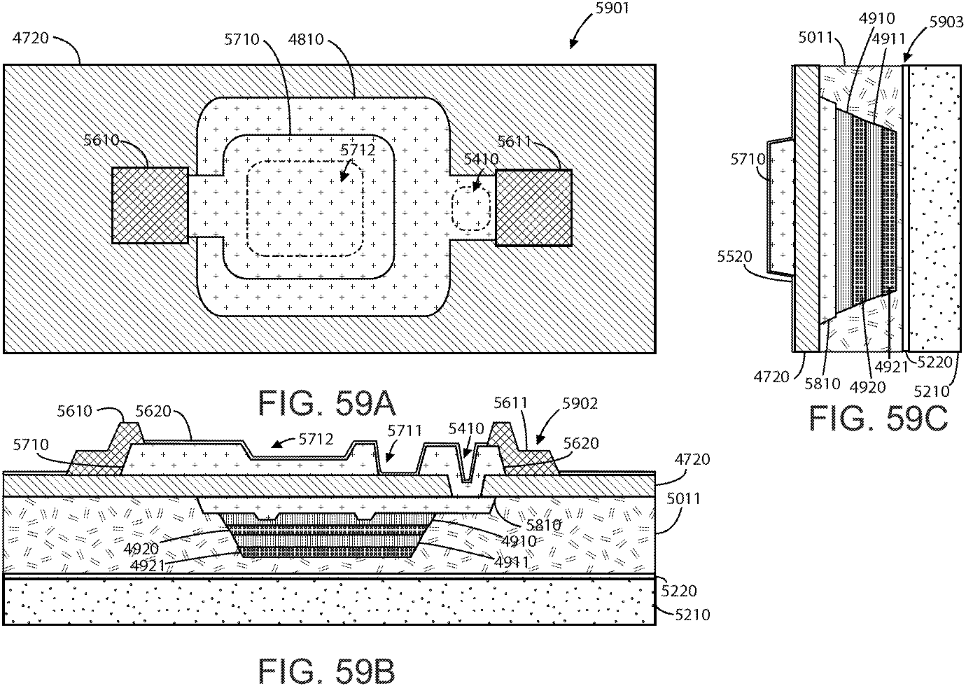

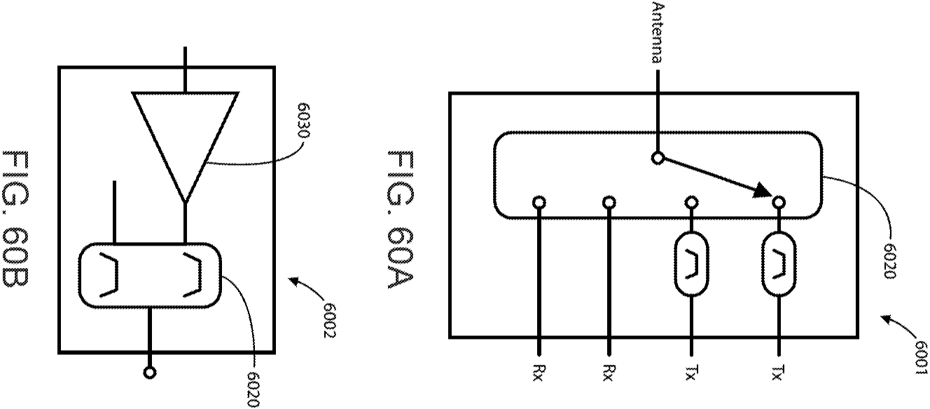

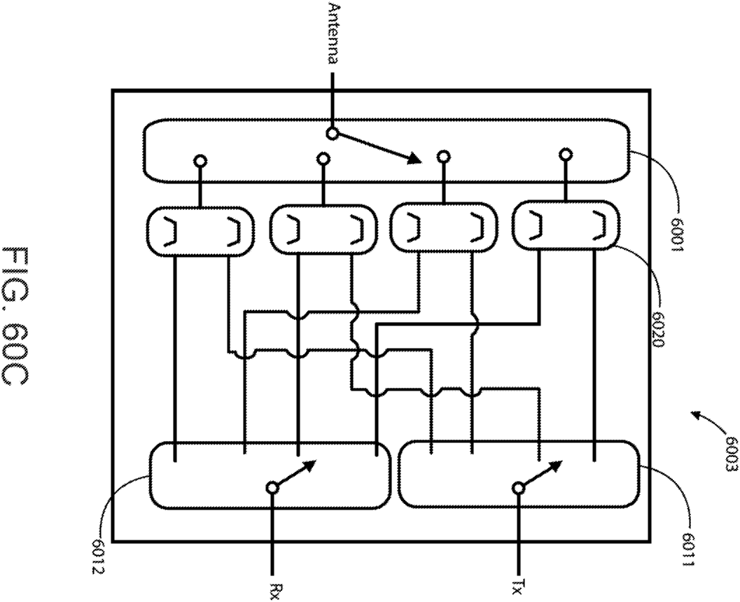

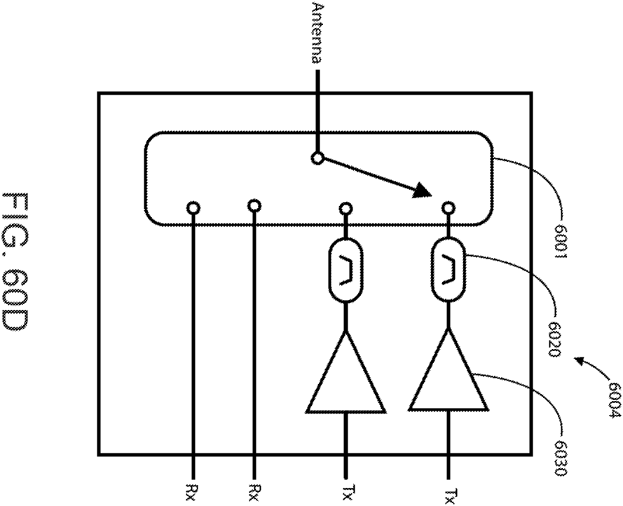

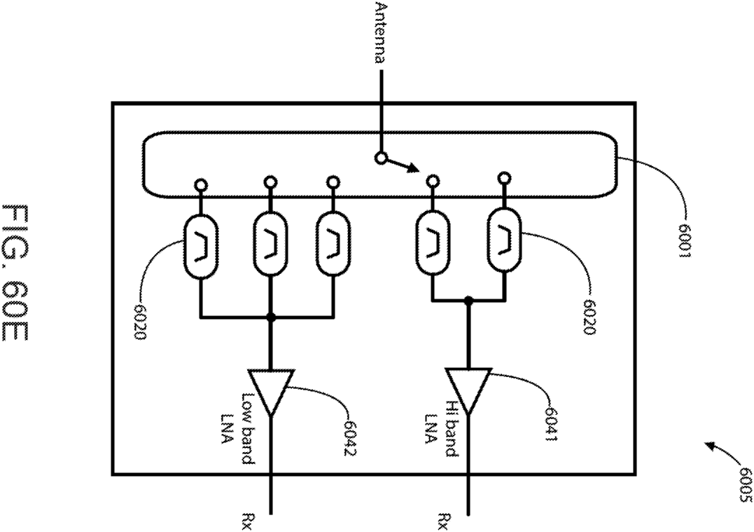

FIGS. 47A-47C through FIGS. 59A-59C illustrate a method of fabrication for an acoustic resonator device using a transfer structure with a multilayer mirror structure. In these figure series described below, the “A” figures show simplified diagrams illustrating top cross-sectional views of single crystal resonator devices according to various embodiments of the present invention. The “B” figures show simplified diagrams illustrating lengthwise cross-sectional views of the same devices in the “A” figures. Similarly, the “C” figures show simplified diagrams illustrating widthwise cross-sectional views of the same devices in the “A” figures. In some cases, certain features are omitted to highlight other features and the relationships between such features. Those of ordinary skill in the art will recognize variations, modifications, and alternatives to the examples shown in these figure series.

FIGS. 47A-47C (devices 4701 to 4703, respectively) are simplified diagrams illustrating various cross-sectional views of a single crystal acoustic resonator device and of method steps for a transfer process with a multilayer mirror for single crystal acoustic resonator devices according to an example of the present invention. As shown, these figures illustrate the method step of forming a piezoelectric film 4720 overlying a growth substrate 4710. In an example, the growth substrate 4710 can include silicon (S), silicon carbide (SiC), or other like materials. The piezoelectric film 4720 can be an epitaxial film including aluminum nitride (A1N), gallium nitride (GaN), or other like materials. Additionally, this piezoelectric substrate can be subjected to a thickness trim.

FIGS. 48A-48C (devices 4801 to 4803, respectively) are simplified diagrams illustrating various cross-sectional views of a single crystal acoustic resonator device and of method steps for a transfer process with a multilayer mirror for single crystal acoustic resonator devices according to an example of the present invention. As shown, these figures illustrate the method step of forming a first electrode 4810 overlying the surface region of the piezoelectric film 4720. In an example, the first electrode 4810 can include molybdenum (Mo), ruthenium (Ru), tungsten (W), or other like materials. In a specific example, the first electrode 4810 can be subjected to a dry etch with a slope. As an example, the slope can be about 60 degrees.

FIGS. 49A-49C (devices 4901 to 4903, respectively) are simplified diagrams illustrating various cross-sectional views of a single crystal acoustic resonator device and of method steps for a transfer process with a multilayer mirror for single crystal acoustic resonator devices according to an example of the present invention. As shown, these figures illustrate the method step of forming a multilayer mirror or reflector structure. In an example, the multilayer mirror includes at least one pair of layers with a low impedance layer 4910 and a high impedance layer 4920. In FIGS. 49A-49C, two pairs of low/high impedance layers are shown (low: 4910 and 4911; high: 4920 and 4921). In an example, the mirror/reflector area can be larger than the resonator area and can encompass the resonator area. In a specific embodiment, each layer thickness is about ¼ of the wavelength of an acoustic wave at a targeting frequency. The layers can be deposited in sequence and be etched afterwards, or each layer can be deposited and etched individually. In another example, the first electrode 4810 can be patterned after the mirror structure is patterned.

FIGS. 50A-50C (devices 5001 to 5003, respectively) are simplified diagrams illustrating various cross-sectional views of a single crystal acoustic resonator device and of method steps for a transfer process with a multilayer mirror for single crystal acoustic resonator devices according to an example of the present invention. As shown, these figures illustrate the method step of forming a support layer 5010 overlying the mirror structure (layers 4910, 4911, 4920, and 4921), the first electrode 4810, and the piezoelectric film 4720. In an example, the support layer 5010 can include silicon dioxide (SiO₂), silicon nitride (SiN), or other like materials. In a specific example, this support layer 5010 can be deposited with a thickness of about 2-3 um. As described above, other support layers (e.g., SiNx) can be used.

FIGS. 51A-51C (devices 5101 to 5103, respectively) are simplified diagrams illustrating various cross-sectional views of a single crystal acoustic resonator device and of method steps for a transfer process with a multilayer mirror for single crystal acoustic resonator devices according to an example of the present invention. As shown, these figures illustrate the method step of polishing the support layer 5010 to form a polished support layer 5011. In an example, the polishing process can include a chemical-mechanical planarization process or the like.

FIGS. 52A-52C (devices 5201 to 5203, respectively) are simplified diagrams illustrating various cross-sectional views of a single crystal acoustic resonator device and of method steps for a transfer process with a multilayer mirror for single crystal acoustic resonator devices according to an example of the present invention. As shown, these figures illustrate flipping the device and physically coupling overlying the support layer 5011 overlying a bond substrate 5210. In an example, the bond substrate 5210 can include a bonding support layer 5220 (SiO₂ or like material) overlying a substrate having silicon (Si), sapphire (A1₂O₃), silicon dioxide (SiO₂), silicon carbide (SiC), or other like materials. In a specific embodiment, the bonding support layer 5220 of the bond substrate 5210 is physically coupled to the polished support layer 5011. Further, the physical coupling process can include a room temperature bonding process following by a 300 degree Celsius annealing process.

FIGS. 53A-53C (devices 5301 to 5303, respectively) are simplified diagrams illustrating various cross-sectional views of a single crystal acoustic resonator device and of method steps for a transfer process with a multilayer mirror for single crystal acoustic resonator devices according to an example of the present invention. As shown, these figures illustrate the method step of removing the growth substrate 4710 or otherwise the transfer of the piezoelectric film 4720. In an example, the removal process can include a grinding process, a blanket etching process, a film transfer process, an ion implantation transfer process, a laser crack transfer process, or the like and combinations thereof.

FIGS. 54A-54C (devices 5401 to 5403, respectively) are simplified diagrams illustrating various cross-sectional views of a single crystal acoustic resonator device and of method steps for a transfer process with a multilayer mirror for single crystal acoustic resonator devices according to an example of the present invention. As shown, these figures illustrate the method step of forming an electrode contact via 5410 within the piezoelectric film 4720 overlying the first electrode 4810. The via forming processes can include various types of etching processes.

FIGS. 55A-55C (devices 5501 to 5503, respectively) are simplified diagrams illustrating various cross-sectional views of a single crystal acoustic resonator device and of method steps for a transfer process with a multilayer mirror for single crystal acoustic resonator devices according to an example of the present invention. As shown, these figures illustrate the method step of forming a second electrode 5510 overlying the piezoelectric film 4720. In an example, the formation of the second electrode 5510 includes depositing molybdenum (Mo), ruthenium (Ru), tungsten (W), or other like materials; and then etching the second electrode 5510 to form an electrode cavity 5511 and to remove portion 5511 from the second electrode to form a top metal 5520. Further, the top metal 5520 is physically coupled to the first electrode 5520 through electrode contact via 5410.

FIGS. 56A-56C (devices 5601 to 5603, respectively) are simplified diagrams illustrating various cross-sectional views of a single crystal acoustic resonator device and of method steps for a transfer process with a multilayer mirror for single crystal acoustic resonator devices according to an example of the present invention. As shown, these figures illustrate the method step of forming a first contact metal 5610 overlying a portion of the second electrode 5510 and a portion of the piezoelectric film 4720, and forming a second contact metal 5611 overlying a portion of the top metal 5520 and a portion of the piezoelectric film 4720. In an example, the first and second contact metals can include gold (Au), aluminum (Al), copper (Cu), nickel (Ni), aluminum bronze (AlCu), or other like materials. This figure also shows the method step of forming a second passivation layer 5620 overlying the second electrode 5510, the top metal 5520, and the piezoelectric film 4720. In an example, the second passivation layer 5620 can include silicon nitride (SiN), silicon oxide (SiO), or other like materials. In a specific example, the second passivation layer 5620 can have a thickness ranging from about 50 nm to about 100 nm.

FIGS. 57A-57C (devices 5701 to 5703, respectively) are simplified diagrams illustrating various cross-sectional views of a single crystal acoustic resonator device and of method steps for a transfer process with a multilayer mirror for single crystal acoustic resonator devices according to another example of the present invention. As shown, these figures illustrate the method step of processing the second electrode 5510 and the top metal 5520 to form a processed second electrode 5710 and a processed top metal 5720. This step can follow the formation of second electrode 5710 and top metal 5720. In an example, the processing of these two components includes depositing molybdenum (Mo), ruthenium (Ru), tungsten (W), or other like materials; and then etching (e.g., dry etch or the like) this material to form the processed second electrode 5410 with an electrode cavity 5712 and the processed top metal 5720. The processed top metal 5720 remains separated from the processed second electrode 5710 by the removal of portion 5711. In a specific example, this processing gives the second electrode and the top metal greater thickness while creating the electrode cavity 5712. In a specific example, the processed second electrode 5710 is characterized by the addition of an energy confinement structure configured on the processed second electrode 5710 to increase Q.

FIGS. 58A-58C (devices 5801 to 5803, respectively) are simplified diagrams illustrating various cross-sectional views of a single crystal acoustic resonator device and of method steps for a transfer process with a multilayer mirror for single crystal acoustic resonator devices according to another example of the present invention. As shown, these figures illustrate the method step of processing the first electrode 4810 to form a processed first electrode 5810. This step can follow the formation of first electrode 4810. In an example, the processing of these two components includes depositing molybdenum (Mo), ruthenium (Ru), tungsten (W), or other like materials; and then etching (e.g., dry etch or the like) this material to form the processed first electrode 5810 with an electrode cavity, similar to the processed second electrode 5710. Compared to the two previous examples, there is no air cavity. In a specific example, the processed first electrode 5810 is characterized by the addition of an energy confinement structure configured on the processed second electrode 5810 to increase Q.

FIGS. 59A-59C (devices 5901 to 5903, respectively) are simplified diagrams illustrating various cross-sectional views of a single crystal acoustic resonator device and of method steps for a transfer process with a multilayer mirror for single crystal acoustic resonator devices according to another example of the present invention. As shown, these figures illustrate the method step of processing the first electrode 4810, to form a processed first electrode 5810, and the second electrode 5510/top metal 5520 to form a processed second electrode 5710/processed top metal 5720. These steps can follow the formation of each respective electrode, as described for FIGS. 57A-57C and 58A-58C. Those of ordinary skill in the art will recognize other variations, modifications, and alternatives.

According to various examples, the present invention includes resonator and RF filter devices using both textured polycrystalline materials (deposited using PVD methods) and single crystal piezoelectric materials (grown using CVD technique upon a seed substrate). Various substrates can be used for fabricating the acoustic devices, such silicon substrates of various crystallographic orientations and the like. Additionally, the present method can use sapphire substrates, silicon carbide substrates, gallium nitride (GaN) bulk substrates, or aluminum nitride (A1N) bulk substrates. The present method can also use GaN templates, A1N templates, and AlxGa1-xN templates (where x varies between 0.0 and 1.0). These substrates and templates can have polar, non-polar, or semi-polar crystallographic orientations. Further the piezoelectric materials deposed on the substrate can include alloys selected from at least one of the following: A1N, MgHfA1N, GaN, InN, InGaN, AlInN, AlInGaN, ScAlN, ScAlGaN, ScGaN, ScN, BA1N, BAlScN, and BN.

In each of the preceding examples, the piezoelectric materials can include single crystal materials, polycrystalline materials, or combinations thereof and the like. The piezoelectric materials can also include a substantially single crystal material that exhibits certain polycrystalline qualities, i.e., an essentially single crystal material. In a specific example, the first, second, third, and fourth piezoelectric materials are each essentially a single crystal aluminum nitride (A1N) bearing material or aluminum scandium nitride (AlScN) bearing material, a single crystal gallium nitride (GaN) bearing material or gallium aluminum nitride (GaAlN) bearing material, a magnesium hafnium aluminum nitride (MgHfAlN) material, or the like. In other specific examples, these piezoelectric materials each comprise a polycrystalline aluminum nitride (A1N) bearing material or aluminum scandium nitride (AlScN) bearing material, or a polycrystalline gallium nitride (GaN) bearing material or gallium aluminum nitride (GaAlN) bearing material, a magnesium hafnium aluminum nitride (MgHfAlN) material, or the like. In other examples, the piezoelectric materials can include aluminum gallium nitride (AlₓGa₁₋ₓN) material or an aluminum scandium nitride (AlₓSc₁₋ₓN) material characterized by a composition of 0 ≤ X < 1.0. As discussed previously, the thicknesses of the piezoelectric materials can vary, and in some cases can be greater than 250 nm.

In each of the preceding examples relating to transfer processes, energy confinement structures can be formed on the first electrode, second electrode, or both. In an example, these energy confinement structures are mass loaded areas surrounding the resonator area. The resonator area is the area where the first electrode, the piezoelectric layer, and the second electrode overlap. The larger mass load in the energy confinement structures lowers a cut-off frequency of the resonator. The cut-off frequency is the lower or upper limit of the frequency at which the acoustic wave can propagate in a direction parallel to the surface of the piezoelectric film. Therefore, the cut-off frequency is the resonance frequency in which the wave is travelling along the thickness direction and thus is determined by the total stack structure of the resonator along the vertical direction. In piezoelectric films (e.g., A1N), acoustic waves with lower frequency than the cut-off frequency can propagate in a parallel direction along the surface of the film, i.e., the acoustic wave exhibits a high-band-cut-off type dispersion characteristic. In this case, the mass loaded area surrounding the resonator provides a barrier preventing the acoustic wave from propagating outside the resonator. By doing so, this feature increases the quality factor of the resonator and improves the performance of the resonator and, consequently, the filter.

In addition, the top single crystalline piezoelectric layer can be replaced by a polycrystalline piezoelectric film. In such films, the lower part that is close to the interface with the substrate has poor crystalline quality with smaller grain sizes and a wider distribution of the piezoelectric polarization orientation than the upper part of the film close to the surface. This is due to the polycrystalline growth of the piezoelectric film, i.e., the nucleation and initial film have random crystalline orientations. Considering A1N as a piezoelectric material, the growth rate along the c-axis or the polarization orientation is higher than other crystalline orientations that increase the proportion of the grains with the c-axis perpendicular to the growth surface as the film grows thicker. In a typical polycrystalline A1N film with about a 1 um thickness, the upper part of the film close to the surface has better crystalline quality and better alignment in terms of piezoelectric polarization. By using the thin film transfer process contemplated in the present invention, it is possible to use the upper portion of the polycrystalline film in high frequency BAW resonators with very thin piezoelectric films. This can be done by removing a portion of the piezoelectric layer during the growth substrate removal process. Of course, there can be other variations, modifications, and alternatives.

In an example, the present invention provides a method of manufacture and structure of a monolithic single-chip single crystal device. The monolithic design uses a common single crystal material layer stack to integrate both passive and active device elements in a single chip. This design can be applied to a variety of device components, such single crystal bulk acoustic resonators, filters, power amplifiers (PAs), switches, low noise amplifiers (LNAs), and the like. These components can be integrated as a mobile wireless front-end module (FEM) or other type of FEM. In a specific example, this monolithic single-chip single crystal device can be a single crystal III-nitride single chip integrated front end module (SCIFEM). Furthermore, a CMOS based controller chip can be integrated into a package with the SCIFEM chip to provide a complete communications RF FEM.

FIGS. 60A through 60E are simplified circuit diagrams illustrating various monolithic single chip single crystal devices according various examples of the present invention. FIG. 60A shows an antenna switch module 6001, which monolithically integrates a series of switches 6010. FIG. 60B shows a PA duplexer (PAD) 6002, which monolithically integrates a filter 6020 and a PA 6030. FIG. 60C shows a switched duplexer bank 6003, which monolithically integrates an antenna switch module 6001, filters 6020, a transmit switch module 6011, and a receive switch module 6012. FIG. 60D shows a transmit module 6004, which monolithically integrates an antenna switch module 6001, filters 6020, and PAs 6030. FIG. 60E shows a receive diversity module 6005, which monolithically integrates filters 6020, an antenna switch module 6001, a high band LNA 6041 and a low band LNA 6042. These are merely examples, and those of ordinary skill in the art will recognize other variations, modifications, and alternatives.

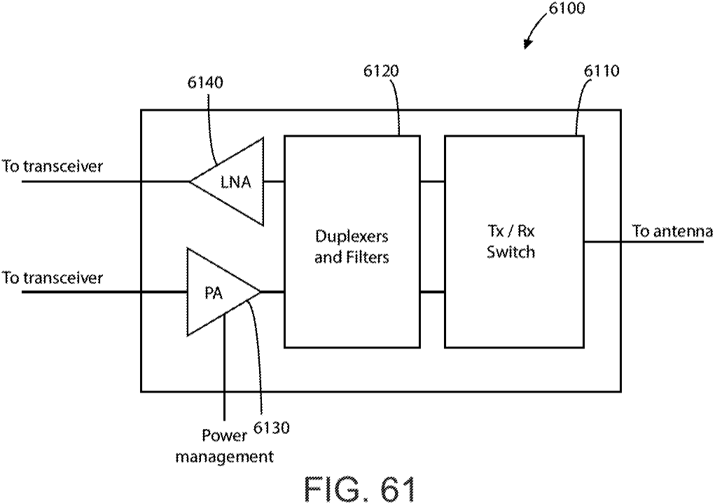

FIG. 61 shows a monolithically integrated system 6100 with an LNA 6140 and a PA 6130 coupled to duplexers and filters 6120, which are coupled to transmit and receive switches 6110. These integrated components can include those that were described in FIGS. 61A-61E. Of course, there can be other variations, modifications, and alternatives.

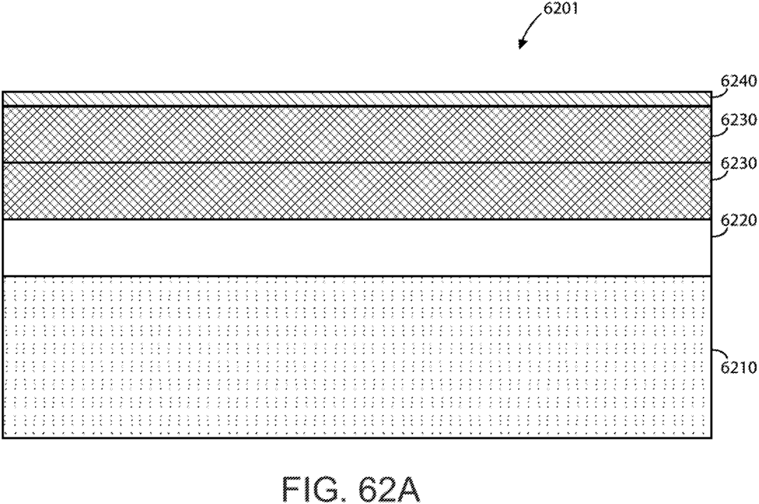

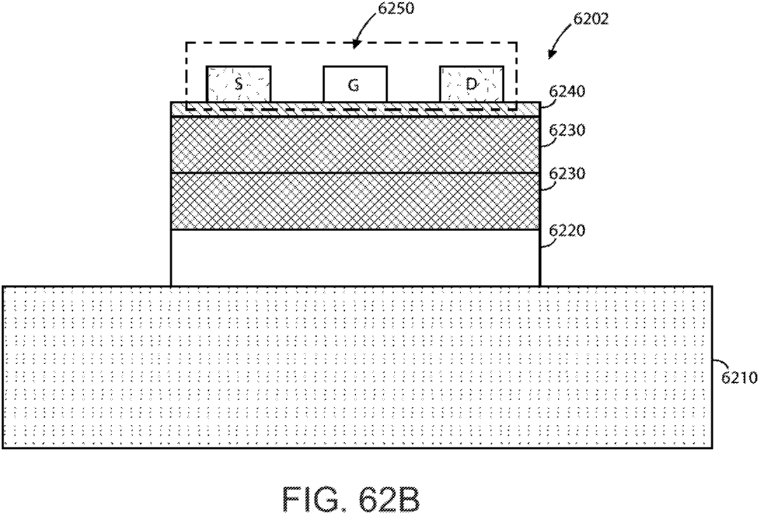

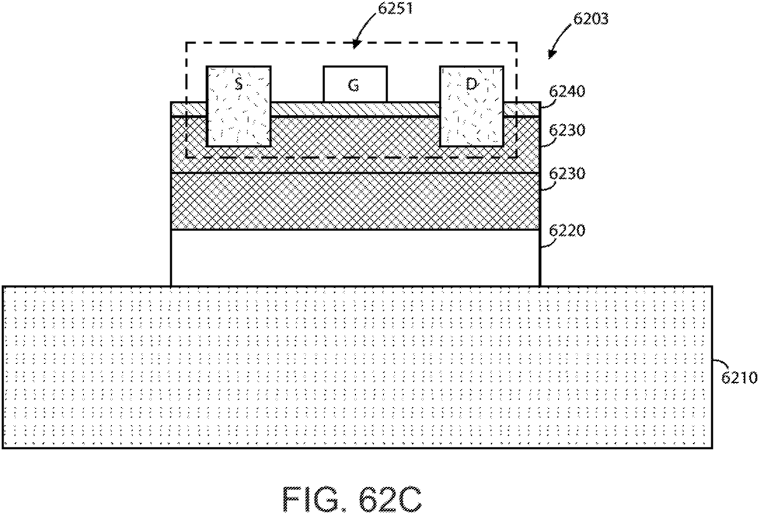

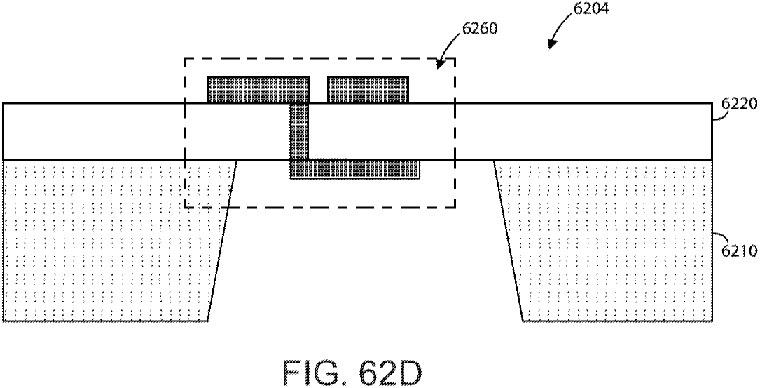

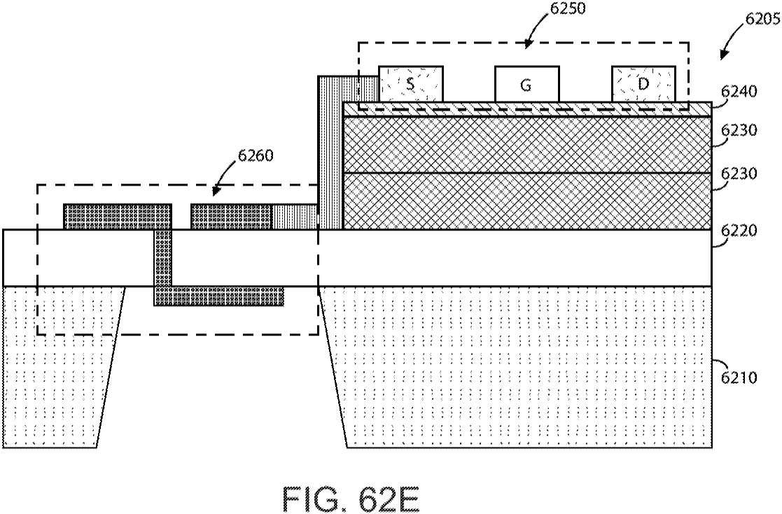

FIGS. 62A-62E are a simplified diagrams illustrating cross-sectional views of monolithic single chip single crystal devices according to various examples of the present invention. In FIG. 62A, a substrate 6210 is provided as a foundation for an epitaxial film stack. The substrate can include silicon, silicon carbide, or other like materials. As shown in device 6201, a first epitaxial layer 6220 can be formed overlying the substrate. In a specific example, this first epitaxial layer can include single crystal aluminum nitride (A1N) materials and can have a thickness ranging from about 0.01 um to about 10.0 um. This epitaxial film can be grown using processes described previously and can be configured for switch/amplifier/filter device applications.

One or more second epitaxial layers 6230 can be formed overlying the first epitaxial layer. In an example, these second epitaxial layers can include single crystal aluminum gallium nitride (AlₓGₐ₁₋ₓN) materials and can be configured for switch/amplifier/filter applications or other passive or active components. In a specific example, at least one of the second layers can be characterized by a composition of 0 ≤ X < 1.0 and can have a thickness ranging from about 200 nm to about 1200 nm. In another specific example, at least one of the second layers can be characterized by a composition of 0.10 ≤ X < 1.0 and can have a thickness ranging from about 10 nm to about 40 nm. The one or more second epitaxial layers can also be grown using the previously described processes. Also, the monolithic device 6201 can include a cap layer 6240, which can include gallium nitride (GaN) materials or the like. The cap layer can have a thickness ranging from about 0.10 nm to about 5.0 nm and can be used to prevent oxidation of the one or more second epitaxial layers.

FIG. 62B shows a cross-sectional view of an example of a single crystal device with an active device having non-recessed contacts. As shown in device 6202, an active device 6250 is formed overlying the cap layer 6240. If there was no cap layer, then the active device would be formed overlying the top layer of the one or more second single crystal epitaxial layers 6230. This active device can be a PA, an LNA, or a switch, or any other active device component.

FIG. 62C shows a cross-sectional view of an example of a single crystal device with an active device having recessed contacts. As shown in device 6203, an active device 6251 is formed overlying the cap layer 6240. Here, the contacts of elements “S” and “D” extend past the cap layer and into the one or more second single crystal epitaxial layers 1530. As stated previously, this active device can be a PA, an LNA, or a switch, or any other active device component.

FIG. 62D shows a cross-sectional view of an example of a single crystal device with a passive filter device. As shown in device 6204, a filter device 6260 is formed through the first single crystal epitaxial layer 6220 with an underlying cavity in the substrate 6210. Other passive elements may also be implemented here.

FIG. 62E shows a cross-sectional view of an example of a monolithic single chip single crystal device having a passive filter device and an active device having non-recessed contacts. As shown, device 6205 monolithically integrates the devices of FIGS. 62B and 62D, with the active device element 6250 and the filter device 6260. Of course, there can be other variations, modifications, and alternatives.

In an example, the monolithically integrated components described in FIGS. 60A-E and FIG. 61 can be implemented in an epitaxial stack structure as shown in FIGS. 62A-E and/or combined with any of the preceding methods of fabricating acoustic resonator devices. Compared to conventional embodiments, which combine various discretely packaged components onto a larger packaged device, the present invention provides a method to grow multiple single crystal device layers to monolithically integrate unpackaged active and passive single crystal components into a single chip package. This method is possible due to the use of single crystal bulk fabrication processes, such as those described previously. Using such a method, the resulting device can benefit from size reduction, improved performance, lower integrated cost, and a faster time to market.

One or more benefits are achieved over pre-existing techniques using the invention. In particular, the present device can be manufactured with lower integrated cost by using a smaller PCB area and fewer passive components. The monolithic single chip design of the present invention reduces the complexity of the front end module by eliminating wire bonds and discrete component packaging. Device performance can also be improved due to optimal impedance match, lower signal loss, and less assembly variability. Depending upon the embodiment, one or more of these benefits may be achieved. Of course, there can be other variations, modifications, and alternatives.

According to an example, the present invention provides a method of manufacturing a monolithic single chip single crystal device. The method can include providing a substrate having a substrate surface region; forming a first single crystal epitaxial layer overlying the substrate surface region; processing the first single crystal epitaxial layer to form one or more active or passive device components; forming one or more second single crystal epitaxial layers overlying the first single crystal epitaxial layer; and processing the one or more second single crystal epitaxial layers to form one or more active or passive device components. The first single crystal epitaxial layer and the one or more second single crystal epitaxial layers can form a monolithic epitaxial stack integrating multiple circuit functions.

The substrate can be selected from one of the following: a silicon substrate, a sapphire substrate, silicon carbide substrate, a GaN bulk substrate, a GaN template, an A1N bulk, an A1N template, and an AlₓGa₁₋ₓN template. In a specific example, the first single crystal epitaxial layer comprises an aluminum nitride (A1N) material used for the RF filter functionality, and wherein the first single crystal epitaxial layer is characterized by a thickness of about 0.01 um to about 10.0 um. In a specific example, at least one of the one or more second single crystal epitaxial layer comprises a single crystal aluminum gallium nitride (AlₓGa₁₋ₓN) material, and wherein the second single crystal epitaxial layer is characterized by a composition of 0 ≤ X < 1.0 and a thickness of about 200 nm to about 1200 nm or a thickness of about 10 nm to about 40 nm. The one or more active or passive device components can include one or more filters, amplifiers, switches, or the like.

In an example, the method can further include forming a cap layer overlying the third epitaxial layer, wherein the cap layer comprises gallium nitride (GaN) materials. In a specific example, the cap layer is characterized by a thickness of about 0.10 nm to about 5.0 nm.

According to an example, the present invention also provides the resulting structure of the monolithic single chip single crystal device. The device includes a substrate having a substrate surface region; a first single crystal epitaxial layer formed overlying the substrate surface region, the first single crystal epitaxial layer having one or more active or passive device components; and one or more second single crystal epitaxial layers formed overlying the first single crystal epitaxial layer, the one or more second single crystal epitaxial layers having one or more active or passive device components. The first single crystal epitaxial layer and the one or more second single crystal epitaxial layers are formed as a monolithic epitaxial stack integrating multiple circuit functions.

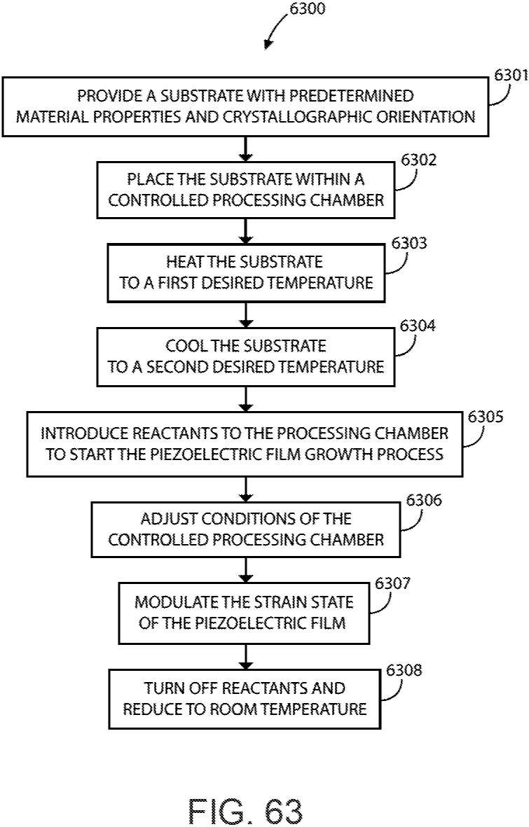

FIG. 63 is a flow diagram illustrating a method for manufacturing an acoustic resonator device according to an example of the present invention. The following steps are merely examples and should not unduly limit the scope of the claims herein. One of ordinary skill in the art would recognize many other variations, modifications, and alternatives. For example, various steps outlined below may be added, removed, modified, rearranged, repeated, and/or overlapped, as contemplated within the scope of the invention. A typical growth process 6300 can be outlined as follows:
6301. Provide a substrate having the required material properties and crystallographic orientation. Various substrates can be used in the present method for fabricating an acoustic resonator device such as Silicon, Sapphire, Silicon Carbide, Gallium Nitride (GaN) or Aluminum Nitride (AlN) bulk substrates. The present method can also use GaN templates, AlN templates, and AlₓGa₁₋ₓN templates (where x varies between 0.0 and 1.0). These substrates and templates can have polar, non-polar, or semi-polar crystallographic orientations. Those of ordinary skill in the art will recognize other variations, modifications, and alternatives;
6302. Place the selected substrate into a processing chamber within a controlled environment;
6303. Heat the substrate to a first desired temperature. At a reduced pressure between 5-800 mbar the substrates are heated to a temperature in the range of 1100° - 1350° C. in the presence of purified hydrogen gas as a means to clean the exposed surface of the substrate. The purified hydrogen flow shall be in the range of 5-30 slpm (standard liter per minute) and the purity of the gas should exceed 99.9995%;
6304. Cool the substrate to a second desired temperature. After 10-15 minutes at elevated temperature, the substrate surface temperature should be reduced by 100-200° C.; the temperature offset here is determined by the selection of substrate material and the initial layer to be grown (Highlighted in FIGS. 18A-C);
6305. Introduce reactants to the processing chamber. After the temperature has stabilized the Group III and Group V reactants are introduced to the processing chamber and growth is initiated.
6306. Upon completion of the nucleation layer the growth chamber pressures, temperatures, and gas phase mixtures may be further adjusted to grow the layer or plurality of layers of interest for the acoustic resonator device.
6307. During the film growth process the strain-state of the material may be modulated via the modification of growth conditions or by the controlled introduction of impurities into the film (as opposed to the modification of the electrical properties of the film).
6308. At the conclusion of the growth process the Group III reactants are turned off and the temperature resulting film or films are controllably lowered to room. The rate of thermal change is dependent upon the layer or plurality of layers grown and in the preferred embodiment is balanced such that the physical parameters of the substrate including films are suitable for subsequent processing.

Referring to step 6305, the growth of the single crystal material can be initiated on a substrate through one of several growth methods: direct growth upon a nucleation layer, growth upon a super lattice nucleation layer, and growth upon a graded transition nucleation layer. The growth of the single crystal material can be homoepitaxial, heteroepitaxial, or the like. In the homoepitaxial method, there is a minimal lattice mismatch between the substrate and the films such as the case for a native III-N single crystal substrate material. In the heteroepitaxial method, there is a variable lattice mismatch between substrate and film based on in-plane lattice parameters. As further described below, the combinations of layers in the nucleation layer can be used to engineer strain in the subsequently formed structure.

Referring to step 6306, various substrates can be used in the present method for fabricating an acoustic resonator device. Silicon substrates of various crystallographic orientations may be used. Additionally, the present method can use sapphire substrates, silicon carbide substrates, gallium nitride (GaN) bulk substrates, or aluminum nitride (AlN) bulk substrates. The present method can also use GaN templates, AlN templates, and AlₓGa₁₋ₓN templates (where x varies between 0.0 and 1.0). These substrates and templates can have polar, non-polar, or semi-polar crystallographic orientations. Those of ordinary skill in the art will recognize other variations, modifications, and alternatives.

In an example, the present method involves controlling material characteristics of the nucleation and piezoelectric layer(s). In a specific example, these layers can include single crystal materials that are configured with defect densities of less than 1E+11 defects per square centimeter. The single crystal materials can include alloys selected from at least one of the following: AlN, AlGaN, ScAlN, ScGaN, GaN, InN, InGaN, AlInN, AlInGaN, and BN. In various examples, any single or combination of the aforementioned materials can be used for the nucleation layer(s) and/or the piezoelectric layer(s) of the device structure.

According to an example, the present method involves strain engineering via growth parameter modification. More specifically, the method involves changing the piezoelectric properties of the epitaxial films in the piezoelectric layer via modification of the film growth conditions (these modifications can be measured and compared via the sound velocity of the piezoelectric films). These growth conditions can include nucleation conditions and piezoelectric layer conditions. The nucleation conditions can include temperature, thickness, growth rate, gas phase ratio (V/III), and the like. The piezo electric layer conditions can include transition conditions from the nucleation layer, growth temperature, layer thickness, growth rate, gas phase ratio (V/III), post growth annealing, and the like. Further details of the present method can be found below.

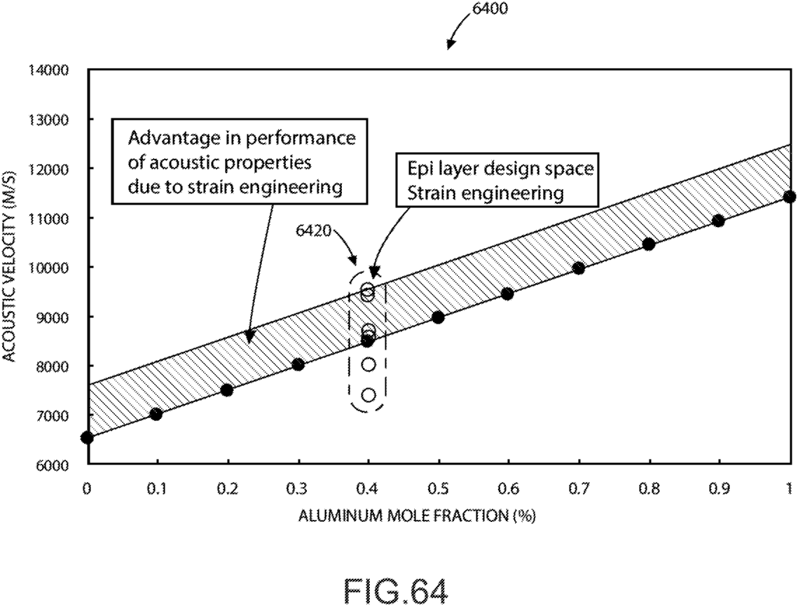

FIG. 64 is a simplified graph illustrating the results of forming a piezoelectric layer for an acoustic resonator device according to an example of the present invention. This graph highlights the ability of to tailor the acoustic properties of the material for a given Aluminum mole fraction. Referring to step 6307 above, such flexibility allows for the resulting resonator properties to be tailored to the individual application. As shown, graph 6400 depicts a plot of acoustic velocity (m/s) over aluminum mole fraction (%). The marked region 6420 shows the modulation of acoustic velocity via strain engineering of the piezo electric layer at an aluminum mole fraction of 0.4. Here, the data shows that the change in acoustic velocity ranges from about 7,500 m/s to about 9,500 m/s, which is about ±1,000 m/s around the initial acoustic velocity of 8,500 m/s. Thus, the modification of the growth parameters provides a large tunable range for acoustic velocity of the acoustic resonator device. This tunable range will be present for all aluminum mole fractions from 0 to 1.0 and is a degree of freedom not present in other conventional embodiments of this technology

The present method also includes strain engineering by impurity introduction, or doping, to impact the rate at which a sound wave will propagate through the material. Referring to step 6307 above, impurities can be specifically introduced to enhance the rate at which a sound wave will propagate through the material. In an example, the impurity species can include, but is not limited to, the following: silicon (Si), magnesium (Mg), carbon (C), oxygen (O), erbium (Er), rubidium (Rb), strontium (Sr), scandium (Sc), beryllium (Be), molybdenum (Mo), zirconium (Zr), Hafnium (Hf), and vanadium (Va). Silicon, magnesium, carbon, and oxygen are common impurities used in the growth process, the concentrations of which can be varied for different piezoelectric properties. In a specific example, the impurity concentration ranges from about 1E+10 to about 1E+21 per cubic centimeter. The impurity source used to deliver the impurities to can be a source gas, which can be delivered directly, after being derived from an organometallic source, or through other like processes.

The present method also includes strain engineering by the introduction of alloying elements, to impact the rate at which a sound wave will propagate through the material. Referring to step 6407 above, alloying elements can be specifically introduced to enhance the rate at which a sound wave will propagate through the material. In an example, the alloying elements can include, but are not limited to, the following: magnesium (Mg), erbium (Er), rubidium (Rb), strontium (Sr), scandium (Sc), titanium (Ti), zirconium (Zr), Hafnium (Hf), vanadium (Va), Niobium (Nb), and tantalum (Ta). In a specific embodiment, the alloying element (ternary alloys) or elements (in the case of quaternary alloys) concentration ranges from about 0.01% to about 50%. Similar to the above, the alloy source used to deliver the alloying elements can be a source gas, which can be delivered directly, after being derived from an organometallic source, or through other like processes. Those of ordinary skill in the art will recognize other variations, modifications, and alternatives to these processes.

The methods for introducing impurities can be during film growth (in-situ) or post growth (ex-situ). During film growth, the methods for impurity introduction can include bulk doping, delta doping, co-doping, and the like. For bulk doping, a flow process can be used to create a uniform dopant incorporation. For delta doping, flow processes can be intentionally manipulated for localized areas of higher dopant incorporation. For co-doping, the any doping methods can be used to simultaneously introduce more than one dopant species during the film growth process. Following film growth, the methods for impurity introduction can include ion implantation, chemical treatment, surface modification, diffusion, co-doping, or the like. The of ordinary skill in the art will recognize other variations, modifications, and alternatives.

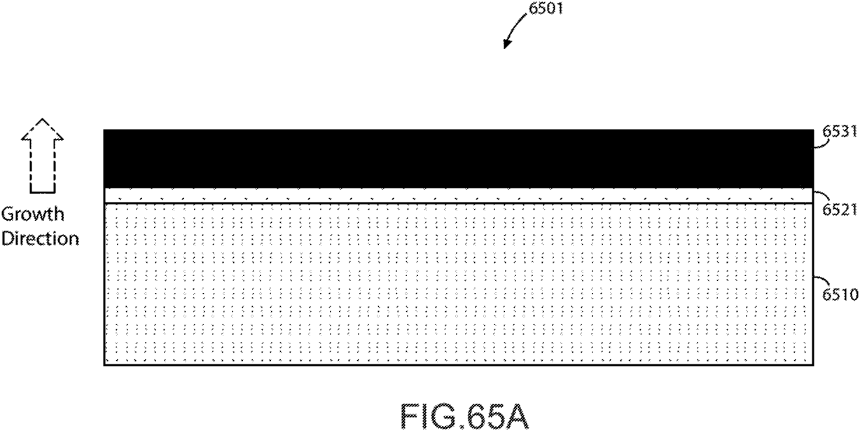

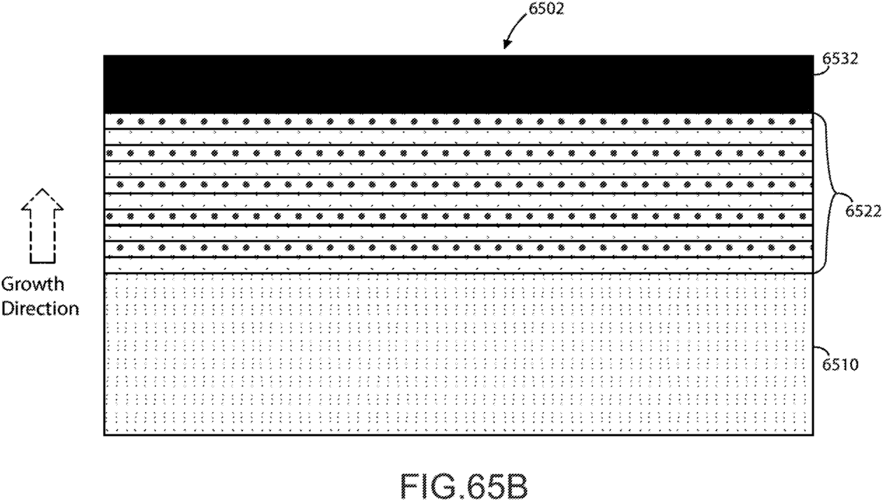

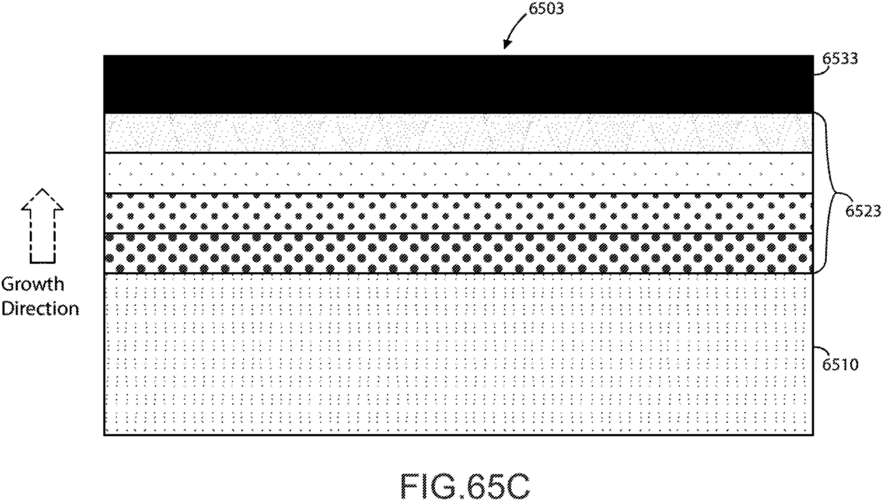

FIG. 65A is a simplified diagram illustrating a method for forming a piezoelectric layer for an acoustic resonator device according to an example of the present invention. As shown in device 6501, the piezoelectric layer 6531, or film, is directly grown on the nucleation layer 6521, which is formed overlying a surface region of a substrate 6510. The nucleation layer 6521 may be the same or different atomic composition as the piezoelectric layer 6531. Here, the piezoelectric film 6531 may be doped by one or more species during the growth (in-situ) or post-growth (ex-situ) as described previously.

FIG. 65B is a simplified diagram illustrating a method for forming a piezoelectric layer for an acoustic resonator device according to an example of the present invention. As shown in device 6502, the piezoelectric layer 6532, or film, is grown on a super lattice nucleation layer 6522, which is comprised of layer with alternating composition and thickness. This super lattice layer 6522 is formed overlying a surface region of the substrate 6510. The strain of device 6502 can be tailored by the number of periods, or alternating pairs, in the super lattice layer 6522 or by changing the atomic composition of the constituent layers. Similarly, the piezoelectric film 6532 may be doped by one or more species during the growth (in-situ) or post-growth (ex-situ) as described previously.

FIG. 65C is a simplified diagram illustrating a method for forming a piezoelectric layer for an acoustic resonator device according to an example of the present invention. As shown in device 6503, the piezoelectric layer 6533, or film, is grown on graded transition layers 6523. These transition layers 6523, which are formed overlying a surface region of the substrate 6510, can be used to tailor the strain of device 6503. In an example, the alloy (binary or ternary) content can be decreased as a function of growth in the growth direction. This function may be linear, step-wise, or continuous. Similarly, the piezoelectric film 6533 may be doped by one or more species during the growth (in-situ) or post-growth (ex-situ) as described previously.

In an example, the present invention provides a method for manufacturing an acoustic resonator device. As described previously, the method can include a piezoelectric film growth process such as a direct growth upon a nucleation layer, growth upon a super lattice nucleation layer, or a growth upon graded transition nucleation layers. Each process can use nucleation layers that include, but are not limited to, materials or alloys having at least one of the following: A1N, AlGaN, GaN, InN, InGaN, AlInN, AlInGaN, and BN. Those of ordinary skill in the art will recognize other variations, modifications, and alternatives.

One or more benefits are achieved over pre-existing techniques using the invention. In particular, the present device can be manufactured in a relatively simple and cost effective manner while using conventional materials and/or methods according to one of ordinary skill in the art. Using the present method, one can create a reliable single crystal based acoustic resonator using multiple ways of three-dimensional stacking through a wafer level process. Such filters or resonators can be implemented in an RF filter device, an RF filter system, or the like. Depending upon the embodiment, one or more of these benefits may be achieved. Of course, there can be other variations, modifications, and alternatives.

As an example, the packaged device can include any combination of elements described above, as well as outside of the present specification. As used herein, the term “substrate” can mean the bulk substrate or can include overlying growth structures such as an aluminum, gallium, or ternary compound of aluminum and gallium and nitrogen containing epitaxial region, or functional regions, combinations, and the like.

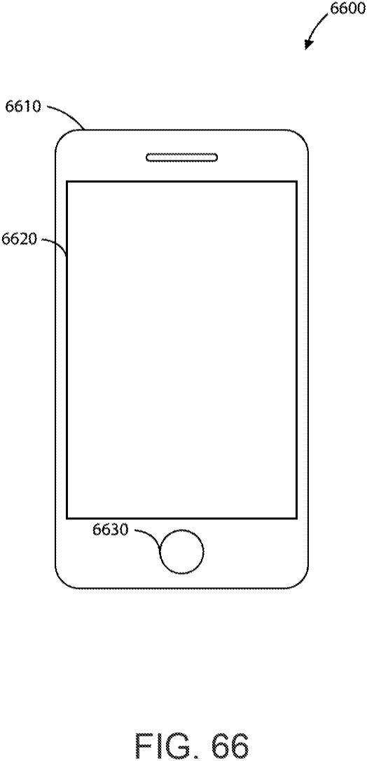

FIG. 66 is a simplified diagram 6600 illustrating a smart phone with a capture image of a user according to an embodiment of the present invention. As shown, the smart phone includes a housing 6610, display 6620, and interface device 6630, which may include a button, microphone, or touch screen. Preferably, the phone has a high-resolution camera device, which can be used in various modes. An example of a smart phone can be an iPhone from Apple Computer of Cupertino California. Alternatively, the smart phone can be a Galaxy from Samsung or others.

In an example, the smart phone includes the following features (which are found in an iPhone 4 from Apple Computer, although there can be variations), see www.apple.com.
GSM model: UMTS/HSDPA/HSUPA (850, 900, 1900, 2100 MHz); GSM/EDGE (850, 900, 1800, 1900 MHz)
CDMA model: CDMA EV-DO Rev. A (800, 1900 MHz)
802.11b/g/n Wi-Fi (802.11n 2.4 GHz only)
Bluetooth 2.1 + EDR wireless technology
Assisted GPS
Digital compass
Wi-Fi
Cellular
Retina display
3.5-inch (diagonal) widescreen Multi-Touch display
800: 1 contrast ratio (typical)
500 cd/m2 max brightness (typical)
Fingerprint-resistant oleophobic coating on front and back
Support for display of multiple languages and characters simultaneously
5-megapixel iSight camera
Video recording, HD (720 p) up to 30 frames per second with audio
VGA-quality photos and video at up to 30 frames per second with the front camera
Tap to focus video or still images
LED flash
Photo and video geotagging
Built-in rechargeable lithium-ion battery
Charging via USB to computer system or power adapter
Talk time: Up to 7 hours on 3G, up to 14 hours on 2G (GSM)
Standby time: Up to 300 hours
Internet use: Up to 6 hours on 3G, up to 10 hours on Wi-Fi
Video playback: Up to 10 hours
Audio playback: Up to 40 hours
Frequency response: 20 Hz to 20,000 Hz
Audio formats supported: AAC (8 to 320 Kbps), Protected AAC (from iTunes Store), HE-AAC, MP3 (8 to 320 Kbps), MP3 VBR, Audible (formats 2, 3, 4, Audible Enhanced Audio, AAX, and AAX+), Apple Lossless, AIFF, and WAV
User-configurable maximum volume limit
Video out support at up to 720 p with Apple Digital AV Adapter or Apple VGA Adapter; 576 p and 480 p with Apple Component AV Cable; 576i and 480i with Apple Composite AV Cable (cables sold separately)
Video formats supported: H.264 video up to 720 p, 30 frames per second, Main Profile Level 3.1 with AAC-LC audio up to 160 Kbps, 48 kHz, stereo audio in .m4v, .mp4, and .mov file formats; MPEG-4 video up to 2.5 Mbps, 640 by 480 pixels, 30 frames per second, Simple Profile with AAC-LC audio up to 160 Kbps per channel, 48 kHz, stereo audio in .m4v, .mp4, and .mov file formats; Motion JPEG (M-JPEG) up to 35 Mbps, 1280 by 720 pixels, 30 frames per second, audio in ulaw, PCM stereo audio in .avi file format
Three-axis gyro
Accelerometer
Proximity sensor
Ambient light sensor.”

An exemplary electronic device may be a portable electronic device, such as a media player, a cellular phone, a personal data organizer, or the like. Indeed, in such embodiments, a portable electronic device may include a combination of the functionalities of such devices. In addition, the electronic device may allow a user to connect to and communicate through the Internet or through other networks, such as local or wide area networks. For example, the portable electronic device may allow a user to access the internet and to communicate using e-mail, text messaging, instant messaging, or using other forms of electronic communication. By way of example, the electronic device may be a model of an iPod having a display screen or an iPhone available from Apple Inc.

In certain embodiments, the device may be powered by one or more rechargeable and/or replaceable batteries. Such embodiments may be highly portable, allowing a user to carry the electronic device while traveling, working, exercising, and so forth. In this manner, and depending on the functionalities provided by the electronic device, a user may listen to music, play games or video, record video or take pictures, place and receive telephone calls, communicate with others, control other devices (e.g., via remote control and/or Bluetooth functionality), and so forth while moving freely with the device. In addition, device may be sized such that it fits relatively easily into a pocket or a hand of the user. While certain embodiments of the present invention are described with respect to a portable electronic device, it should be noted that the presently disclosed techniques may be applicable to a wide array of other, less portable, electronic devices and systems that are configured to render graphical data, such as a desktop computer.

In the presently illustrated embodiment, the exemplary device includes an enclosure or housing 6610, a display, user input structures, and input/output connectors. The enclosure may be formed from plastic, metal, composite materials, or other suitable materials, or any combination thereof. The enclosure may protect the interior components of the electronic device from physical damage, and may also shield the interior components from electromagnetic interference (EMI).

The display 6620 may be a liquid crystal display (LCD), a light emitting diode (LED) based display, an organic light emitting diode (OLED) based display, or some other suitable display. In accordance with certain embodiments of the present invention, the display may display a user interface and various other images, such as logos, avatars, photos, album art, and the like. Additionally, in one embodiment, the display may include a touch screen through which a user may interact with the user interface. The display may also include various function and/or system indicators to provide feedback to a user, such as power status, call status, memory status, or the like. These indicators may be incorporated into the user interface displayed on the display.

In one embodiment, one or more of the user input structures 6630 are configured to control the device, such as by controlling a mode of operation, an output level, an output type, among others. For instance, the user input structures may include a button to turn the device on or off. Further the user input structures may allow a user to interact with the user interface on the display. Embodiments of the portable electronic device may include any number of user input structures, including buttons, switches, a control pad, a scroll wheel, or any other suitable input structures. The user input structures may work with the user interface displayed on the device to control functions of the device and/or any interfaces or devices connected to or used by the device. For example, the user input structures may allow a user to navigate a displayed user interface or to return such a displayed user interface to a default or home screen.

The exemplary device may also include various input and output ports to allow connection of additional devices. For example, a port may be a headphone jack that provides for the connection of headphones. Additionally, a port may have both input/output capabilities to provide for connection of a headset (e.g., a headphone and microphone combination). Embodiments of the present invention may include any number of input and/or output ports, such as headphone and headset jacks, universal serial bus (USB) ports, IEEE-1394 ports, and AC and/or DC power connectors. Further, the device may use the input and output ports to connect to and send or receive data with any other device, such as other portable electronic devices, personal computers, printers, or the like. For example, in one embodiment, the device may connect to a personal computer via an IEEE-1394 connection to send and receive data files, such as media files. Further details of the device can be found in U.S. Pat. No. 8,294,730, assigned to Apple, Inc.

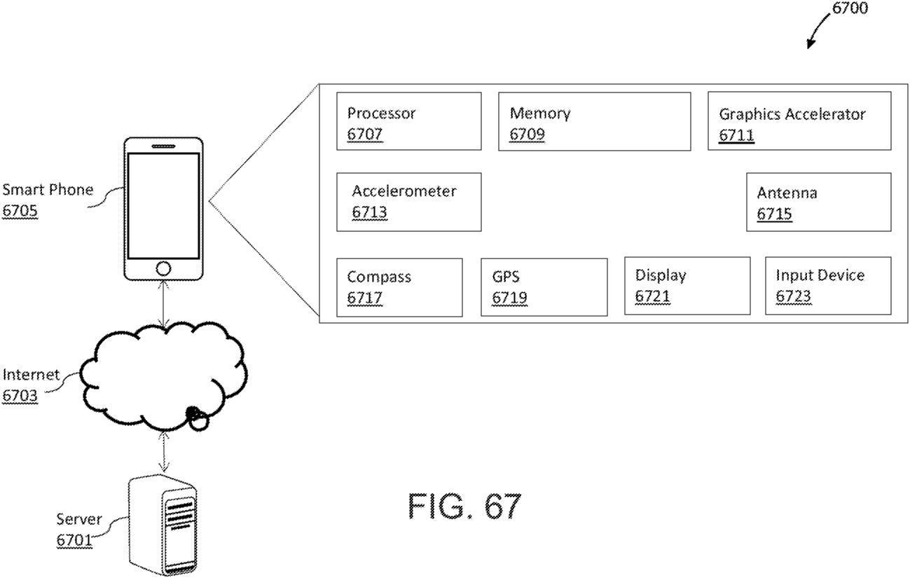

FIG. 67 is a simplified system diagram 6700 with a smart phone according to an embodiment of the present invention. A server 6701 is in electronic communication with a handheld electronic device 6705 having functional components such as a processor 6707, memory 6709, graphics accelerator 6711, accelerometer 6713, communications interface 6715, compass 6717, GPS 6719, display 6721, and input device 6723. Each device is not limited to the illustrated components. The components may be hardware, software or a combination of both.

In some examples, instructions are input to the handheld electronic device 6705 through an input device 6723 that instructs the processor 6707 to execute functions in an electronic imaging application. One potential instruction can be to generate a wireframe of a captured image of a portion of a human user. In that case the processor 6707 instructs the communications interface 6715 to communicate with the server 6701, via the internet 6703 or the like, and transfer human wireframe or image data. The data transferred by the communications interface 6715 and either processed by the processor 6707 immediately after image capture or stored in memory 6709 for later use, or both. The processor 6707 also receives information regarding the display’s 6721 attributes, and can calculate the orientation of the device, or e.g., using information from an accelerometer 6713 and/or other external data such as compass headings from a compass 6717, or GPS location from a GPS chip, and the processor then uses the information to determine an orientation in which to display the image depending upon the example.

In an example, the captured image can be drawn by the processor 6707, by a graphics accelerator 6711, or by a combination of the two. In some embodiments, the processor 6707 can be the graphics accelerator. The image can be first drawn in memory 6709 or, if available, memory directly associated with the graphics accelerator 6711. The methods described herein can be implemented by the processor 6707, the graphics accelerator 6711, or a combination of the two to create the image and related wireframe. Once the image or wireframe is drawn in memory, it can be displayed on the display 6721.

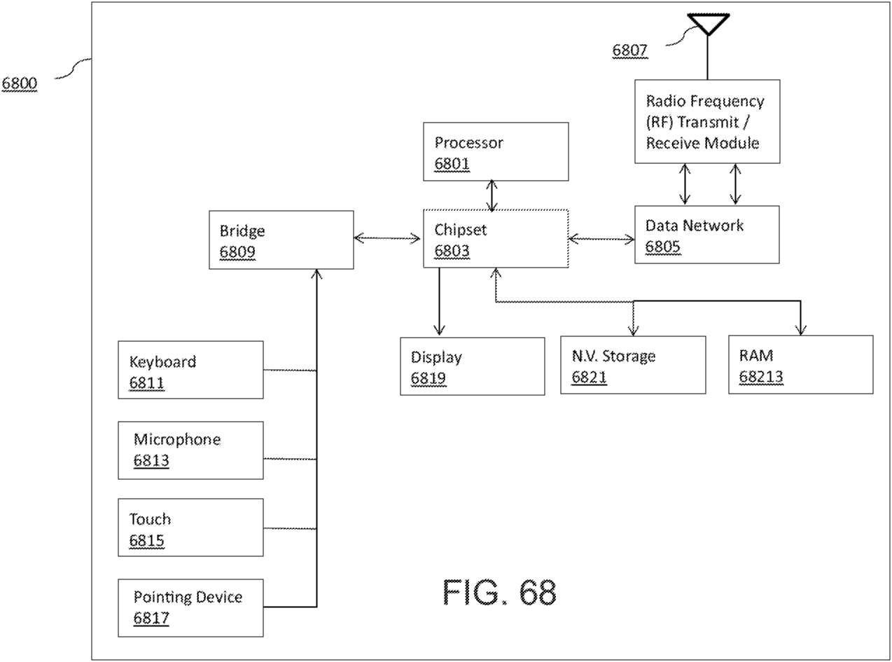

FIG. 68 is a simplified diagram of a smart phone system diagram according to an example of the present invention. System 6800 is an example of hardware, software, and firmware that can be used to implement disclosures above. System 6800 includes a processor 6801, which is representative of any number of physically and/or logically distinct resources capable of executing software, firmware, and hardware configured to perform identified computations. Processor 6801 communicates with a chipset 6803 that can control input to and output from processor 6801. In this example, chipset 6803 outputs information to display 6819 and can read and write information to non-volatile storage 6821, which can include magnetic media and solid state media, for example. Chipset 6803 also can read data from and write data to RAM 68213. A bridge 6809 for interfacing with a variety of user interface components can be provided for interfacing with chipset 6803. Such user interface components can include a keyboard 6811, a microphone 6813, touch-detection-and-processing circuitry 6815, a pointing device such as a mouse 6817, and so on. In general, inputs to system 6800 can come from any of a variety of sources, machine-generated and/or human-generated sources.

Chipset 6803 also can interface with one or more data network interfaces 6805 that can have different physical interfaces 6807. Such data network interfaces can include interfaces for wired and wireless local area networks, for broadband wireless networks, as well as personal area networks. Some applications of the methods for generating and displaying and using the GUI disclosed herein can include receiving data over physical interface 6807 or be generated by the machine itself by processor 6801 analyzing data stored in memory 6821 or 68213. Further, the machine can receive inputs from a user via devices keyboard 6811, microphone 6813, touch device 6814, and pointing device 6817 and execute appropriate functions, such as browsing functions by interpreting these inputs using processor 6801.

A transmit module and a receive module is coupled between the antenna and data network interfaces. In an example, the transmit module and the receive module can be separate devices, or integrated with each other in a single module. Of course, there can be alternatives, modifications, and variations. Further details of the module can be found throughout the present specification and more particularly below.

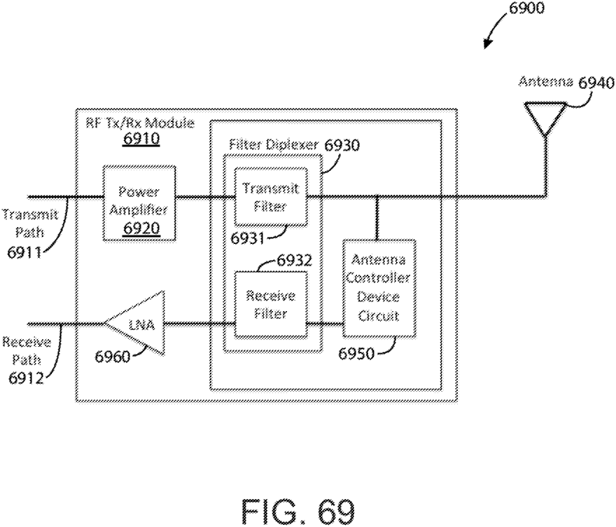

FIG. 69 is a simplified diagram of device 2200 including a transmit module and a receive module 6910 according to examples of the present invention. In an example, the transmit module and the receive module are shown as one block structure. As shown, the RF transmit module is configured on a transmit path 6911. The RF receive module is configured on a receive path 612. In an example, the antenna 6940 is coupled to the RF transmit module 6931 and the RF receive module 6932. As shown, an antenna control device 6950 is coupled to the receive path 6912 and the transmit path 6911, and is configured to select either the receive path 6912 or the transmit path 6911. In other examples, the antenna control can include a variety of features. Such features include signal tracking, filtering, and the like.

In an example, a receive filter 6932 provided within the RF receive module. In an example, a low noise amplifier device 6960 coupled to the RF receive module. The low noise amplifier can be of CMOS, GaAs, SiGe process technology, or the like. In an example, a transmit filter 6931 is provided within the RF transmit module. The transmit filter comprises a filter 6930 comprising a single crystal acoustic resonator device. As shown in FIG. 69, the filter 6930 includes both the transmit and receive filters 6931, 6932. In an example, a power amplifier 6920 is coupled to the RF transmit module, and configured to drive a signal through the transmit path 6911 to the antenna 6940. In an example, the power amplifier is CMOS, GaAs, SiGe process technology, or the like.

In an example, a band-to-band isolation is characterizing the transmit filter such that a difference between a pass band to reject band as measured in relative decibels (dBc) is greater than 10 dBc and less than 100 dBc. In other examples, the difference can have a broader or narrower range. In an example, an insertion loss characterizing the transmit filter, the insertion loss being less than 3 dB and greater than 0.5 dB. In other examples, a center frequency configured to define the pass band.

In an example, the single crystal acoustic resonator device is included. In an example, the device a substrate, which has a surface region. In an example, the resonator device has a first electrode material coupled to a portion of the substrate, and a single crystal capacitor dielectric material having a thickness of greater than 0.4 microns and overlying an exposed portion of the surface region and coupled to the first electrode material. In an example, the single crystal capacitor dielectric material is characterized by a dislocation density of less than 10¹² defects/cm². In an example, the device has a second electrode material overlying the single crystal capacitor dielectric material.

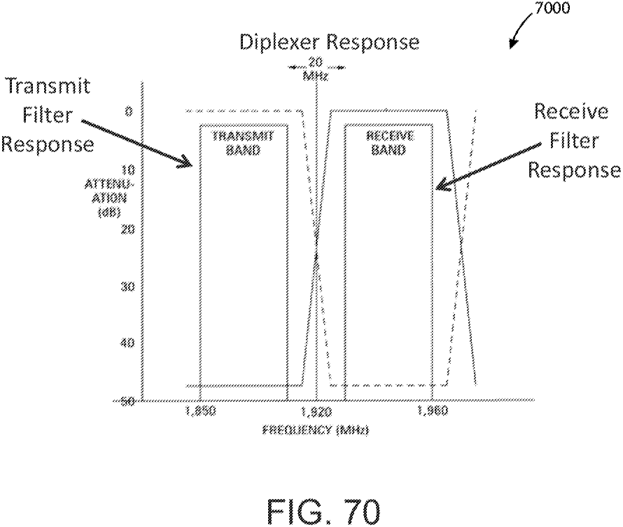

FIG. 70 is an example of filter response in an example of the present invention. As shown, the response graph 7000 shows attenuation plotted against frequency. Attenuation is measured in decibels (dB), and frequency in hertz. The first region represents the transmit filter response, while the second region represents the receive filter response.

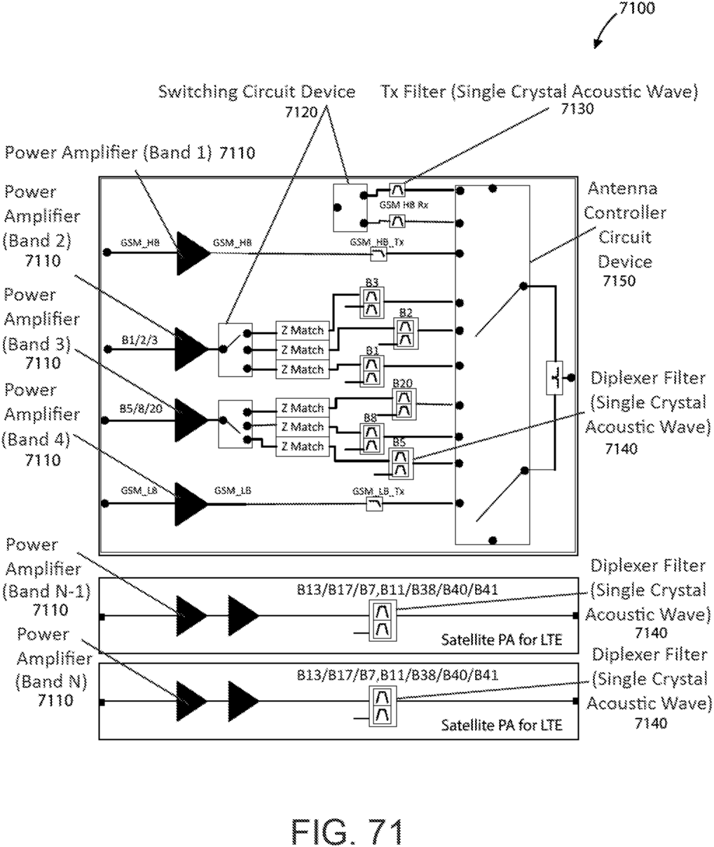

FIG. 71 is a simplified diagram of a smart phone RF power amplifier module 7100 according to an example of the present invention. In an example as shown is an RF power amplifier module 7110 coupled to a processor device, as described previously in FIGS. 67 and 68. In an example, the RF power amplifier module 7110 is configured to a transmit path and a receive path. Also, any of the power amplifier modules can contain one or more single crystal acoustic wave filters.

In an example, the module has an antenna coupled to the RF power amplifier module 7110. In an example, the module has an antenna control device 7150 configured within the RF power amplifier module 7110. In an example, the control device 7150 is coupled to the receive path and the transmit path, and is configured to select either the receive path or the transmit path.

As shown, the module has a plurality of communication bands 7110 configured within the RF power amplifier module. In an example, the plurality of communication bands are numbered from 1 through N, where N is an integer greater than 2 and less than 50, although there can be variations. In an example, each of the communication bands can include a power amplifier. In an example, the power amplifier is CMOS, GaAs, SiGe process technology, or the like.

In an example, one or more of the communication bands can be configured with a filter device. The filter device 7140 is configured from a single crystal acoustic resonator device. An example of such device can be found in U.S. Serial No. 14/298,057, commonly assigned, and hereby incorporated by reference herein. The module can have a single crystal acoustic resonator filter device configured with at least one of the plurality of communication bands, as shown. One or more of the communication bands can also be configured with a switching device 7120. The switching device 7120 is coupled to an output impedance matching circuit, as shown. The matching circuit is configured to multiple acoustic wave filters 7140 as shown. A switching device 7120 can also be coupled to transmit (Tx) filter devices 7130, which are coupled ot the antenna controller circuit device 7150. These filter devices 7130 can also be configured from single crystal resonator devices or any of the acoustic resonator devices discussed previously. The paths are controlled by the switching device. In an example, the module has a band-to-band isolation between any pair of adjacent communication bands such that a difference between a pass band to reject band as measured in relative decibels (dBc) is greater than 10 dBc and less than 100 dBc. In an example, the module has a control device coupled to the rf power amplifier module.

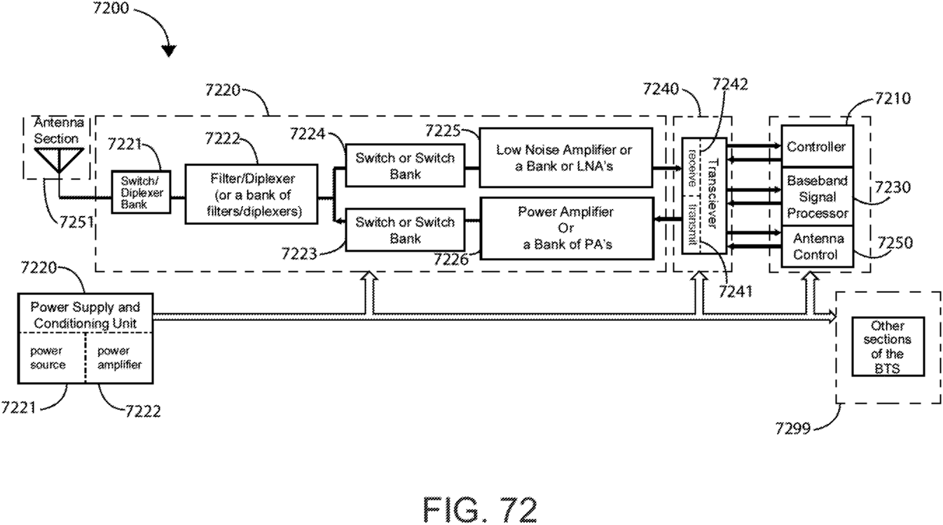

FIG. 72 is a simplified diagram of a fixed wireless communication infrastructure system according to an example of the present invention. The present invention includes specific architectures for wireless communication infrastructure applications using various single crystal piezoelectric devices. Typical infrastructure systems may include controllers, power supplies and/or batteries, cooling infrastructure, transceivers (transmit and/or receive modules), power amplifiers, low-noise amplifiers, switches, antennas, and the like.

As an example, wireless system 7200 includes a controller 7210 coupled to a power source 7221, a signal processing module 7230, and at least a transceiver module 7240. Each of the transceiver modules includes a transmit module 7241 configured on a transmit path and a receive module 7242 configured on a receive path. These paths can be implemented separately or together. The transmit modules 7241 each include at least a transmit filter having one or more filter devices, while the receive modules 7242 each include at least a receive filter. The signal processing module 7230 can be a baseband signal processing module. Further, the transceiver modules 7240 can include RF transmit and receive modules. Those of ordinary skill in the art will recognize other variations, modifications, and alternatives.

Each of these filter (or diplexer) devices includes a single crystal acoustic resonator device. As an example, each device can include a first electrode material, a single crystal material, and a second electrode material. The first electrode material can be coupled to a portion of the substrate. Also, a reflector region can be configured to the first electrode material. The single crystal material can be formed overlying an exposed portion of the substrate surface region and coupled to the first electrode material. The second electrode material can be formed overlying the single crystal material. The structure of these resonator devices can also be similar to those described previously in FIGS. 1A-12E, 62A-62E, and 65A-65C.

Depending on the whether the communication system is a frequency division duplex (FDD) type or time division duplex (TDD) type, the transmit and receive paths may be isolated or shared.. In FDD systems, filters are required to separate transmission and reception, thus separating the transmit and receive paths. In TDD systems, since transmission and reception occur in the same channel, there is no need for diplexers to isolate transmission and reception. As shown in FIG. 72, the present invention may have separate channels (FDD system) using filters 7222 or a shared communication channel (TDD system) using diplexers 7222. Those of ordinary skill in the art will recognize other variations, modifications, and alternatives.

An antenna section 7251, having an antenna or an array of antennas, can be coupled to each of the transmit modules 7241 and each of the receive modules 7242. An antenna control module 7250 is coupled to each of the receive path, the transmit path, and the transceiver modules 7240. This antenna control module 7250 is configured to select one of the receive paths or one of the transmit paths in facilitating communication type operations. In an example, the antenna control module 7250 may be physically configured with the controller and/or signal processing module (as shown). Alternatively, the antenna control module 7250 can be physically configured within a front-end module 7220, within the antenna section 7251, or otherwise closer to the antenna section 7251.

In an example, the front-end module 7220 (RF, Bluetooth, or the like) can be coupled to the power supply and conditioning unit 7220 and be configured between the transceiver 7240 and the antenna 7251. A switch bank 7221 can be coupled to the antenna 7251, and the transmit and receive filters can be configured to filter module 7222 (which can be a bank of filters). The filter 7222 can be coupled to two switches (or switch banks) 7223, 7224, that are configured on the transmit path and receive path, respectively. These switches or switch banks can be configured to switch the different paths in or out of the signal flow. On the receive path, switch 7224 can be coupled to a power amplifier 7225 (or bank of PAs) through to the transceiver 7240. On the transmit path, switch 7223 can be coupled to a low noise amplifier 7226 (or bank of LNAs) through to the transceiver 7240.

In an example, the power source 7221 and a power amplifier module 7222 can be part of a power supply and conditioning unit 7220 that is coupled to the controller 7210, the power source 7220, and the transceiver module 7240. The power amplifier module 7260 can be configured on each of the transmit paths and each of the receive paths. This power amplifier module can also include a plurality of communication bands, each of which can have a power amplifier. The filters of the transceiver modules 7240 can each be configured to one or more of the communication bands. The number of filters and switches can vary depending on the number of bands supported and other tradeoffs in the system design. Further, the power supply and conditioning unit 7220 can be coupled to other sections of the wireless system 7200 or base station (BTS) system (represented by block 2599).

One or more benefits are achieved over pre-existing techniques using the present invention. Wireless infrastructures using the present single crystal technology achieves better thermal conductivity, which enables such infrastructures to perform better in high power density applications. The present single crystal infrastructures also provide low loss, thus enabling higher out of band rejection (OOBR). With better thermal properties and resilience over higher power, such single crystal infrastructures achieve higher linearity as well. Depending upon the embodiment, one or more of these benefits may be achieved. Of course, there can be other variations, modifications, and alternatives.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A fixed wireless communication system comprising:
a controller;
a power source coupled to the controller;
a baseband signal processing module coupled to the controller;
one or more transceiver modules, each of the transceiver modules comprising
an RF transmit module coupled to the baseband signal processing module and configured on a transmit path, wherein the RF transmit module includes a transmit filter having one or more filter devices, each of the one or more filter devices comprising a bulk acoustic wave resonator device;
an RF receive module coupled to the baseband signal processing module, and configured on a receive path, wherein the RF receive module includes a receive filter;
an antenna coupled to each of the RF transmit modules and each of the RF receive modules;
an antenna control device coupled to each of the receive paths and each of the transmit paths, and configured to select one of the receive paths or one of the transmit paths, wherein the antenna control device is coupled to the one or more transceiver modules;
a power amplifier module coupled to the controller, the power source, and the one or more transceiver modules; the power amplifier module being configured on each of the transmit paths and each of the receive paths, wherein the power amplifier module comprises a plurality of communication bands, each communication band having a power amplifier, wherein the one or more filter devices of each transceiver module are configured to one or more of the plurality of communication bands;
wherein each bulk acoustic wave resonator device comprises:
a support layer having a support layer surface region;
a piezoelectric film formed overlying the support layer;
a first electrode formed underlying a portion of the piezoelectric film;
a second electrode formed overlying a portion of the piezoelectric film;
a reflector region underlying the first electrode; and
wherein one of the bulk acoustic wave resonator devices comprises:
a contact via in the corresponding piezoelectric film of the bulk acoustic wave resonator device through which the corresponding first electrode of the bulk acoustic wave resonator device is electrically coupled to a contact metal.

2. The system of claim 1 further comprising a cooling module coupled to the power source, the one or more transceiver modules, and the power amplifier module.

3. The system of claim 1 wherein the power source includes a power supply, a battery-based power supply, or a power supply combined with a battery backup.

4. The system of claim 1 configured as a base station, wherein the base station is characterized as macro, micro, nano, pico, or femto, depending on the range, capacity and power capability.

5. The system of claim 1 configured as a Wi-Fi access point.

6. The system of claim 1 wherein the substrate includes silicon (S), silicon carbide (SiC), sapphire (Al2O3), silicon dioxide (SiO2), or other silicon materials.

7. The system of claim 1 wherein the piezoelectric film is a single crystal or polycrystalline piezoelectric film that includes aluminum nitride (AIN), aluminum scandium nitride (AlScN), gallium nitride (GaN), aluminum gallium nitride (AlGaN), AlxSc1-xN or AlxGa1-xN materials characterized by a composition of 0 ≤ X < 1.0, or magnesium hafnium aluminum nitride (MgHfAlN).

8. The system of claim 1 wherein the piezoelectric film is an upper portion of a polycrystalline piezoelectric film that includes aluminum nitride (AIN), aluminum scandium nitride (AlScN), gallium nitride (GaN), aluminum gallium nitride (AlGaN), AlxSc1-xN or AlxGa1-xN materials characterized by a composition of 0 ≤ X < 1.0, or magnesium hafnium aluminum nitride (MgHfAlN).

9. The system of claim 1 wherein the first electrode, second electrode, and top metal include molybdenum (Mo), ruthenium (Ru), tungsten (W), or other conductive materials; and wherein the first and second contact metals include gold (Au), aluminum (Al), copper (Cu), nickel (Ni), aluminum bronze (AlCu), or other metal materials.

10. The system of claim 1 wherein the substrate includes a bare and exposed crystalline material; and wherein the piezoelectric film is configured to propagate a longitudinal signal at an acoustic velocity of 6000 meters/second and greater; and wherein the first contact metal and the second contact metal are configured in a co-planar arrangement.

11. A fixed wireless communication system comprising:
a controller;
a signal processing module coupled to the controller;
one or more transceiver modules coupled to the controller, each of the transceiver modules comprising
a transmit module coupled to the signal processing module and configured on a transmit path, wherein the transmit module includes a transmit filter having one or more filter devices, each of the one or more filter devices comprising a bulk acoustic wave resonator device;
a receive module coupled to the signal processing module, and configured on a receive path, wherein the receive module includes a receive filter;
an antenna coupled to each of the transmit modules and each of the receive modules;
an antenna control device coupled to each of the receive paths and each of the transmit paths, and configured to select one of the receive paths or one of the transmit paths, wherein the antenna control device is coupled to the one or more transceiver modules;
wherein each bulk acoustic wave resonator device comprises:
a support layer having a support layer surface region;
a piezoelectric film formed overlying the support layer;
a first electrode formed underlying a portion of the piezoelectric film;
a second electrode formed overlying a portion of the piezoelectric film;
a reflector region underlying the first electrode; and
wherein one of the bulk acoustic wave resonator devices comprises:
a contact via in the corresponding piezoelectric film of the bulk acoustic wave resonator device through which the corresponding first electrode of the bulk acoustic wave resonator device is electrically coupled to a contact metal.

12. The system of claim 11 further comprising a power amplifier module coupled to the controller, the power source, and the one or more transceiver modules; the power amplifier module being configured on each of the transmit paths and each of the receive paths, wherein the power amplifier module comprises a plurality of communication bands, each communication band having a power amplifier, wherein the one or more filter devices of each transceiver module are configured to one or more of the plurality of communication bands.

13. The system of claim 12 further comprising
a band-to-band isolation between any pair of adjacent communication bands in the plurality of communication bands characterizing each of the transmit filters such that a difference between a pass band to reject band as measured in relative decibels (dBc) is greater than 10 dBc and less than 100 dBc.

14. The system of claim 11 further comprising a power source coupled to the controller, wherein the power source includes a power supply, a battery-based power supply, or a power supply combined with a battery backup.

15. A fixed wireless communications system comprising:
a processing device;
a plurality of transceiver modules, each of the transceiver modules comprising
an RF transmit module coupled to the processing device and configured on a transmit path, wherein the RF module includes a transmit filter having one or more filter devices, each of the one or more filter devices comprising a bulk acoustic wave resonator device;
an RF receive module coupled to the processing device, and configured on a receive path, wherein the RF receive module includes a receive filter;
a plurality of antennas coupled to the plurality of transceiver modules, each of the plurality of antennas being coupled to one the RF transmit modules and one of the RF receive modules;
a plurality of antenna control devices coupled to the plurality of antennas, each of the plurality of antenna control devices coupled to one of the receive paths and one of the transmit paths, and configured to select one of the receive paths or one of the transmit paths, wherein the plurality antenna control devices is also coupled to the plurality of transceiver modules;
a power amplifier module coupled to the processing device and the plurality of transceiver modules, the power amplifier module being configured on the transmit path and the receive path of each transceiver module, wherein the power amplifier module comprises a plurality of communication bands, each communication band having a power amplifier, wherein the one or more filter devices of each transceiver module are configured to one or more of the plurality of communication bands;
a band-to-band isolation between any pair of adjacent communication bands in the plurality of communication bands characterizing each of the transmit filters such that a difference between a pass band to reject band as measured in relative decibels (dBc) is greater than 10 dBc and less than 100 dBc;
an insertion loss characterizing each of the transmit filters, the insertion loss being less than 3 dB and greater than 0.5 dB; and
a center frequency configured to define the pass band;
wherein each bulk acoustic wave resonator device comprises:
a support layer having a support layer surface region;
a piezoelectric film formed overlying the support layer;
a first electrode formed underlying a portion of the piezoelectric film;
a second electrode formed overlying a portion of the piezoelectric film;
a reflector region underlying the first electrode; and
wherein one of the bulk acoustic wave resonator devices comprises:
a contact via in the corresponding piezoelectric film of the bulk acoustic wave resonator device through which the corresponding first electrode of the bulk acoustic wave resonator device is electrically coupled to a contact metal.

16. The system of claim 15 wherein the substrate includes silicon (S), silicon carbide (SiC), sapphire (Al2O3), silicon dioxide (SiO2), or other silicon materials.

17. The system of claim 15 wherein the piezoelectric film is a single crystal or polycrystalline piezoelectric film that includes aluminum nitride (AIN), aluminum scandium nitride (AlScN), gallium nitride (GaN), aluminum gallium nitride (AlGaN), AlxSc1-xN or AlxGa1-xN materials characterized by a composition of 0 ≤ X < 1.0, or magnesium hafnium aluminum nitride (MgHfAlN).

18. The system of claim 15 wherein the piezoelectric film is an upper portion of a polycrystalline piezoelectric film that includes aluminum nitride (AIN), aluminum scandium nitride (AlScN), gallium nitride (GaN), aluminum gallium nitride (AlGaN), AlxSc1-xN or AlxGa1-xN materials characterized by a composition of 0 ≤ X < 1.0, or magnesium hafnium aluminum nitride (MgHfAlN).

19. The system of claim 15 wherein the first electrode, second electrode, and top metal include molybdenum (Mo), ruthenium (Ru), tungsten (W), or other conductive materials; and wherein the first and second contact metals include gold (Au), aluminum (Al), copper (Cu), nickel (Ni), aluminum bronze (AlCu), or other metal materials.

20. The system of claim 15 wherein the surface region of the substrate is bare and exposed crystalline material; and wherein the piezoelectric film is configured to propagate a longitudinal signal at an acoustic velocity of 6000 meters/second and greater; and wherein the first contact metal and the second contact metal are configured in a co-planar arrangement.
